(19) United States
(12) Patent Application Publication
(10) Pub. No.: US 2024/0079856 A1
(43) Pub. Date: Mar. 7, 2024

(54) METHOD OF FABRICATING A RESONANT CAVITY AND DISTRIBUTED BRAGG REFLECTOR MIRRORS FOR A VERTICAL CAVITY SURFACE EMITTING LASER ON A WING OF AN EPITAXIAL LATERAL OVERGROWTH REGION

(71) Applicant: The Regents of the University of California, Oakland, CA (US)

(72) Inventors: Gandrothula Srinlvas, Santa Barbara, CA (US); Takeshi Kamikawa, Nara-city Nara (JP); Masahiro Araki, Yokkaichi-city, Mie (JP)

(73) Assignee: The Regents of the University of California, Oakland, CA (US)

(21) Appl. No.: 17/766,960

(22) PCT Filed: Oct. 23, 2020
(86) PCT No.: PCT/US20/57026

§ 371 Date: Apr. 6, 2022

Related U.S. Application Data
(60) Provisional application No. 62/924,756, filed on Oct. 23, 2019.

(51) Int. Cl. H01S 5/183; H01S 5/02

(52) U.S. Cl. CPC H01S 5/18394; H01S 5/0216; H01S 5/0217; H01S 5/18369; H01S 2304/04; H01S 2304/12

(57) ABSTRACT

A method for fabricating a quality and manufacturable aperture for light emitting elements, such as vertical cavity surface emitting lasers (VCSELs), using epitaxial later overgrowth (ELO). A bar comprised of island-like III-nitride semiconductor layers is grown on a substrate using a growth restrict mask, and the island-like III-nitride semiconductor layers are fabricated into light-emitting resonating cavities across a smallest length of the bar. Apertures for the resonating cavities are also fabricated along the smallest length of the bar on wing regions of the epitaxial lateral overgrowth. Distributed Bragg reflectors (DBRs) are fabricated as mirrors for the resonant cavities on the bottom and top of the wing regions of the epitaxial lateral overgrowth.

### CROSS REFERENCE TO RELATED APPLICATIONS

This application claims the benefit under 35 U.S.C. Section 119(e) of the following co-pending and commonly-assigned application:
U.S. Provisional Application Ser. No. 62/924,756, filed on Oct. 23, 2019, by Srinivas Gandrothula, Takeshi Kamikawa and Masahiro Araki, entitled “METHOD OF FABRICATING A RESONANT CAVITY AND DISTRIBUTED BRAGG REFLECTOR MIRRORS FOR A VERTICAL CAVITY SURFACE EMITTING LASER ON A WING OF AN EPITAXIAL LATERAL OVERGROWTH REGION,” attorneys' docket number G&C 30794.0745USP1 (UC 2020-071-1);
which application is incorporated by reference herein.

This application is related to the following co-pending and commonly-assigned applications:
U.S. Utility patent application Ser. No. 16/608,071, filed on Oct. 24, 2019, by Takeshi Kamikawa, Srinivas Gandrothula, Hongjian Li and Daniel A. Cohen, entitled “METHOD OF REMOVING A SUBSTRATE,” attorney's docket no. 30794.0653USWO (UC 2017-621-2), which application claims the benefit under 35 U.S.C. Section 365(c) of co-pending and commonly-assigned PCT International Patent Application Serial No. PCT/US18/31393, filed on May 7, 2018, by Takeshi Kamikawa, Srinivas Gandrothula, Hongjian Li and Daniel A. Cohen, entitled “METHOD OF REMOVING A SUBSTRATE,” attorney's docket no. 30794.0653WOU1 (UC 2017-621-2), which application claims the benefit under 35 U.S.C. Section 119(e) of co-pending and commonly-assigned U.S. Provisional Patent Application Ser. No. 62/502,205, filed on May 5, 2017, by Takeshi Kamikawa, Srinivas Gandrothula, Hongjian Li and Daniel A. Cohen, entitled “METHOD OF REMOVING A SUBSTRATE,” attorney's docket no. 30794.0653USP1 (UC 2017-621-1);
U.S. Utility patent application Ser. No. 16/642,298, filed on Feb. 26, 2020, by Takeshi Kamikawa, Srinivas Gandrothula and Hongjian Li, entitled “METHOD OF REMOVING A SUBSTRATE WITH A CLEAVING TECHNIQUE,” attorney's docket no. 30794.0659USWO (UC 2018-086-2), which application claims the benefit under 35 U.S.C. Section 365(c) of co-pending and commonly-assigned PCT International Patent Application Serial No. PCT/US18/51375, filed on Sep. 17, 2018, by Takeshi Kamikawa, Srinivas Gandrothula and Hongjian Li, entitled “METHOD OF REMOVING A SUBSTRATE WITH A CLEAVING TECHNIQUE.” attorney's docket no. 30794.0659WOU1 (UC 2018-086-2), which application claims the benefit under 35 U.S.C. Section 119(e) of co-pending and commonly-assigned U.S. Provisional Patent Application Ser. No. 62/559,378, filed on Sep. 15, 2017, by Takeshi Kamikawa, Srinivas Gandrothula and Hongjian Li, entitled “METHOD OF REMOVING A SUBSTRATE WITH A CLEAVING TECHNIQUE,” attorney's docket no. 30794.0659USP1 (UC 2018-086-1);
U.S. Utility patent application Ser. No. 16/978,493, filed on Sep. 4, 2020, by Takeshi Kamikawa, Srinivas Gandrothula and Hongjian Li, entitled “METHOD OF FABRICATING NON-POLAR AND SEMI-POLAR DEVICES USING EPITAXIAL LATERAL OVERGROWTH,” attorney's docket no. 30794.0680USWO (UC 2018-427-2), which application claims the benefit under 35 U.S.C. Section 365(c) of co-pending and commonly-assigned PCT International Patent Application Serial No. PCT/US19/25187, filed on Apr. 1, 2019, by Takeshi Kamikawa, Srinivas Gandrothula and Hongjian Li, entitled “METHOD OF FABRICATING NON-POLAR AND SEMI-POLAR DEVICES USING EPITAXIAL LATERAL OVERGROWTH,” attorney's docket no. 30794.0680WOU1 (UC 2018-427-2), which application claims the benefit under 35 U.S.C. Section 119(e) of co-pending and commonly-assigned U.S. Provisional Patent Application Ser. No. 62/650,487, filed on Mar. 30, 2018, by Takeshi Kamikawa, Srinivas Gandrothula, and Hongjian Li, entitled “METHOD OF FABRICATING NON-POLAR AND SEMI-POLAR DEVICES USING EPITAXIAL LATERAL OVERGROWTH,” attorney docket number G&C 30794.0680USP1 (UC 2018427-1);
U.S. Utility patent application Ser. No. 17/048,383, filed on Oct. 16, 2020, by Takeshi Kamikawa and Srinivas Gandrothula, entitled “METHOD FOR DIVIDING A BAR OF ONE OR MORE DEVICES.” attorney's docket no. 30794.0681USWO (UC 2018-605-2), which application claims the benefit under 35 U.S.C. Section 365(c) of co-pending and commonly-assigned PCT International Patent Application Serial No. PCT/US19/32936, filed on May 17, 2019, by Takeshi Kamikawa and Srinivas Gandrothula, entitled “METHOD FOR DIVIDING A BAR OF ONE OR MORE DEVICES,” attorney's docket no. 30794.0681WOU1 (UC 2018-605-2), which application claims the benefit under 35 U.S.C. Section 119(c) of co-pending and commonly-assigned U.S. Provisional Application Ser. No. 62/672,913, filed on May 17, 2018, by Takeshi Kamikawa and Srinivas Gandrothula, entitled “METHOD FOR DIVIDING A BAR OF ONE OR MORE DEVICES,” attorneys' docket number G&C 30794.0681USP1 (UC 2018-605-1);
PCT International Patent Application Serial No. PCT/US19/34868, filed on May 30, 2019, by Srinivas Gandrothula and Takeshi Kamikawa, entitled “METHOD OF REMOVING SEMICONDUCTING LAYERS FROM A SEMICONDUCTING SUBSTRATE.” attorneys' docket number G&C 30794.0682WOU1 (UC 2018-614-2), which application claims the benefit under 35 U.S.C. Section 119(e) of co-pending and commonly-assigned U.S. Provisional Application Ser. No. 62/677,833, filed on May 30, 2018, by Srinivas Gandrothula and Takeshi Kamikawa, entitled “METHOD OF REMOVING SEMICONDUCTING LAYERS FROM A SEMICONDUCTING SUBSTRATE,” attorneys' docket number G&C 30794.0682USP1 (UC 2018-614-1);
PCT International Patent Application Serial No. PCT/US19/59086, filed on Oct. 31, 2019, by Takeshi Kamikawa and Srinivas Gandrothula, entitled “METHOD OF OBTAINING A SMOOTH SURFACE WITH EPITAXIAL LATERAL OVERGROWTH,” attorneys' docket number G&C 30794.0693WOU1 (UC 2019-166-2), which application claims the benefit under 35 U.S.C. Section 119(e) of co-pending and commonly-assigned U.S. Provisional Application Ser. No. 62/753,225, filed on Oct. 31, 2018, by Takeshi Kamikawa and Srinivas Gandrothula, entitled “METHOD OF OBTAINING A SMOOTH SURFACE WITH EPITAXIAL LATERAL OVERGROWTH,” attorneys' docket number G&C 30794.0693USP1 (UC 2019-166-1);
PCT International Patent Application Serial No. PCT/US20/13934, filed on Jan. 16, 2020, by Takeshi Kamikawa, Srinivas Gandrothula and Masahiro Araki, entitled “METHOD FOR REMOVAL OF DEVICES USING A TRENCH,” attorneys' docket number G&C 30794.0713WOU1 (UC 2019-398-2), which application claims the benefit under 35 U.S.C. Section 119(e) of co-pending and commonly-assigned U.S. Provisional Application Ser. No. 62/793,253, filed on Jan. 16, 2019, by Takeshi Kamikawa, Srinivas Gandrothula and Masahiro Araki, entitled “METHOD FOR REMOVAL OF DEVICES USING A TRENCH,” attorneys' docket number G&C 30794.0713USP1 (UC 2019-398-1);
PCT International Patent Application Serial No. PCT/US20/20647, filed on Mar. 2, 2020, by Takeshi Kamikawa and Srinivas Gandrothula, entitled “METHOD FOR FLATTENING A SURFACE ON AN EPITAXIAL LATERAL GROWTH LAYER,” attorneys' docket number G&C 30794.0720WOU1 (UC 2019-409-2), which application claims the benefit under 35 U.S.C. Section 119(e) of co-pending and commonly-assigned U.S. Provisional Application Ser. No. 62/812,453, filed on Mar. 1, 2019, by Takeshi Kamikawa and Srinivas Gandrothula, entitled “METHOD FOR FLATTENING A SURFACE ON AN EPITAXIAL LATERAL GROWTH LAYER,” attorneys' docket number G&C 30794.0720USP1 (UC 2019-409-1);
PCT International Patent Application Serial No. PCT/US20/22735, filed on Mar. 13, 2020, by Takeshi Kamikawa, Masahiro Araki and Srinivas Gandrothula, entitled “SUBSTRATE FOR REMOVAL OF DEVICES USING VOID PORTIONS,” attorneys' docket number G&C 30794.0722WOU1 (UC 2019-412-2), which application claims the benefit under 35 U.S.C. Section 119(e) of co-pending and commonly-assigned U.S. Provisional Application Ser. No. 62/817,757, filed on Mar. 13, 2019, by Takeshi Kamikawa, Masahiro Araki and Srinivas Gandrothula, entitled “SUBSTRATE FOR REMOVAL OF DEVICES USING VOID PORTIONS,” attorneys' docket number G&C 30794.0722USP1 (UC 2019-412-1); and
PCT International Patent Application Serial No. PCT/US20/22430, filed on Mar. 12, 2020, by Takeshi Kamikawa, Srinivas Gandrothula and Masahiro Araki, entitled “METHOD FOR REMOVING A BAR OF ONE OR MORE DEVICES USING SUPPORTING PLATES,” attorneys' docket number G&C 30794.0724WOU1 (UC 2019-416-1), which application claims the benefit under 35 U.S.C. Section 119(e) of co-pending and commonly-assigned U.S. Provisional Application Ser. No. 62/817,216, filed on Mar. 12, 2019, by Takeshi Kamikawa, Srinivas Gandrothula and Masahiro Araki, entitled “METHOD FOR REMOVING A BAR OF ONE OR MORE DEVICES USING SUPPORTING PLATES,” attorneys' docket number G&C 30794.0724USP1 (UC 2019-416-1);
all of which applications are incorporated by reference herein.

### BACKGROUND OF THE INVENTION

### 1. Field of the Invention

This invention relates to a method for fabricating good quality light emitting apertures of Vertical Cavity Surface Emitting Lasers (VCSELs) on wings of an Epitaxial Lateral Overgrowth (ELO) region.

### 2. Description of the Related Art

There has been a lot of interest in fabricating a VCSEL which satisfies manufacturability, good quality, non-critical tolerances, best characteristics and better yield. The work done by Kuramoto et al. (APEX, 11, 112101 (2018)) on developing epitaxial distributed Bragg reflectors (DBRs), and Hamaguchi et al (APEX, 12, 044004 (2019)) on developing a curved mirror approach on the substrate side, are some examples that mention industry's interest for better quality VCSEL devices.

In the case of visible region light emitters, III-nitride materials, namely (B, Al, Ga, In)N semiconductors having the formula B_{w}AlₓGa_{y}In_{z}N where 0≤w≤1, 0≤x≤1, 0≤y≤1, 0≤z≤1, and w+x+y+z=1, such as GaN, are required to fabricate good quality VCSELs. Alternatively, there have been approaches utilizing III-nitride templates on foreign substrates, such as Si, sapphire, etc. However, especially with devices that involve stimulated emission and smaller dimensional light emitting areas, a homogeneous epitaxy would be suggested, rather than a non-homogeneous epitaxy or hetero-epitaxy, in order to tolerate micron-level defects.

In U.S. Pat. No. 9,407,067, and US Patent Application Publication No. 2019/0173263, and in the publication Phys. Status Solidi A 2016, 213, 1170-1176, Hamaguchi et al. mentioned fabricating a light emitting element aperture on an ELO region; however, mass production and an unwanted crystal quality between the resonating length of the cavity might affect the final characteristics of the device.

Also, Hamaguchi et al. uses a curved mirror approach that still needs substrate thinning to reduce absorption loss in the cavity, which can be a difficult process to control at industrial scales. In addition, removing or thinning the substrate by chemical or mechanical polishing would be a tedious and affect yields.

In Takeshi et al. (APEX, Vol. 27, Issue 17, pp. 24717-24723 (2019)), as well as PCT International Patent Application No. PCT/US18/31293, filed on May 7, 2018, by Takeshi Kamikawa, Srinivas Gandrothula, Hongjian Li and Daniel A. Cohen, entitled “METHOD OF REMOVING A SUBSTRATE,” which is cross-referenced above, a robust method was demonstrated for removing a substrate after fabricating a light emitting element on it. This method is utilized as an example to remove a substrate after making a light emitting element on it.

Nonetheless, there remains a need in the art for improved methods for fabricating VCSELs, including the resonant cavity and mirrors of the resonant cavity. The present invention satisfies this need.

### SUMMARY OF THE INVENTION

To overcome the limitations in the prior art described above, and to overcome other limitations that will become apparent upon reading and understanding this specification, the present invention discloses a method for fabricating a good quality aperture for devices that emit light normal to substrates from where the devices have been epitaxially fabricated, such as VCSELs.

Specifically, this invention proposes a method for preparing good quality VCSEL device designs using a combination of epitaxial lateral overgrowth and mechanical peeling. Additionally, this invention provides away to solve yield and dead pixel problems associated in display applications, when the display applications require VCSELs for better quality and faster communications. This invention also proposes a handling method to integrate or mass produce VCSELs by assembling or packaging in terms of pre-assembled bars.

Key aspects of this invention include:
A light emitting aperture of the device is made on a wing region of an ELO III-nitride layer; therefore, the device is intended to have a better crystal quality in terms of defects and stacking faults than a device aperture made directly on a native substrate.
The resonant cavity length of the VCSEL can be controlled epitaxially rather than using complicated techniques of thinning or chemical methods on native substrates.
At least one of the DBR mirrors of the cavity is placed on the wing of the ELO III-nitride layer, and at least one of the DBR mirrors may be placed at a backside of the ELO III-nitride layer after separating the ELO III-nitride layer from its native substrate.
The substrate can be recycled for a next batch of device fabrication.
This method is independent of crystal orientations of the native substrate.
In this invention, preparing a surface for a DBR mirror for resonant cavity VCSELs uses only a growth restrict mask.
This invention can be applied to make a curved mirror when a long resonant cavity for the VCSEL is desired.
This invention includes a method for realizing stress relaxation of the ELO III-nitride layer, which results in crack-free and long-lived device devices 111, by placing one of the DBR mirrors after removing the ELO III-nitride layer from its host substrate.

A few of the possible designs using this method are illustrated in the following description. The invention has many benefits as compared to conventionally manufacturable device elements when combined with the cross-referenced inventions on removing semiconducting devices from a semiconducting substrate set forth above.

In one embodiment, this invention performs the following steps: island-like III-nitride semiconductor layers are grown on a substrate using a growth restrict mask and an ELO method; where the growth restrict mask occupies at least 50% or more of a single device. The ELO regions are meant to be a region with reduced dislocation densities as compared to a region that is not covered by ELO. The light emitting aperture of the VCSEL is made to be confined to the wings of the ELO region, such that a good crystal quality aperture can be formed. The resonant cavity and DBR mirrors of the VCSEL device are made on the ELO region wings, and on the top and bottom of the ELO region wings, respectively.

The interface at the growth restrict mask surface and the ELO regions is smooth enough to fabricate one of the light reflecting DBR mirrors, without severe chemical treatments. The island-like III-nitride semiconductor layers are removed from the substrate and another one of the DBR mirrors is placed at the backside of the ELO III-nitride layer, which is the interface served between growth restrict mask and ELO III-nitride layer.

The method of ELO to form the island-like III-nitride semiconductor layers may include growth by metal organic chemical vapor deposition (MOCVD), hydride vapor phase epitaxy (HVPE), etc., to accurately control thickness, and thus the cavity length of the VCSEL device. The III-nitride semiconductor layers are dimensioned such that one or more of the island-like III-nitride semiconductor layers form a bar (known as a semiconductor bar or a bar of the device). By doing this, nearly identical devices can be fabricated adjacent to each other in a self-assembled array, and thus by integration, to scale up can be made easier. Alternatively, ELO III-nitride layers can made to coalesce initially, such that they can be later divided into bars of devices or individual chips.

Every device of such a bar can be addressed separately or together with other devices, by designing a proper fabrication process. For example, one could make a common cathode or anode for such a device bar for a monolithic integration or one can address individual devices for full color display applications. Consequently, a high yield can be obtained.

Moreover, the present invention can use hetero-substrates to grow the island-like III-nitride semiconductor layers that form the bar. For example, a GaN template grown on a hetero-substrate, such as sapphire, Si, GaAs, SiC, etc., can be used in the present invention.

Furthermore, the ELO method can drastically reduce dislocation density and stacking faults density, which are critical issues when using hetero-substrates.

Therefore, this invention can solve many kinds of problems incurred with the use of hetero-substrates, at the same time. For example, in a laser device, the interface between growth restrict mask and the ELO III-nitride layer can be used as a facet for the resonator.

### BRIEF DESCRIPTION OF THE DRAWINGS

Referring now to the drawings in which like reference numbers represent corresponding parts throughout:

FIG. 1(a) is a schematic of a substrate, growth restrict mask and epitaxial layers, according to one embodiment of the present invention,

FIG. 1(b) illustrates magnified view of the device layers on island-like III-nitride semiconductor layers, and

FIG. 1(c) is atop view of bars of devices fabricated on island-like III-nitride semiconductor layers.

FIGS. 2(a), 2(b), 2(c), 2(d), 2(e) and 2(f) are illustrations when ELO III-nitride layers are made to coalesce with neighboring ELO III-nitride layers from each neighboring open area.

FIGS. 3(a), 3(b), 3(c), 3(d) 3(e) and 3(f) illustrate a new device design when one of the light reflecting DBR mirrors of the resonant cavity of the VCSEL is embedded between two ELO III-nitride layers,

FIGS. 3(g), 3(h), 3(i), 3(j) and 3(k) are the potential designs of embedded DBR mirrors, and

FIGS. 3(l) and 3(m) are magnified versions of FIGS. 3(j) and 3(k), respectively.

FIGS. 4(a), 4(b), 4(c), 4(d) and 4(e) are cross-sectional views of a process to obtain a concave shaped patches on a III-nitride substrate, wherein the patches can be used to form a curved light reflecting mirror on an n-side by allowing the III-nitride ELO III-nitride layer to flow into the designed shape from the open region,

FIG. 4(f) is a cross-sectional view of formed island-like III-nitride semiconductor layers on a processed substrate, and

FIG. 4(g) is a VCSEL device fabricated using the substrate.

FIGS. 5(a), 5(b), 5(c) and 5(d) are cross-sectional views of a process to obtain irregular (rectangular, tapered etc.) shaped patches on a III-nitride substrate, wherein the patches can be used to form a designed shape light reflecting mirror on an n-side by allowing the III-nitride ELO III-nitride layer to flow into the designed shape from the open region,

FIG. 5(e) is a cross-sectional view of formed island-like III-nitride semiconductor layers on a processed substrate,

FIG. 5(f) is a VCSEL device fabricated using the substrate prepared in step FIG. 5(d),

FIG. 5(g) is a patterned host substrate with a two-period growth restrict mask structure in the form of stripes, where the dips near the open area assist in forming ELO III-nitride layers of a patterned shape,

FIG. 5(h) is a patterned host substrate in the form of patches, and

FIG. 5(i) is a graphical representation when device layers are formed on the pre-patterned host substrate.

FIG. 6(a) illustrates how a dividing region is formed at periodic lengths along a bar of the device, according to one embodiment of the present invention.

FIGS. 6(b), 6(c) and 6(d) illustrate how a supporting plate can be attached on the bar of devices, and

FIG. 6(e) is a cross sectional view of a supporting plate with finger-like structures to attach and grab island-like III-nitride semiconductor layers.

FIG. 7(a) illustrates a possible removal method for ELO III-nitride layers using a hooking technique,

FIG. 7(b) illustrates coalesced or non-coalesced structures for a hooking process,

FIG. 7(c) illustrates a disposed selective etched mask where two types of etching masks are shown.

FIG. 7(d) illustrates Type-1 etching to separate a III-nitride layer chip, where a hook is from an open ELO window,

FIG. 7(e) illustrates Type-2 etching where an optical microscope image shows III-nitride layer chips sandwiched between a growth restrict mask and an etching mask,

FIG. 7(f) illustrates III-nitride layers sandwiched between a growth restrict mask and an etched mask in Step 2, and placement of a secured chip layer in Step 3,

FIG. 7(g) illustrates a secured chip layer that is selectively etched to obtain a hook pattern 1, hook pattern 2 and hook pattern 3,

FIG. 7(h) illustrates optical and scanning electron microscope images of pattern 3 hooked III-nitride layered chips,

FIG. 7(i) illustrates a unique curved mirror VCSEL structure process on an n-side epitaxial layer, and

FIG. 7(j) illustrates a dual-clad FP laser structure using a booking process.

FIG. 8(a) shows images of c-plane ELO III-nitride layer growth and interface surface morphology measurements following removal,

FIG. 8(b) shows images of semipolar 20-21 plane ELO III-nitride layer growth and interface surface morphology measurements following removal, and

FIGS. 8(c) and 8(d) show images of nonpolar 10-10 plane ELO III-nitride layer growth and interface surface morphology measurements following removal for two different growth restrict mask patterns.

FIGS. 9(a), 9(b). 9(c), 9(d), and 9(e) illustrate controlling the interface of the bottom of the ELO III-nitride layer for fabricating one of the DBR mirrors of the resonant cavity VCSEL.

FIG. 9(f) are optical microscope images of 20-2-1 ELO III-nitride layers grown on various masks, FIG. 9(g) are optical microscope images of the removed 20-2-1 ELO III-nitride layers on an adhesive film, and FIG. 9(h) is an atomic force microscopy (AFM) scan of the interfaces at the ELO wings of the removed 20-2-1 ELO III-nitride layers.

FIG. 9(i) is a plot of surface roughness at the interface of the ELO III-nitride layers with various types of masks.

FIGS. 10(a), 10(b), 10(c), 10(d), 10(e) and 10(f) are different possible designs of VCSEL devices.

FIG. 10(g) is a cross-sectional view of a single aperture VCSEL device with opposite side electrodes formed from the island-like III-nitride semiconductor layers,

FIG. 10(h) is a cross-sectional view of a single aperture VCSEL device with same side electrodes formed from the island-like III-nitride semiconductor layers,

FIG. 10(i) is a cross-sectional view of a single aperture VCSEL device with opposite side electrodes and an n-side curved mirror formed from the island-like III-nitride semiconductor layers,

FIG. 10(j) is a cross-sectional view of a single aperture VCSEL device with same side electrodes and an n-side curved mirror formed from the island-like III-nitride semiconductor layers,

FIG. 10(k) is a cross-sectional view of a single aperture VCSEL device with opposite side electrodes and a p-side curved mirror formed from the island-like III-nitride semiconductor layers, and

FIG. 10(l) is a cross-sectional view of a single aperture VCSEL device with same side electrodes and a p-side curved mirror formed from the island-like III-nitride semiconductor layers.

FIGS. 11(a), 11(b), 11(c), 11(d), 11(e), 11(f), 11(g) and 11(h) illustrate a VCSEL fabrication process on non-coalesced island-like III-nitride semiconductor layers, according to one embodiment of the present invention, and

FIGS. 11(i), 11(j) and 11(k) illustrate a possible solution when the aspect ratio of the non-coalesced ELO structures do not have enough space to fabricate VCSEL devices.

FIGS. 12(a), 12(b), 12(c), 12(d), 12(c), 12(f), 12(g), 12(h), 12(i), 12(j) and 12(k) illustrate a procedure for removing a bar of a device, according to one embodiment of the present invention.

FIGS. 13(a), 13(b) and 13(c) are schematic views of the effect of the growth restrict mask on the interface.

FIGS. 14(a), 14(b), 14(c), 14(d), 14(e), 14(f) and 14(g) illustrates a process flow for defining an n-side light reflecting layer after removing a bar of devices using supporting plates, and also illustrate possible device designs when VCSEL devices fabricated on the two wings of the ELO III-nitride layer and open region are included in the device design.

FIGS. 15(a) and 15(b) illustrate a process to divide devices after n-electrode formation.

FIGS. 16(a), 16(b), 16(c), 16(d), 16(e) and 16(f) illustrate placing the removed island-like III-nitride semiconductor layers on heatsink plates.

FIGS. 17(a), 17(b), 17(c) and 17(d) illustrate how wire bonds are attached to devices, according to one embodiment of the present invention.

FIGS. 18(a) and 18(b) illustrate a moonlighting integration or a multi-colored integration with heat sink plates, according to one embodiment of the present invention.

FIG. 19 is a flow chart for integrating VCSEL devices onto a back panel of a display or a maximizing flux.

FIGS. 20(a). 20(b), 20(c), 20(d) and 20(e) illustrate a process dedicated to integrating individual devices.

FIGS. 21(a), 21(b), 21(c) and 21(d) illustrate a process dedicated to integrating bars of devices.

FIG. 22 shows one of the possible mass transfer techniques using a ultra-violet (UV) sensitive carrier and UV laser.

FIGS. 23(a), 23(b), 23(c), 23(d), 23(e) and 23(f) represent a process for fabricating an embedded DBR resonant cavity VCSEL and magnified versions of possible designs.

FIG. 24(a) illustrates a growth restrict mask embedded by ELO III-nitride layers, and

FIG. 24(b) shows visible cracks in the surface of the ELO III-nitride layers.

FIG. 25 is a flowchart that illustrates a method for removing a bar comprised of one or more devices from a substrate by bonding supporting plates to the bars.

### DETAILED DESCRIPTION OF THE INVENTION

In the following description of the preferred embodiment, reference is made to a specific embodiment in which the invention may be practiced. It is to be understood that other embodiments may be utilized, and structural changes may be made without departing from the scope of the present invention.

Overview

The present invention describes a method of fabricating a light emitting aperture on or above an interface for an ELO III-nitride layer and manufacturing a light emitting element according to the following steps.

Specifically, the present invention discloses a method of fabricating VCSELs that is aimed at tolerating designs for mass production and better thermal characteristics. This invention can incorporate a curved DBR mirror either on a p-side, on an n-side, or can even embed DBR designs, in addition to regular planar DBR designs.

This invention covers the following approaches:
1. Short cavity VCSELs with planar DBR mirrors, wherein better wing regions without unwanted crystal quality for aperture placements can be obtained in the case of short cavity VCSELs.
2. Long cavity VCSELs with curved DBR mirrors, wherein the curved mirrors have the advantage of reducing diffraction losses by focusing the reflected light back into the aperture. Long cavities can be useful for better thermal management, increased lifetime, output power and efficiency.
3. Short or long cavity embedded light reflecting DBR mirror design for better thermal performance. This approach avoids unwanted crystal quality due to coalescence.
4. An approach to making a good crystal quality, self-grown, curved or non-planar mirrors based on an ELO method for longer cavity VCSELs is simple and manufacturable at an industrial level.

In the following example, a process of realizing a VCSEL is described.

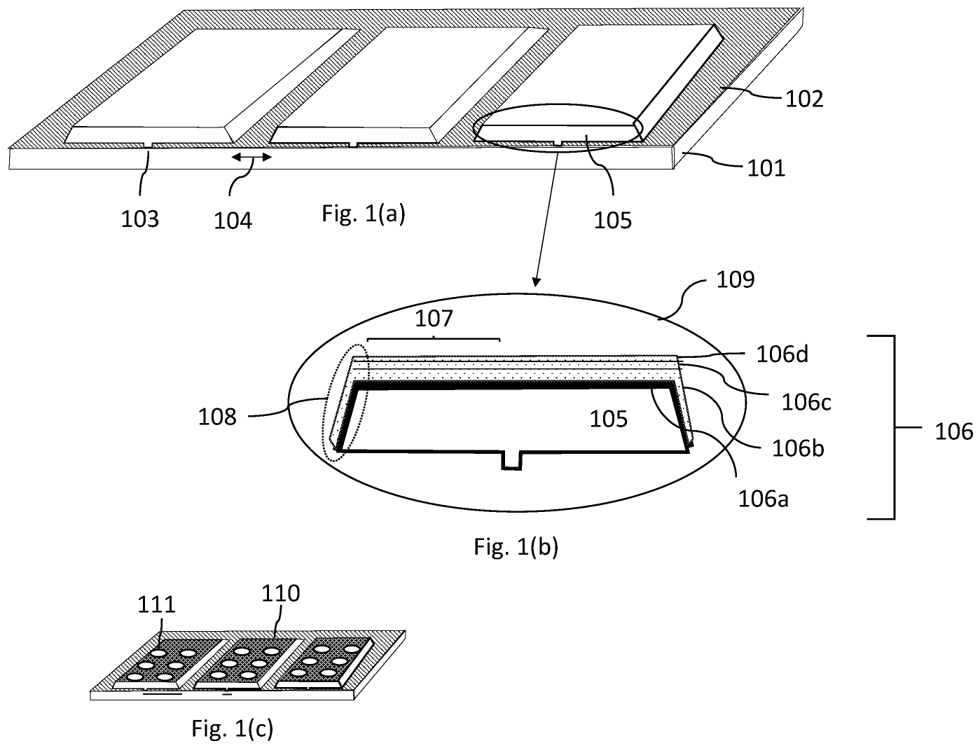

FIGS. 1(a), 1(b) and 1(c) illustrate a method, which comprises providing III-nitride-based substrate 101, such as a bulk GaN substrate 101, wherein FIG. 1(a) is a schematic of a substrate, growth restrict mask and epitaxial layers, FIG. 1(b) illustrates magnified view of the device layers on island-like III-nitride semiconductor layers, and FIG. 1(c) is a top view of bars of devices fabricated on island-like III-nitride semiconductor layers.

A growth restrict mask 102 is formed on or above the GaN-based substrate 101. Specifically, the growth restrict mask 102 is disposed directly in contact with the substrate 101 or is disposed indirectly through an intermediate layer grown by MOCVD, etc., made of III-nitride-based semiconductor deposited on the substrate 101.

The growth restrict mask 102 can be formed from an insulator film, for example, an SiO₂ film deposited upon the base substrate 101, for example, by chemical vapor deposition (CVD), sputter, ion beam deposition (IBD), etc., wherein the SiO₂ film is then patterned by photolithography using a predetermined photo mask and etching to include opening areas 103, as well as no-growth regions 104 (which may or may not be patterned).

Epitaxial III-nitride layers 105, such as GaN-based layers 105, are grown by ELO on the GaN substrate 101 and the growth restrict mask 102. The growth of the ELO III-nitride layers 105 occurs first in the opening areas 103, on the GaN-based substrate 101, and then laterally from the opening areas 103 over the growth restrict mask 102. The growth of the ELO III-nitride layers 105 is stopped or interrupted before the ELO III-nitride layers 105 at adjacent opening areas 103 can coalesce on top of the growth restrict mask 102. This interrupted growth results in the no-growth regions 104 between adjacent ELO III-nitride layers 105.

Additional III-nitride semiconductor device layers 106 are deposited on or above the ELO III-nitride layers 105, and may include an active region 106a, a p-type layer 106b, an electron blocking layer (EBL) 106c, and a cladding layer 106d, as well as other layers.

The ELO III-nitride layers 105 include one or more flat surface regions 107 and layer bending regions 108 at the edges thereof adjacent the no-growth regions 104. The width of the flat surface region 107 is preferably at least 5 μm, and most preferably is 30 μm or more.

The ELO III-nitride layers 105 and additional III-nitride based semiconductor device layers 106 separated by no-growth regions 104 are referred to as island-like III-nitride semiconductor layers 109, which take the shape of a bar 110. The distance between the island-like III-nitride semiconductor layers 109, which is the width of a no-growth region 104, is generally 20 μm or less, and preferably 5 μm or less, but is not limited to these values.

The growth of the island-like III-nitride semiconductor layers 109 is terminated before coalescing with its next neighbors, and by doing so, the ELO region of the island-like III-nitride semiconductor layers 109 is free of unwanted crystal defects that arise due to coalescence between next neighbors, as most of the defects originate from the opening areas 103 and will not propagate to the top surface of the island-like III-nitride semiconductor layers 109.

A light-emitting aperture of a VCSEL device 111 is processed on either side of the opening area 103, preferably between opening area 103 and the layer bending region 108, as shown in FIG. 1(c). By doing so, each bar 110 may be comprised of one or more devices 111, for example, the bars 110 of FIG. 1(c) are comprised of arrays of nearly identical light emitting apertures for multiple devices 111 formed on either side of the opening area 103 along the length of the bar 110.

There are many methods of removing the bar 110 containing the devices 111 from the substrate 101. For example, the present invention can utilize an ELO method for removing the bar 110 of the device 111. Generally, the ELO method is utilized to reduce the defect density in the island-like III-nitride semiconductor layers 109.

In the ELO method for removing the bar 110 of the device 111, the bonding strength between the substrate 101 and the ELO III-nitride layers 105 is weakened by the growth restrict mask 102. In this case, the bonding area between the substrate 101 and the ELO III-nitride layers 105 is the opening area 103, wherein the width of the opening area 103 is narrower than the ELO III-nitride layers 105. Consequently, the bonding area is reduced by the growth restrict mask 102, so that this method is preferable for removing the epitaxial layers 105, 106, 109.

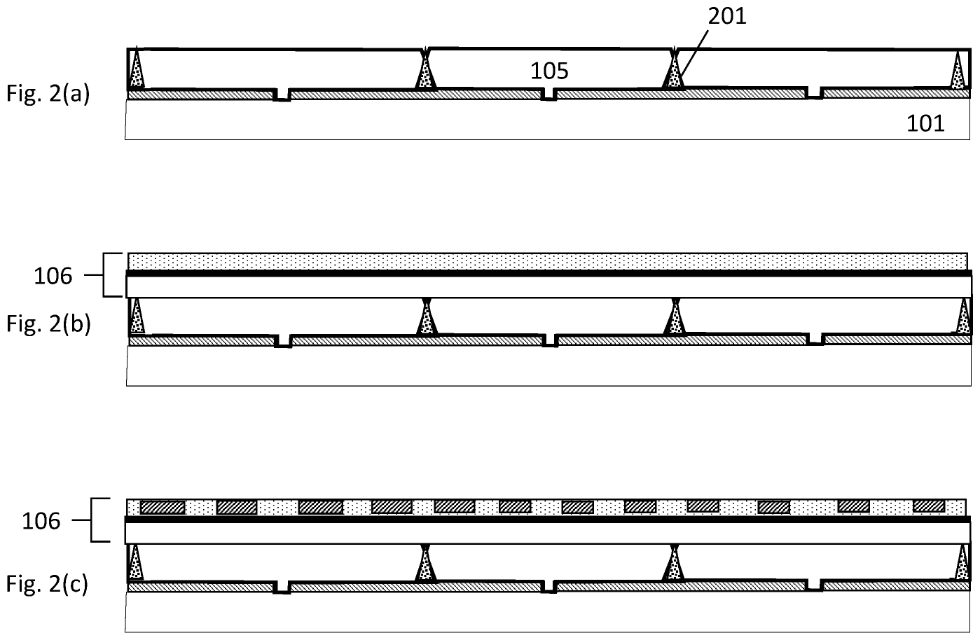

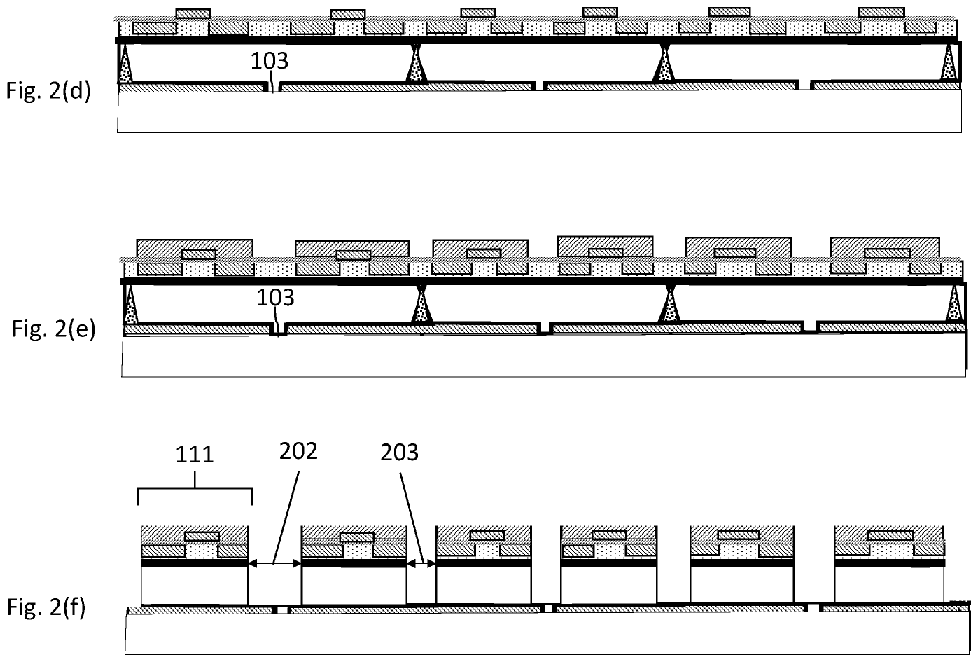

In another embodiment, the ELO III-nitride layers 105 are allowed to coalesce to each other, as shown in FIGS. 2(a)-2(f). Specifically, FIGS. 2(a), 2(b), 2(c), 2(d), 2(e) and 2(f) are illustrations when ELO III-nitride layers 105 are made to coalesce with neighboring ELO III-nitride layers 105 from each neighboring open area 103.

After the ELO III-nitride layers 105 coalesce at region 201 in FIG. 2(a), subsequent III-nitride semiconductor device layers 106 are deposited in FIGS. 2(b), 2(c), 2(d) and 2(e). Light emitting devices 111 with apertures are fabricated on wing regions of the ELO III-nitride layers 105 away from the coalesced region 201 and opening area 103. Then, the III-nitride semiconductor layers 105, 106, 109 can be divided at 202 and 203 as shown in FIG. 2(f), for example, using a dry etching or laser scribing etc.

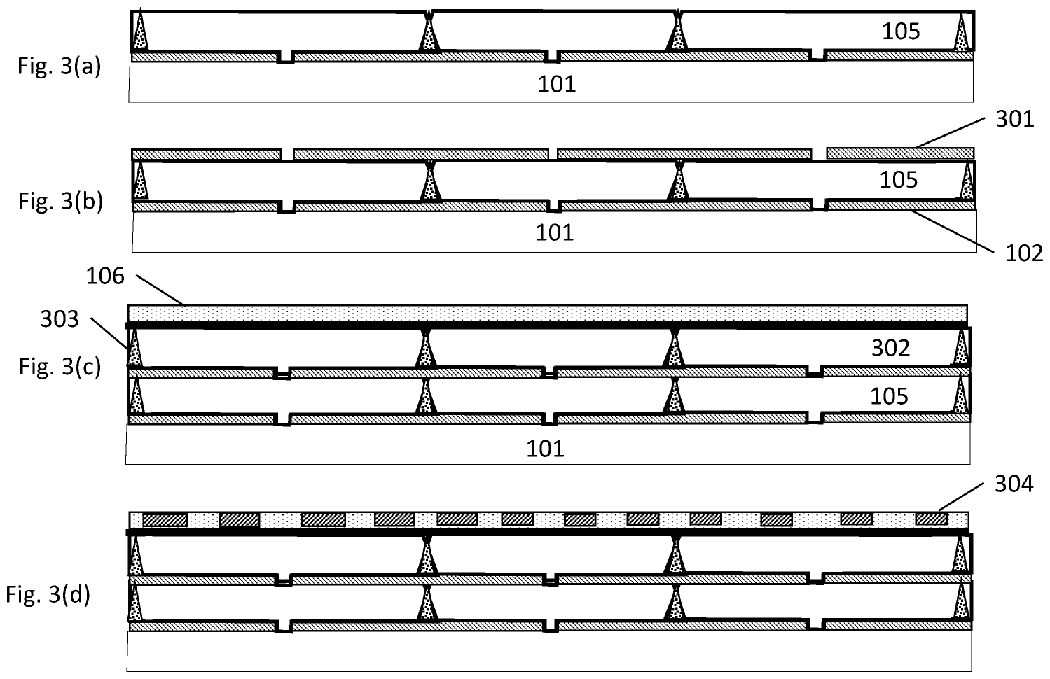

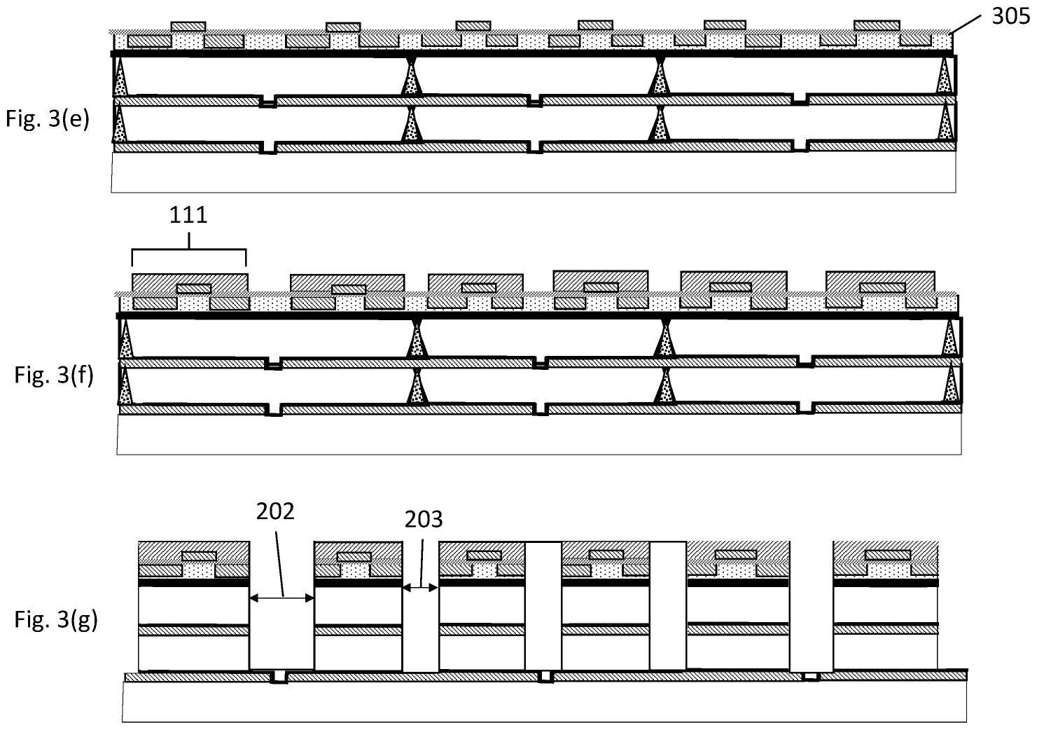

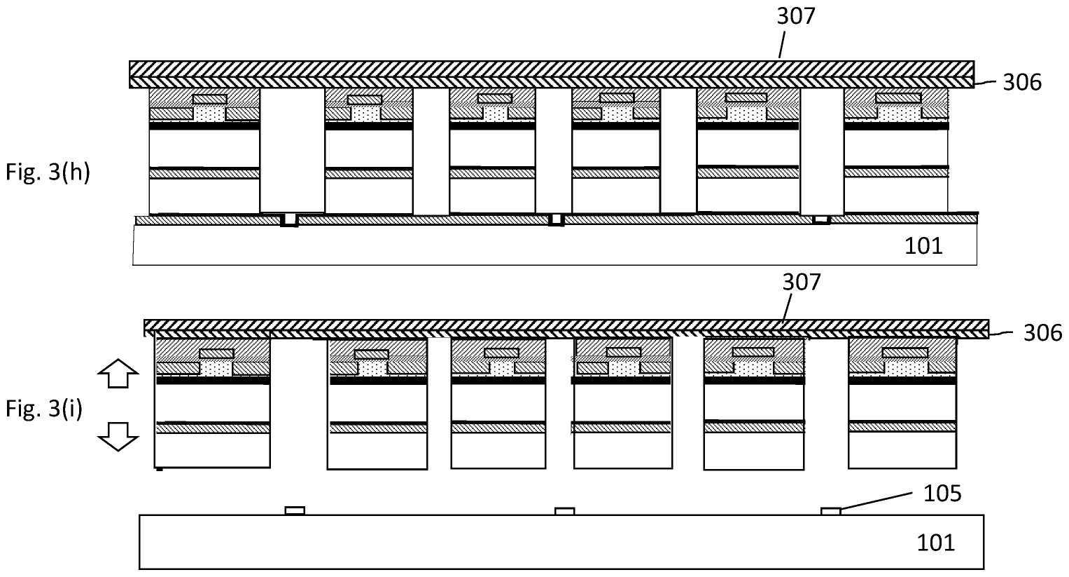

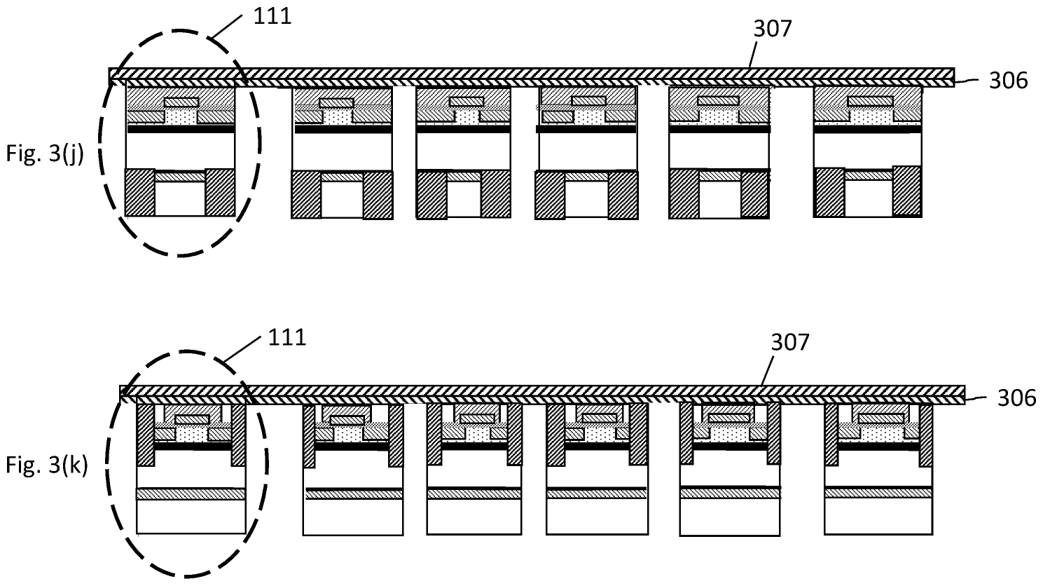

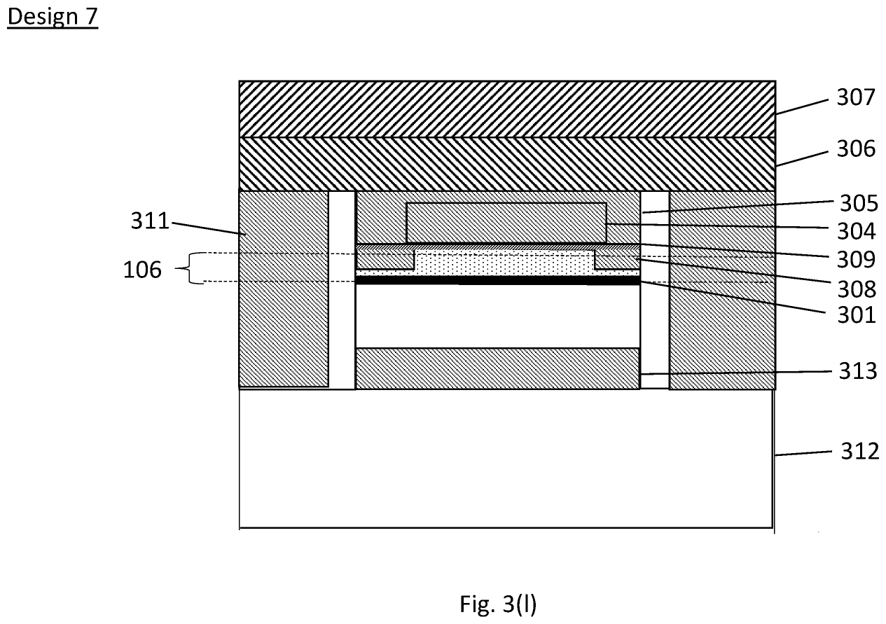

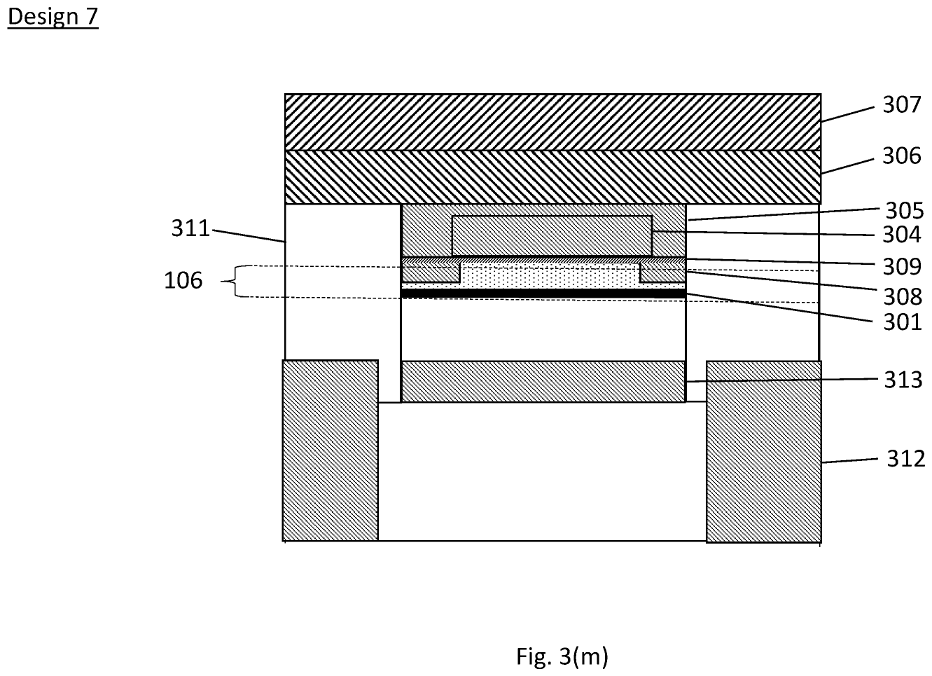

FIGS. 3(a), 3(b), 3(c), 3(d) 3(e) and 3(f) illustrate a new device design when one or more light reflecting DBR mirrors of a resonant cavity of a VCSEL device 111 are embedded between two ELO III-nitride layers, FIGS. 3(g), 3(h), 3(i), 3(j) and 3(k) are the potential designs of embedded DBR mirrors, and FIGS. 3(l) and 3(m) are magnified versions of FIGS. 3(j) and 3(k), respectively.

In one embodiment, as shown in FIGS. 3(a)-3(m), a light reflecting DBR mirror 301 is fabricated on the substrate 101. The DBR mirror placement 301 was chosen to reside on a wing region of the previously-grown ELO III-nitride layer 105. A second epitaxial lateral overgrowth layer 302 is formed from the separated open region between two DBR mirrors 301 on either wing of the previously-embedded ELO III-nitride layer 105. The later-grown ELO III-nitride layers 302 again are allowed to coalesce 303, and subsequent III-nitride device layers 106 are formed. As a result, embedded DBR mirrors 301 can be formed between the first ELO III-nitride layer 105 and the second ELO III-nitride layer 302. In addition, there is a current limiting region 304, p-pad 305, bonding layer 306, carrier 307, current confinement layer 308, current spreading layer 309, n-GaN layer 310, n-pads 311 deposited to contact the n-GaN layer 310 on an opposite side of an interface 312, and second DBR mirror 313.

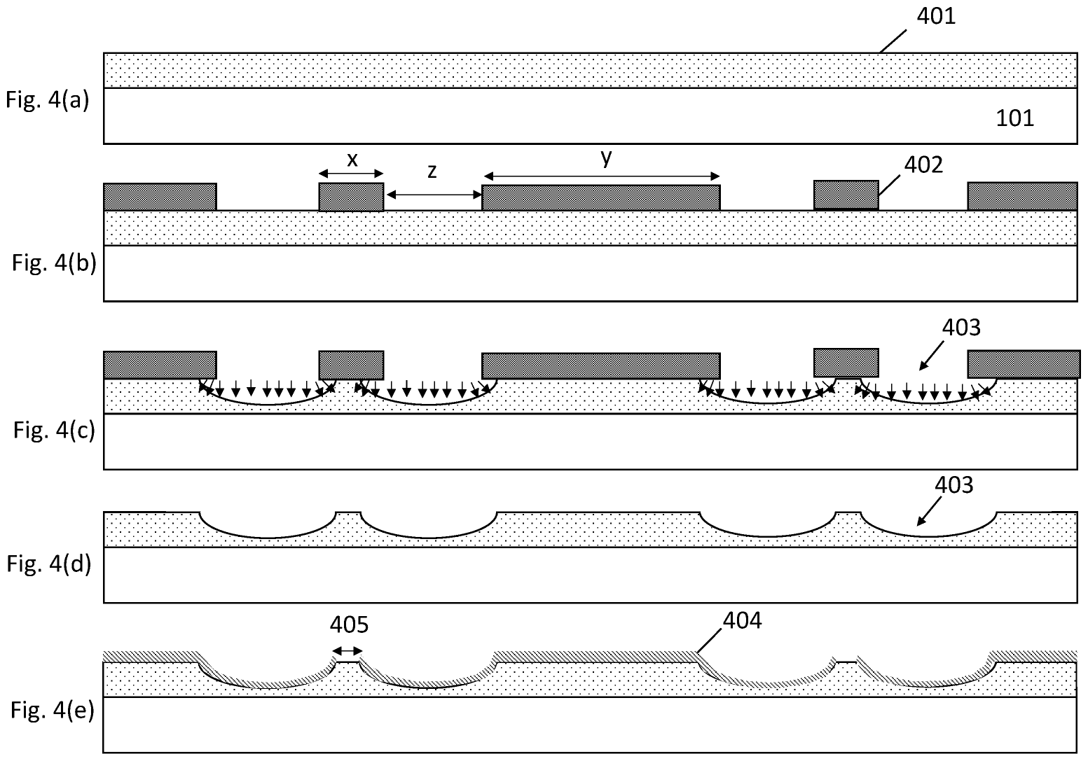

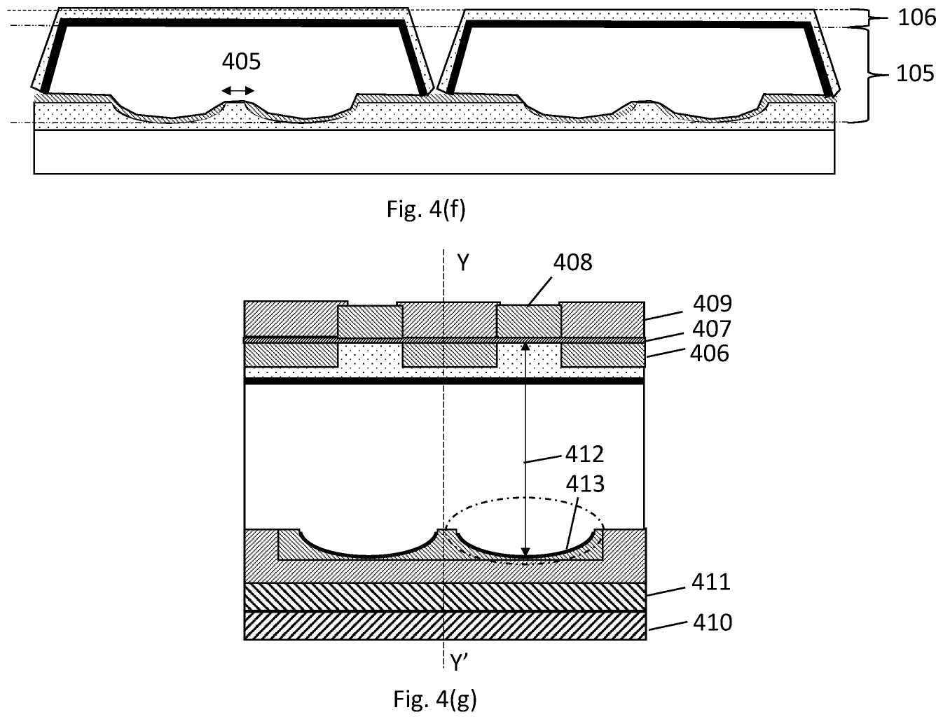

FIGS. 4(a), 4(b). 4(c), 4(d) and 4(e) are cross-sectional views of a process to obtain a concave shaped patches on a III-nitride substrate 101, wherein the patches can be used to form a curved light reflecting mirror on an n-side by allowing the III-nitride ELO III-nitride layer 105 to flow into the designed shape from the open region 103, FIG. 4(f) is a cross-sectional view of formed island-like III-nitride semiconductor layers 109 on a processed substrate 101, and FIG. 4(g) is a VCSEL device 111 fabricated using the substrate 101. These figures are described in more detail below.

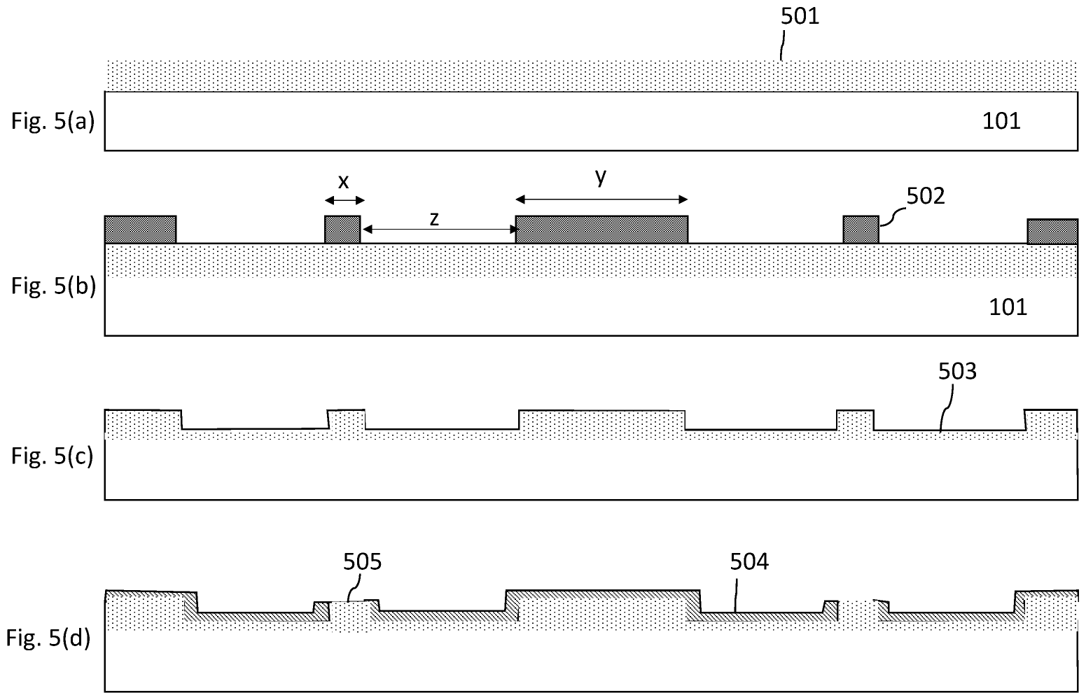

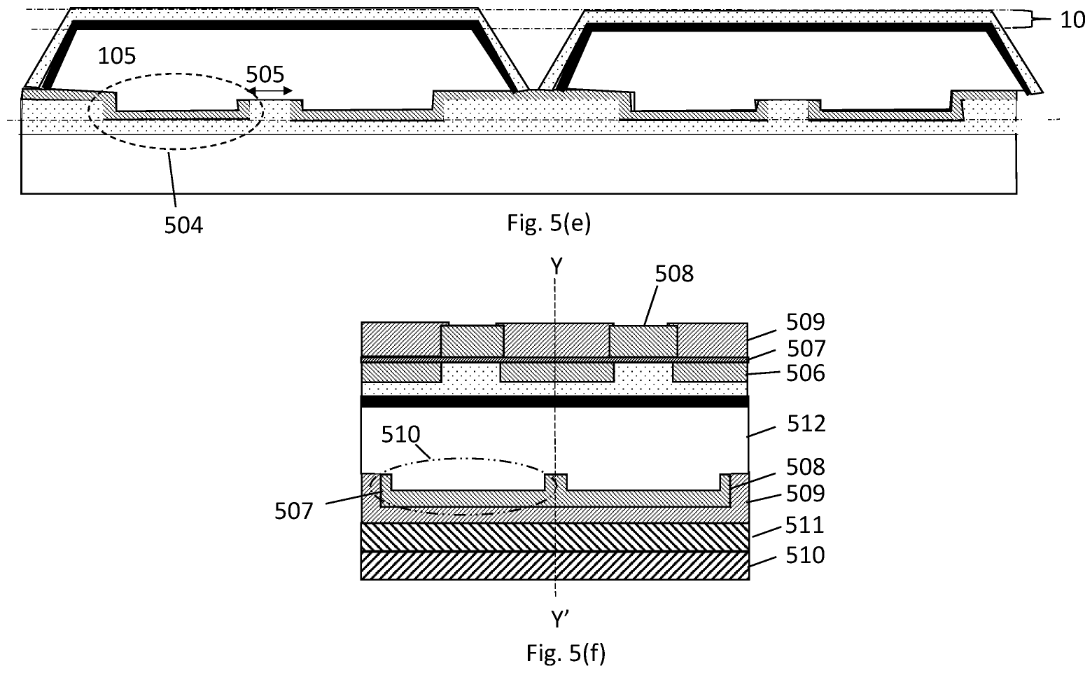

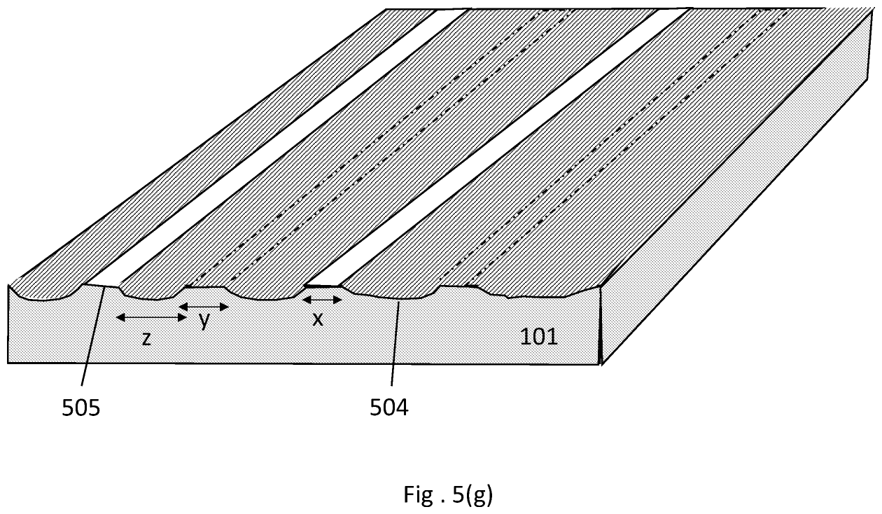

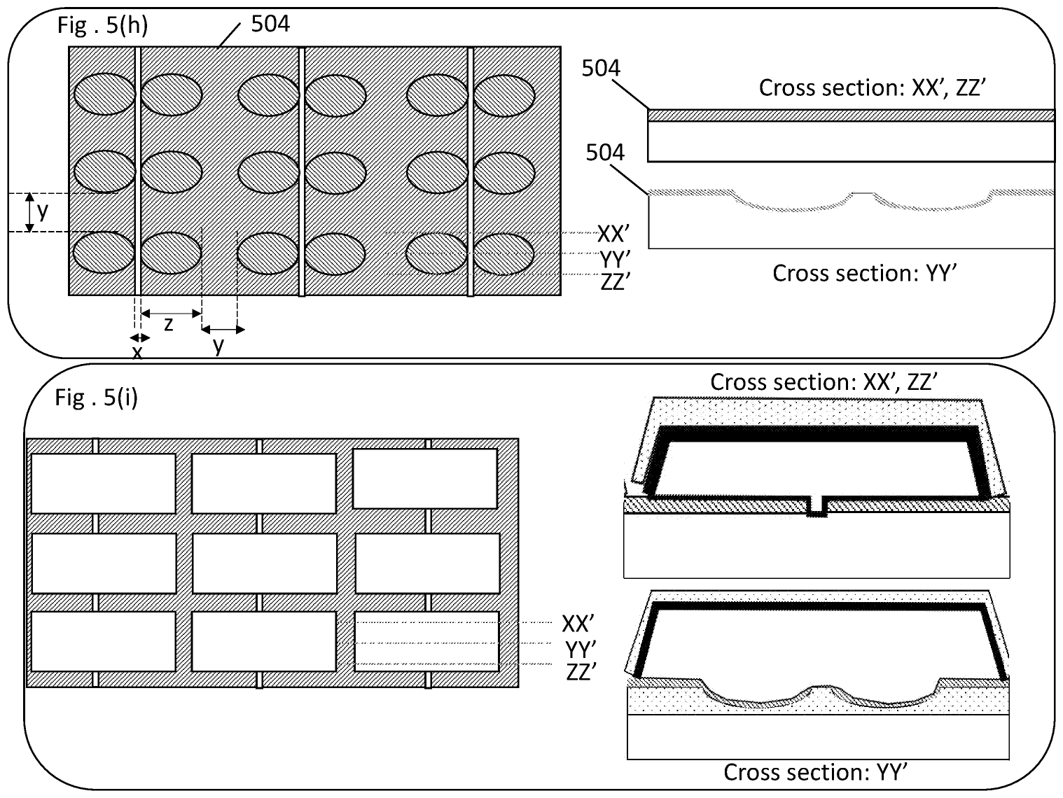

FIGS. 5(a), 5(b). 5(c) and 5(d) are cross-sectional views of a process to obtain irregular (rectangular, tapered etc.) shaped patches on a III-nitride substrate 101, wherein the patches can be used to form a designed shape light reflecting mirror on an n-side by allowing the ELO III-nitride layer 105 to flow into the designed shape from the open region 103, FIG. 5(e) is a cross-sectional view of formed island-like III-nitride semiconductor layers 109 on a processed substrate 101, FIG. 5(f) is a VCSEL device 111 fabricated using the substrate 101 prepared in FIG. 5(d), FIG. 5(g) is a patterned host substrate 101 with a two-period growth restrict mask 102 structure in the form of stripes, where the dips near the open area 103 assist in forming ELO III-nitride layers 105 of a patterned shape, FIG. 5(h) is a patterned host substrate 101 in the form of patches, and FIG. 5(i) is a graphical representation when device layers 106 are formed on the pre-patterned host substrate 101. These figures are described in more detail below.

In one embodiment, as shown in FIGS. 4(a)-4(g) and 5(a)-5(i), the III-nitride substrate 101 is pre-processed to form curved or irregular shape patches. Then, the ELO III-nitride based layers 105 are allowed to grow from the open regions 103, as described earlier. The grown ELO III-nitride layers 105 in this case take the shape of the mask 102 region, thus forming self-formed curved or irregular mirrors for the resonant cavity of long cavity VCSEL devices 111.

The typical fabrication steps for this invention are described in more detail below:
Step 1: Forming a growth restrict mask 102 with a plurality of striped opening areas 103 directly or indirectly upon a substrate 101, wherein the substrate 101 is a III-nitride-based semiconductor or the substrate 101 is a hetero-substrate.
Step 2: Growing a plurality of epitaxial layers 105, 106 and 109 upon the substrate 101 using the growth restrict mask 102, such that the growth extends in a direction parallel to the striped opening areas 103 of the growth restrict mask 102, wherein the ELO III-nitride layers 105 do not coalesce.
Step 3: Fabricating the device 111 at the ELO window region mostly covered by flat surface region 107 by conventional methods, wherein a light reflective element structure (DBR), p-electrode, n-electrode, pads, etc., are deposited at pre-determined positions.
Step 4: Forming a structure for separating devices 111.
Step 5: The ELO III-nitride layers 105 are removed from substrate 101 using process #1 or #2.

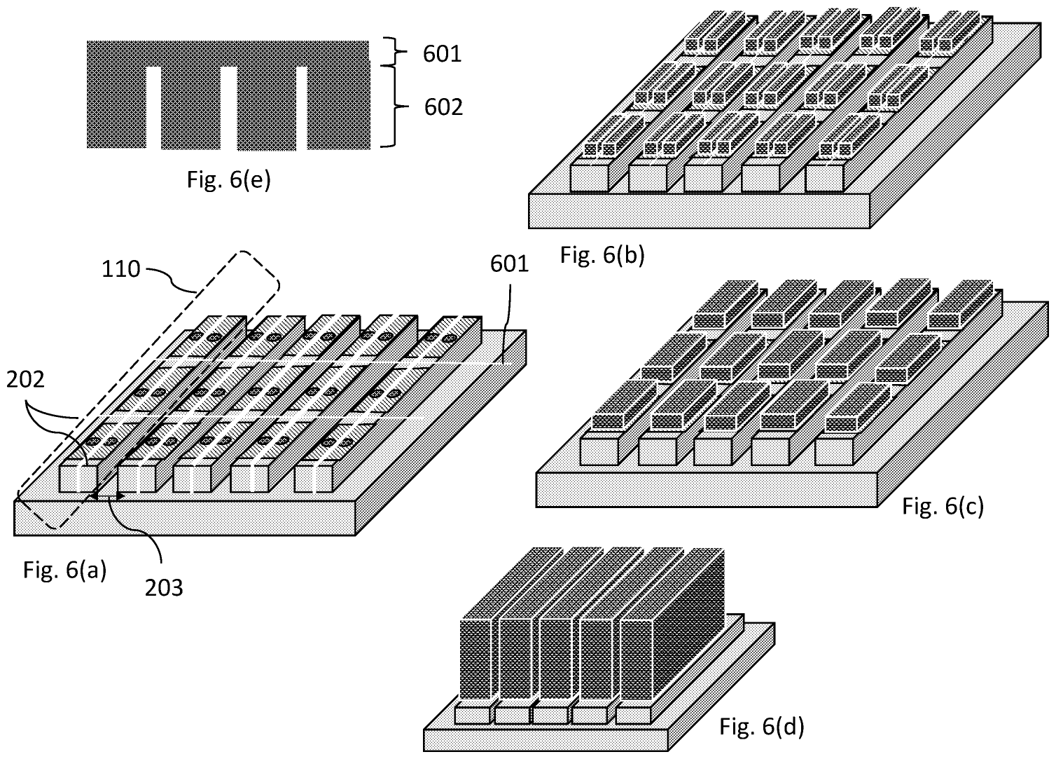

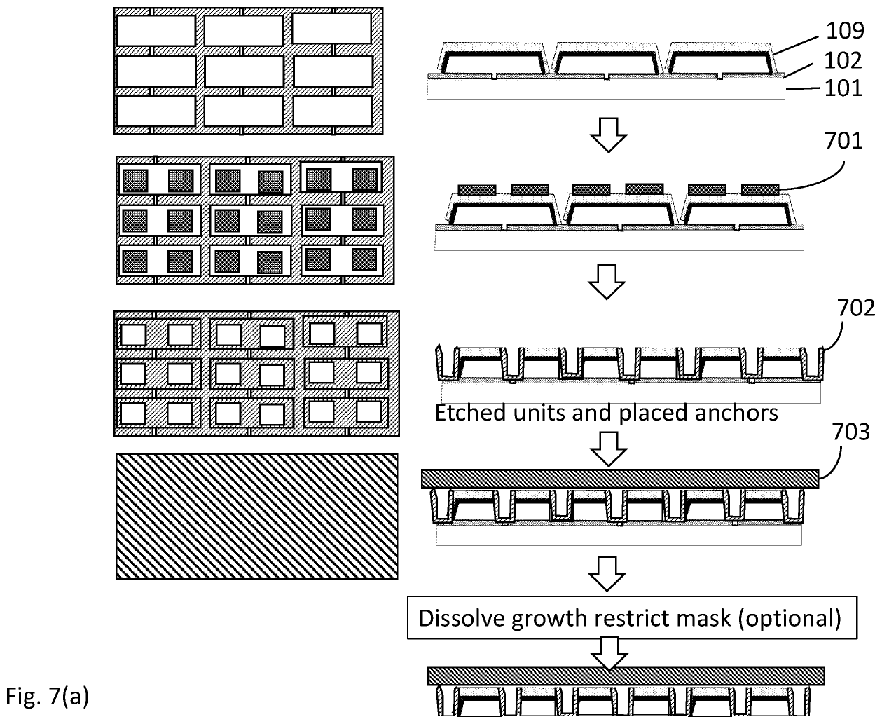

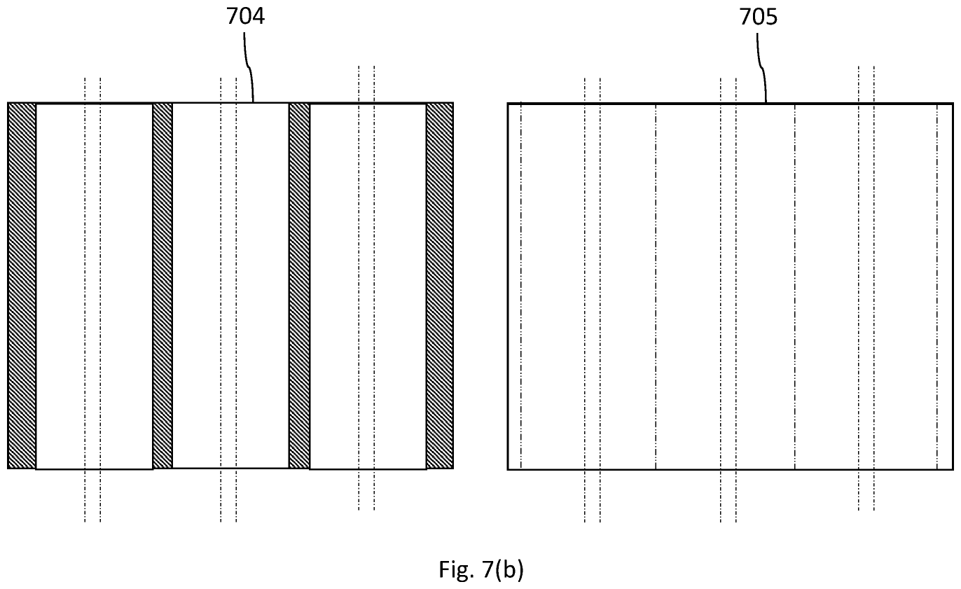

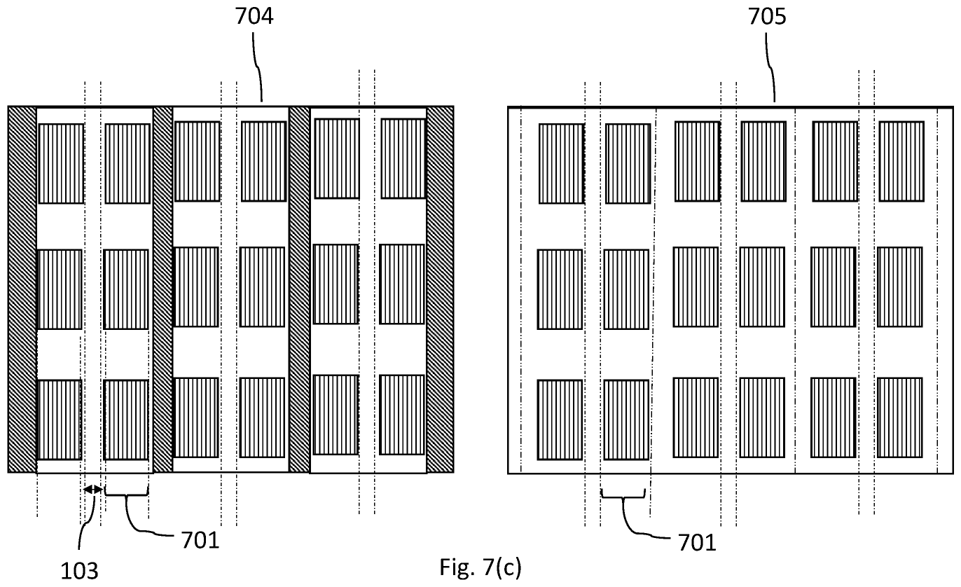

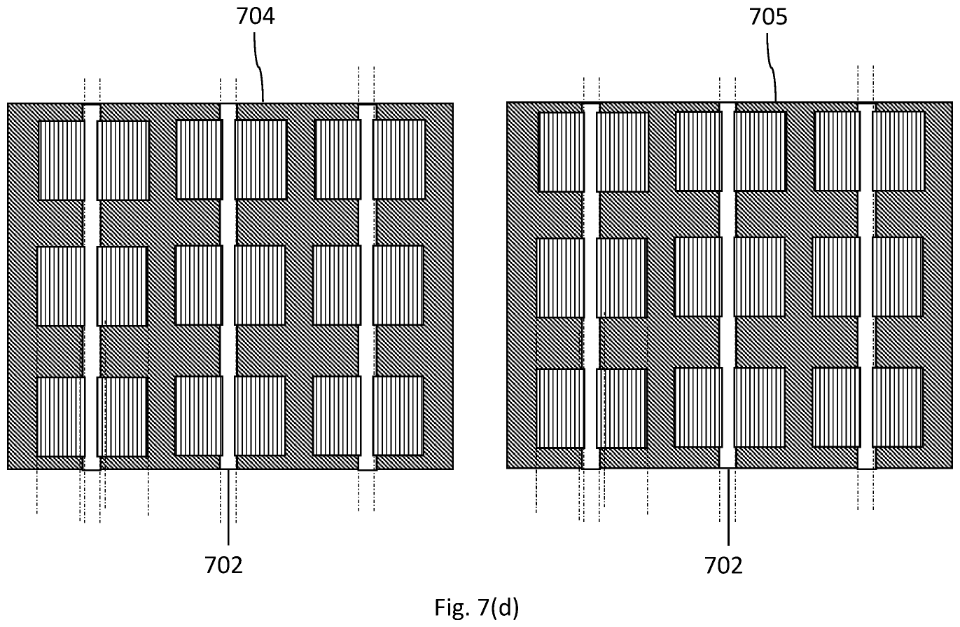

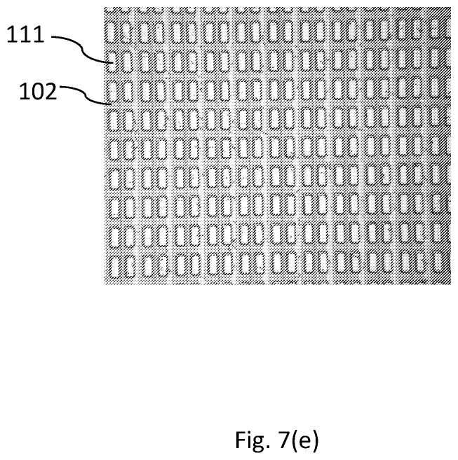

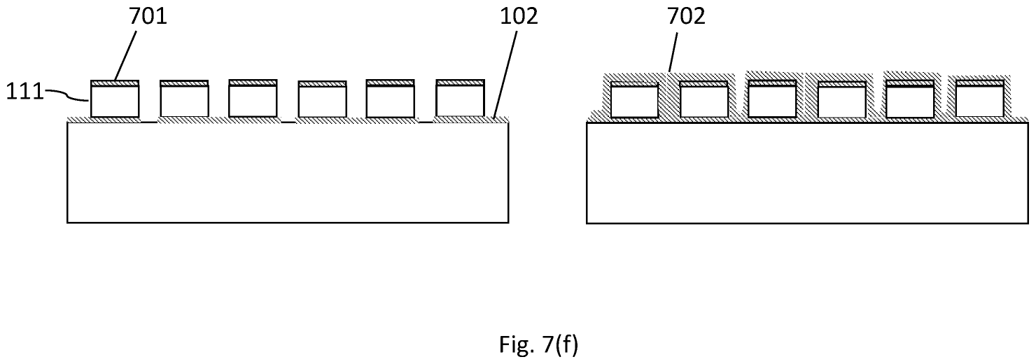

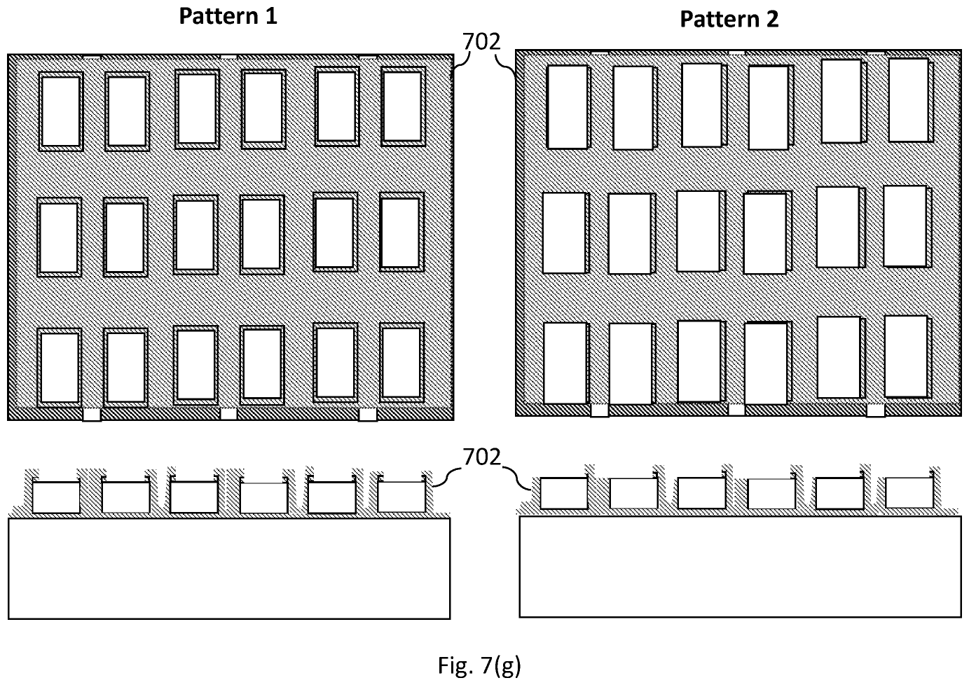

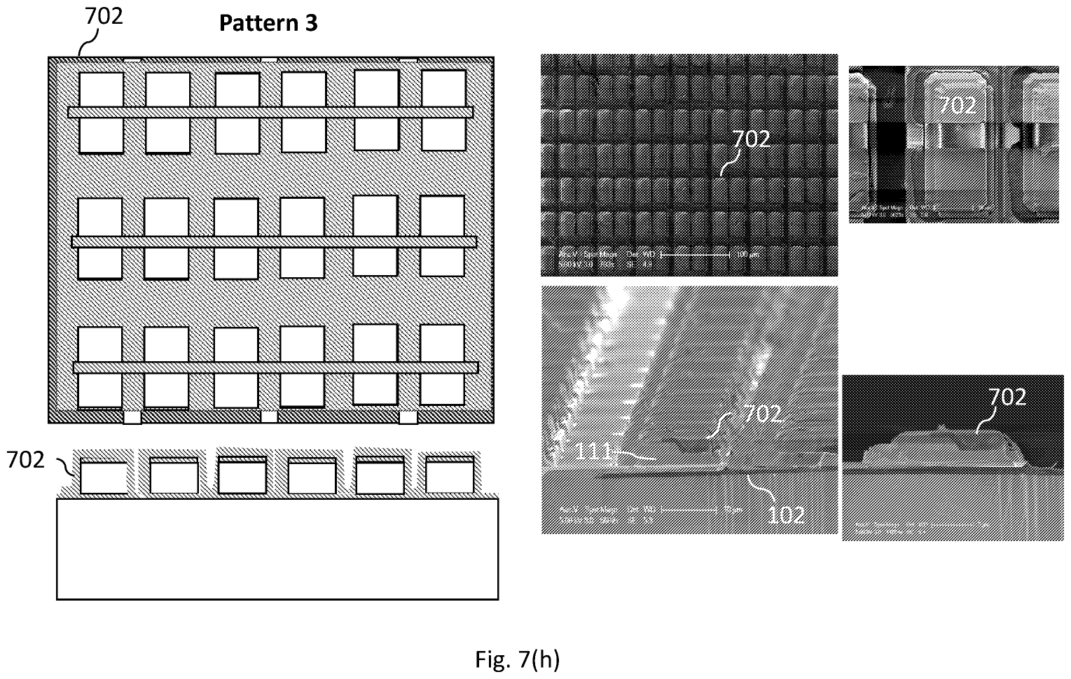

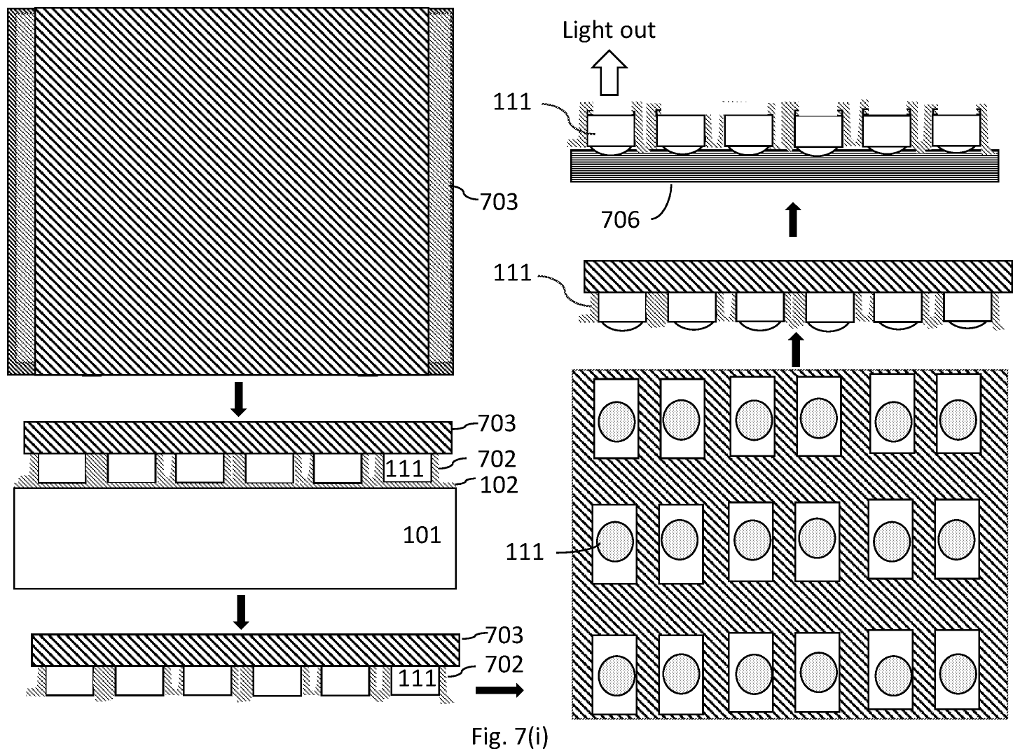

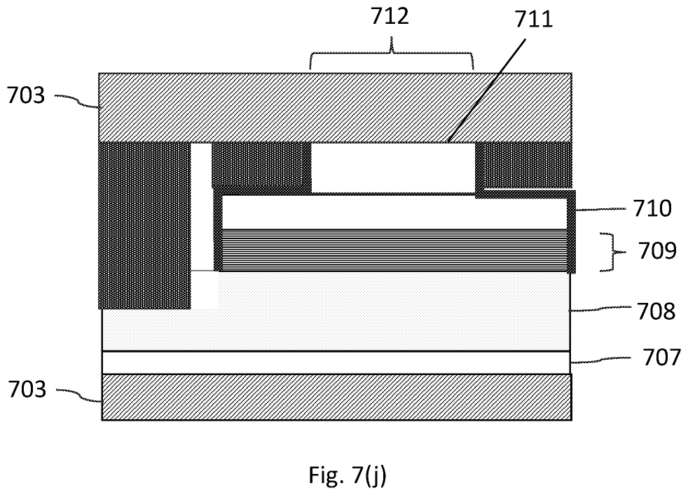

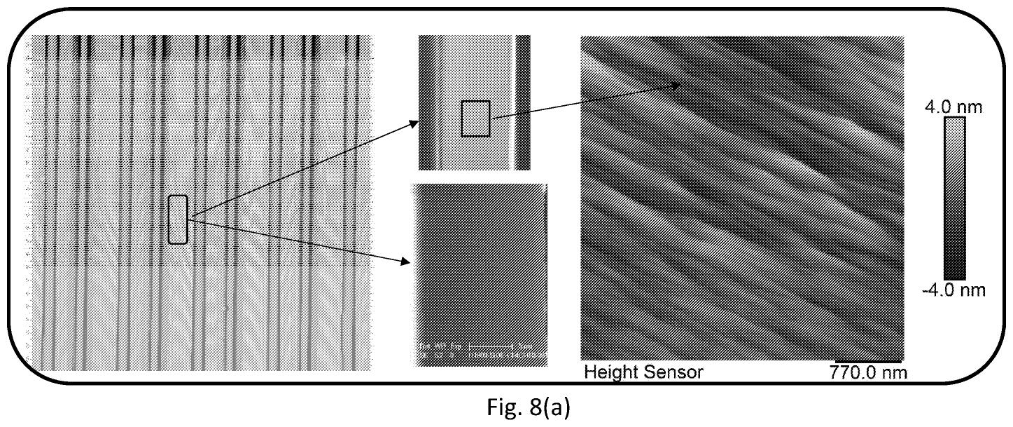

In process #1, the open region of the ELO III-nitride layer 105 is referred to as Region 1 and the region at the which the neighboring ELO III-nitride layer 105 wings meet or may not meet is referred to as Region 2:
1. Region 1 202 and Region 2 203 are etched at least to expose growth restrict mask 102 and the ELO III-nitride layers 105. The individual devices 111 are divided as shown in FIGS. 6(a)-6(e), which illustrate how dividing regions 202, 203 are formed at periodic lengths along a bar 110 of the devices 111, and how a supporting plate 601 can be attached on the bar 110 of devices 111. The supporting plate 601 may have finger-like structures 602 for supporting the bars 110 of devices 111 or individual devices 111 themselves.
2. A hook layer or an assist layer is placed on the devices 111 to avoid floating of the ELO III-nitride layers 105. Preferably, a dielectric layer, for example, SiO₂ may be place between the devices 111 such that newly placed dielectric rests on exposed growth restrict mask 102 via anchoring divided devices 111. The strength of the anchors can be controlled by the thickness of the newly placed dielectric layer. This is shown in FIGS. 7(a)-7(j), wherein FIG. 7(a) illustrates a possible removal method for layers 109 from the substrate 101 using a mask 701 for etching, a placed hook or anchor 702, and an attached receptor 703 followed by an optional step of dissolving the growth restrict mask 102; FIG. 7(b) illustrates non-coalesced and coalesced structures 704, 705 for a hooking process; FIG. 7(c) illustrates a disposed selective etched mask 701 where two types of etching masks 701 are shown;

FIG. 7(d) illustrates Type-1 etching to separate the III-nitride layers 109, where a hook 702 is from an open ELO window; FIG. 7(e) illustrates Type-2 etching where an optical microscope image shows devices 111 sandwiched between a growth restrict mask 102 and an etching mask 701; FIG. 7(f) illustrates devices 111 sandwiched between a growth restrict mask 102 and an etching mask 701 in Step 2, and placement of a secured chip layer 702 in Step 3; FIG. 7(g) illustrates a secured chip layer 702 that is selectively etched to obtain various hook patterns; FIG. 7(h) illustrates optical and scanning electron microscope images of hooked devices 111; FIG. 7(i) illustrates a process for fabricating a curved mirror 706 on an n-side epitaxial layer of a VCSEL device 111; and FIG. 7(j) illustrates fabrication of a dual-clad Fabry-Perot (FP) laser device 111 using a hooking process, wherein the FP laser device 111 is sandwiched between two carrier plates 703, and is comprised of a cladding layer 707, n-GaN and waveguide layers 708, single or multiple quantum wells 709, electron blocking, p-GaN and waveguide layers 710 and a cladding layer 711, with a ridge structure 712.
3. As noted above, devices 111 are bonded to one or more carriers 703, which can be a substrate, or a polymer film with some adhesive or having some vacuum holes to hold the devices 111, or a temporary transit place before transferring to a functional electrode containing substrate, or a glued highly UV transparent substrate that is sensitive to UV lasers.
4. Skip to Step 6, or the devices 111 can be mechanically separated either by using sonication or by gentle peeling.

In process #2, the removal method follows Step 4 and etches accordingly. The second process leaves open area 202 of the ELO III-nitride layers 105 un-etched. Carriers, supporting plates, receptors or recipients, are attached to divided devices 111. Alternatively, divided ELO III-nitride layers 105 can be removed by a polymer film having an adhesive attachment layer, as described below in Step 7.

In process #2, Step 6 can be performed before or after Step 4 as an open region, which is a weak connection region between the ELO III-nitride layer 105 and its growth substrate 101, keeps the layers 105 from floating away or falling apart.
Step 6: Dissolving the growth restrict mask 102 by wet etching.
Step 7: Removing the devices 111 from the substrate 101.
   Step 7.1: Attaching a polymer film to the devices 111. More preferably, devices 111 are first attached to supporting plates, as shown in FIGS. 6(a)-6(e), and a polymer film is placed over the devices 111 and supporting plates.
   Step 7.2: Applying pressure to the polymer film such that the polymer film wraps at least a top surface and partially adjacent faces of the devices 111, and more preferably, the polymer film wraps the top surface of the supporting plate and covers partially its side facets.
   Step 7.3: Reducing the temperature of the film and the substrate 101 while pressure is applied.
   Step 7.4: Thermal stress between the devices 111 and polymer film separates the devices 111 from their host substrate 101.

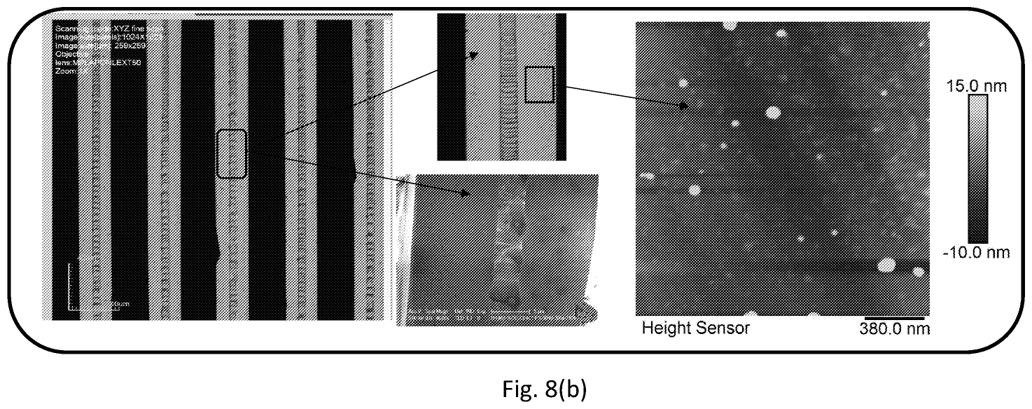

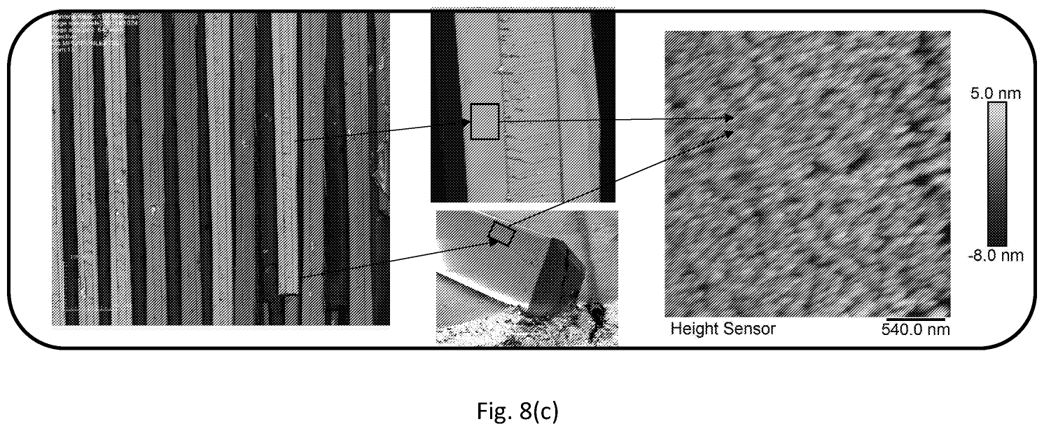

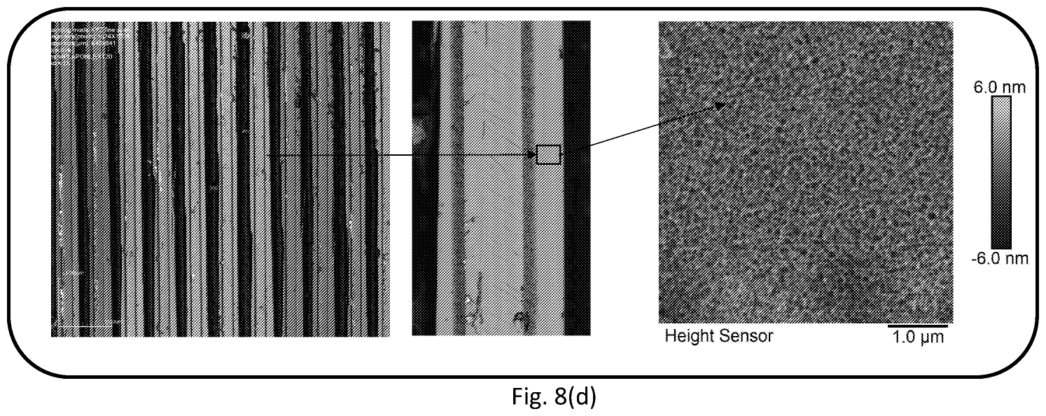

After separation by either process #1 or #2, the ELO III-nitride layers 105 or the devices 111 are attached directly or indirectly to the polymer film facing an exposed interface between ELO III-nitride layer 105 and growth restrict mask 102. The interface is smooth enough to place a second DBR mirror to complete the resonant cavity of the VCSEL device 111. This is illustrated in FIGS. 8(a)-8(d), which illustrate ELO III-nitride layer 105 growth and interface surface morphology measurements, wherein FIG. 8(a) shows images of c-plane ELO III-nitride layer 105 growth and interface surface morphology measurements after removal, FIG. 8(b) shows images of semipolar 20-21 plane ELO III-nitride layer 105 growth and interface surface morphology measurements after removal, and FIGS. 8(c) and 8(d) show images of nonpolar 10-10 plane ELO III-nitride layer 105 growth and interface surface morphology measurements after removal for two different growth restrict mask 102 patterns.
Step 8: Fabricating a second light reflective element, i.e., a DBR mirror, on the interface between the ELO wing region and growth restrict mask 102, and more preferably, on the wing region of the ELO III-nitride layer 105 slightly away from the open area 103, for example, slightly more than a 1 μm or 2 μm space can be left from the open area 103 to place a second DBR on the ELO wing region.

There are alternatives to placing a second DBR mirror onto the ELO wing interface:
(1) For example, an externally prepared DBR mirror substrate can be attached to the back surface of the removed III-nitride epitaxial layers 105, 106, 109 either by surface activation bonding or diffusion pressure bonding or by some other means, such that the top and bottom DBR mirrors of the removed III-nitride epitaxial layers 105, 106, 109 at the wing region of the ELO III-nitride layers 105 can be used as a resonant cavity of the VCSEL device 111; alternatively, external DBRs can be replaced with epitaxial light reflecting layers, such as AlInN/GaN, to improve the thermal performance of the VCSEL device 111.
(2) Deposition of DBR mirror layers onto an interface of the removed III-nitride ELO wing region.
Step 9: Fabricating an n-electrode at a separate area of the device 111 (the top and bottom electrode configuration need an n-electrodeposition after the second DBR layer is placed).
Step 10: Breaking the bars 110 into separate devices 111 (can be performed after Step 3).
Step 11: Mounting each device 111 on a heat sink plate, such as SiC, AlN, etc.
Step 12: Dividing the heat sink plate to separate the devices 111.

These steps are explained in more detail below.

Process Steps

Step 1: Forming a Growth Restrict Mask

In one embodiment, the III-nitride layers 105 are grown by ELO on a III-nitride substrate 101, such as an m-plane GaN substrate 101, patterned with a growth restrict mask 102 comprised of SiO₂, wherein the ELO III-nitride layers 105 do not coalesce on top of the SiO₂.

The growth restrict mask 102 is comprised of striped opening areas 103, wherein the SiO₂ stripes of the growth restrict mask 102 between the opening areas 103 have a width of 1 μm-20 μm and an interval of 30 μm-150 μm, if a nonpolar substrate 101 used the opening areas 103 are oriented along a <0001> axis. If semipolar (20-21) or (20-2-1) planes are used, the opening areas 103 are oriented in a direction parallel to [−1014] or [10-14], respectively. Other planes may be use as well, with the opening areas 103 oriented in other directions.

When using a III-nitride substrate 101, the present invention can obtain high quality III-nitride semiconductor layers 105, 106, 109, and avoid bowing or curvature of the substrate 101 during epitaxial growth due to homo-epitaxial growth. As a result, the present invention can also easily obtain devices 111 with reduced defect density, such as reduced dislocation and stacking faults.

Moreover, these techniques can be used with a hetero-substrate 101, such as sapphire, SiC, LiAlO₂, Si, etc., as long as it enables growth of the ELO III-nitride layers 105 through the growth restrict mask 102.

Step 2: Growing a Plurality of Epitaxial Layers on the Substrate Using the Growth Restrict Mask

At Step 2, the III-nitride semiconductor device layers 106 are grown on the ELO III-nitride layers 105 in the flat region 107 by conventional methods. In one embodiment, MOCVD is used for the epitaxial growth of the island-like III-nitride semiconductor layers 109, including the ELO III-nitride layers 105 and the III-nitride semiconductor device layers 106. In one embodiment, the island-like III-nitride semiconductor layers 109 are separated from each other, because the MOCVD growth is stopped before the ELO III-nitride layers 105 coalesce. In another embodiment, the island-like III-nitride semiconductor layers 109 are made to coalesce and later etching is performed to remove unwanted regions.

Trimethylgallium (TMGa), trimethylindium (TMIn) and triethylaluminium (TMAl) are used as III elements sources. Ammonia (NH₃) is used as the raw gas to supply nitrogen. Hydrogen (H₂) and nitrogen (N₂) are used as a carrier gas of the III elements sources. It is important to include hydrogen in the carrier gas to obtain a smooth surface epi-layer.

Saline and Bis(cyclopentadienyl)magnesium (Cp₂Mg) are used as n-type and p-type dopants. The pressure setting typically is 50 to 760 Torr. III-nitride-based semiconductor layers are generally grown at temperature ranges from 700 to 1250° C.

For example, the growth parameters include the following: TMG is 12 sccm, NH₃ is 8 slm, carrier gas is 3 slm, SiH₄ is 1.0 sccm, and the V/III ratio is about 7700.

ELO of Limited Area Epitaxy (LAE) III-Nitride Layers

In the prior art, a number of pyramidal hillocks have been observed on the surface of m-plane III-nitride films following growth. See, for example, US Patent Application Publication No. 2017/0092810. Furthermore, a wavy surface and depressed portions have appeared on the growth surface, which made the surface roughness worse. This is a very severe problem when an VCSEL structure is fabricated on the surface. For that reason, it is better to grow the epitaxial layers 105, 106, 109 on a nonpolar and semipolar substrate 101, which is well known to be difficult.

For example, according to some papers, a smooth surface can be obtained by controlling an off-angle (>1 degree) of the substrate's 101 growth surface, as well as by using an N₂ carrier gas condition. These are very limiting conditions for mass production, however, because of the high production costs. Moreover, GaN substrates 101 have a large fluctuation of off-angles to the origin from their fabrication methods. For example, if the substrate 101 has a large in-plane distribution of off-angles, it has a different surface morphology at these points in the wafer. In this case, the yield is reduced by the large in-plane distribution of the off-angles. Therefore, it is necessary that the technique does not depend on the off-angle in-plane distribution.

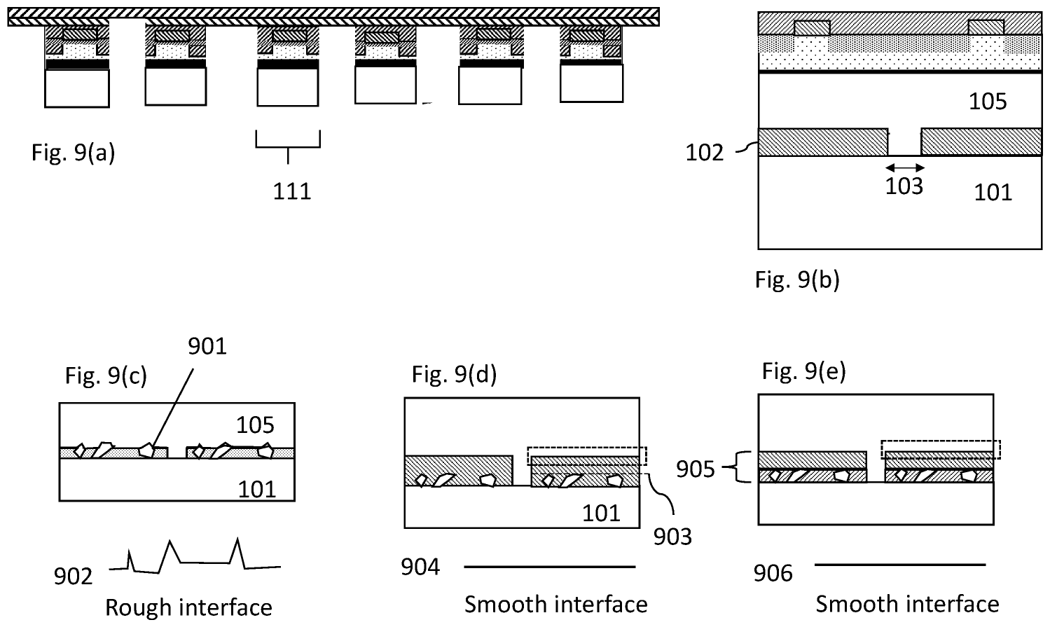

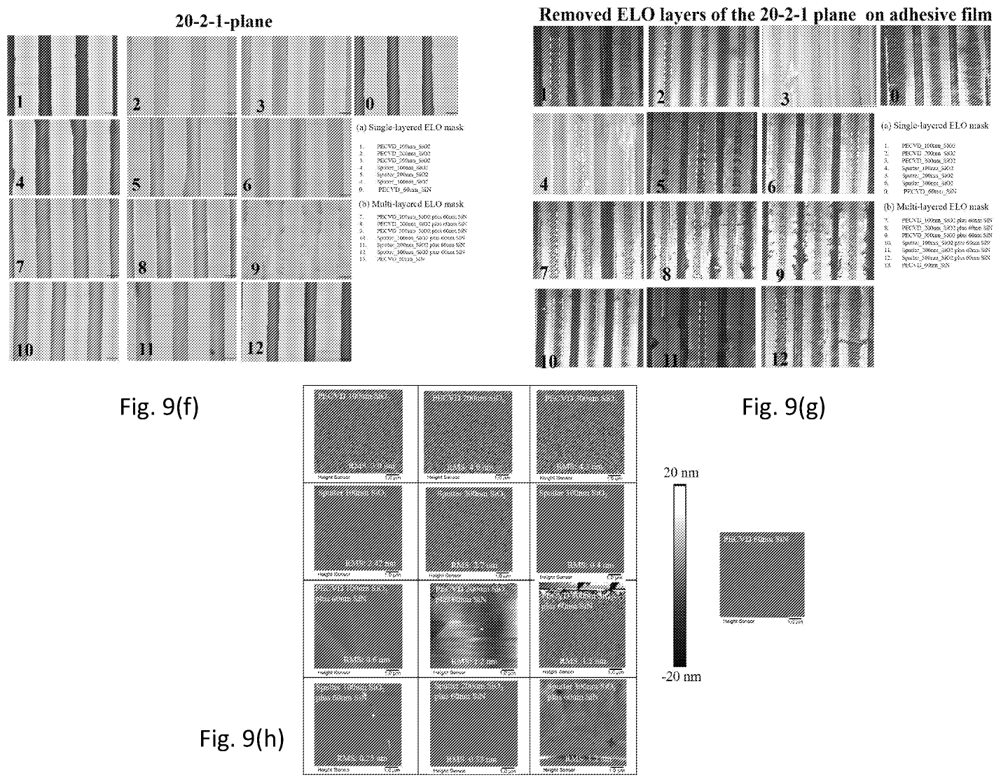

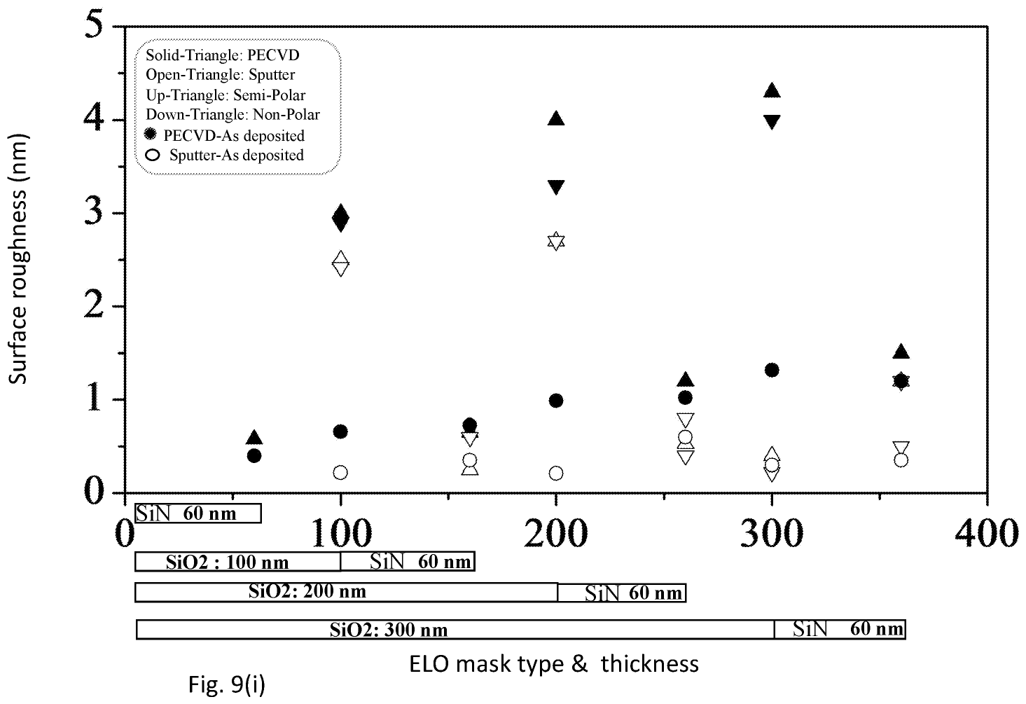

The present invention solves these problem as set forth below.
1. The growth area is limited by the area of the growth restrict mask 102 from the edges of the substrate 101.
2. The substrate 101 is a nonpolar or semipolar III-nitride substrate 101 that has off-angle orientations ranging from −16 degrees to +30 degrees from the m-plane towards the c-plane. Alternatively, a hetero-substrate 101 with a III-nitride-based semiconductor layer deposited thereon may be used, wherein the layer has an off-angle orientation ranging from +16 degrees to −30 degrees from the m-plane towards the c-plane.
3. The island-like III-nitride semiconductor layers 109 have a long side that is perpendicular to an a-axis of the III-nitride-based semiconductor crystal.
4. During MOCVD growth, a hydrogen atmosphere can be used.
5. The island-like III-nitride semiconductor layers 109 do not coalesce with each other.
6. In other embodiments, the growth restrict mask 102 or light reflecting mirror element was placed on wing region of the primarily grown island-like III-nitrite base semiconductor layer, as shown in FIGS. 9(a)-9(e), wherein FIGS. 9(a), 9(b), 9(c), 9(d), and 9(e) illustrate controlling the interface of the bottom of the ELO III-nitride layer for fabricating one of the DBR mirrors of the resonant cavity VCSEL. These figures are described in more detail below.
7. MOCVD growth was carried to embed the secondly placed growth restrict mask 102 or light reflecting mirror

Using at least steps #1, #2 and #3 above, a bar 110 of the device 111 with a smooth surface is obtained. It is preferable that every one of steps #1, #2, #3, #4, #5, #6 and #7 above is performed.

Those results have been obtained by the following growth conditions.

In one embodiment, the growth pressure ranges from 60 to 760 Torr, although the growth pressure preferably ranges from 100 to 300 Torr to obtain a wide width for the island-like III-nitride semiconductor layers 109; the growth temperature ranges from 900 to 1200° C. degrees; the V/III ratio ranges from 1000-30,000 and more preferably 3000-10000; the TMG is from 2-20 sccm; NH₃ ranges from 3 to 10 slm; and the carrier gas is only hydrogen gas, or both hydrogen and nitrogen gases. To obtain a smooth surface, the growth conditions of each plane needs to be optimized by conventional methods.

After growing for about 2-8 hours, the ELO III-nitride layers 105 had a thickness of about 8-50 μm and a bar 110 width of about 20-150 μm, wherein the bar 110 width comprises the width of the island-like III-nitride semiconductor layers 109.

Step 3: Fabricating the Device

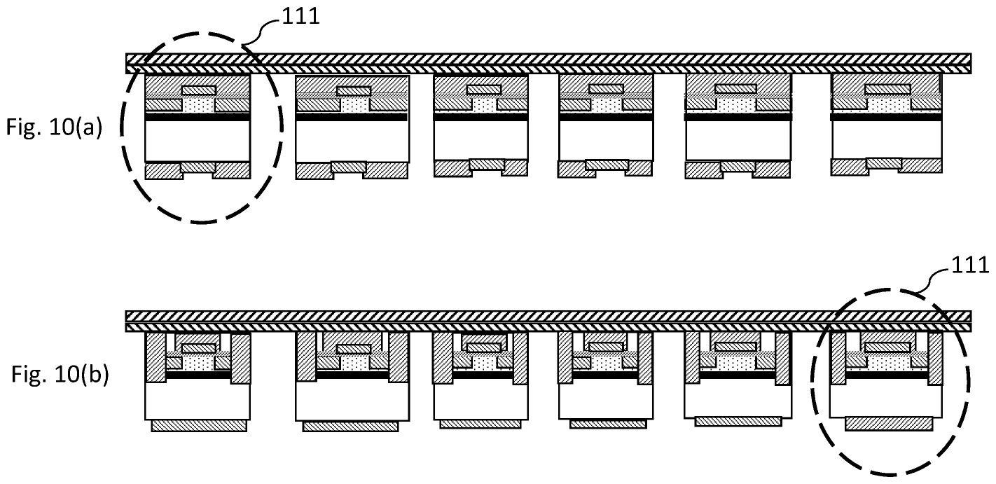

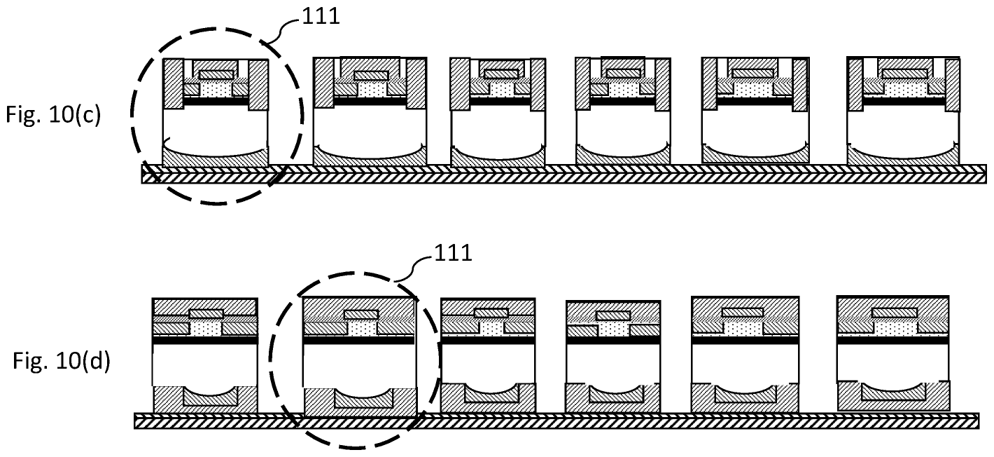

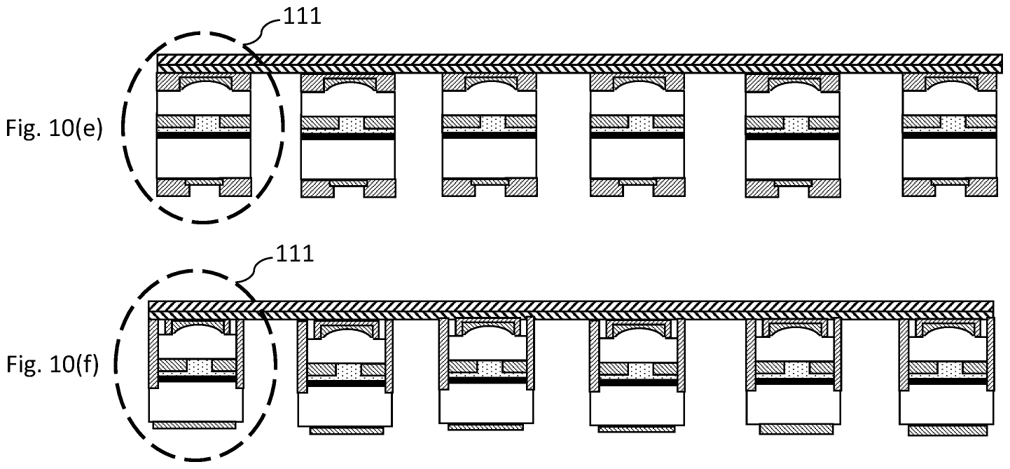

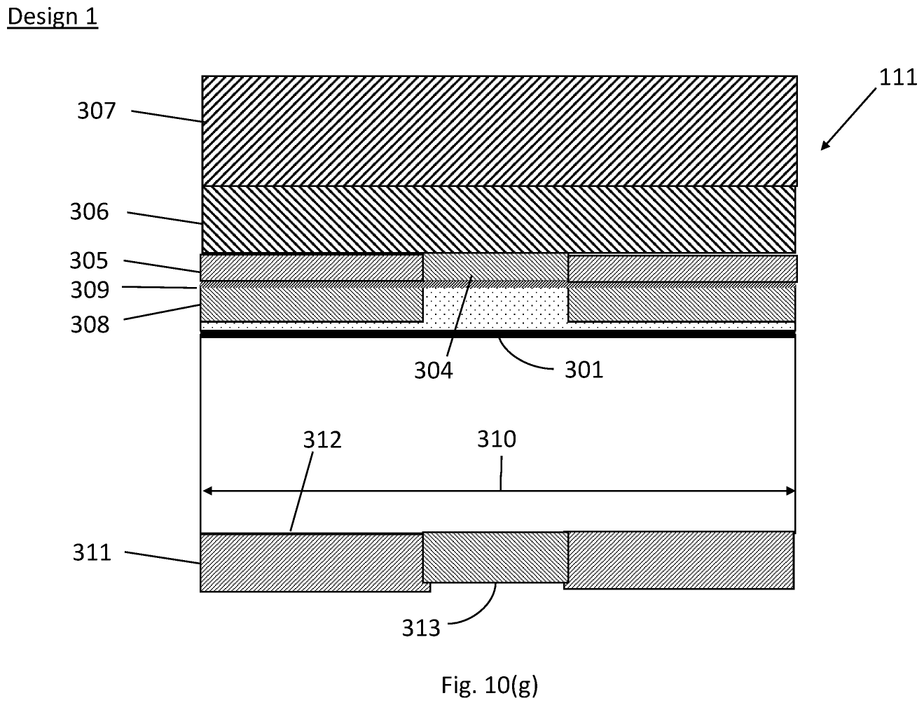

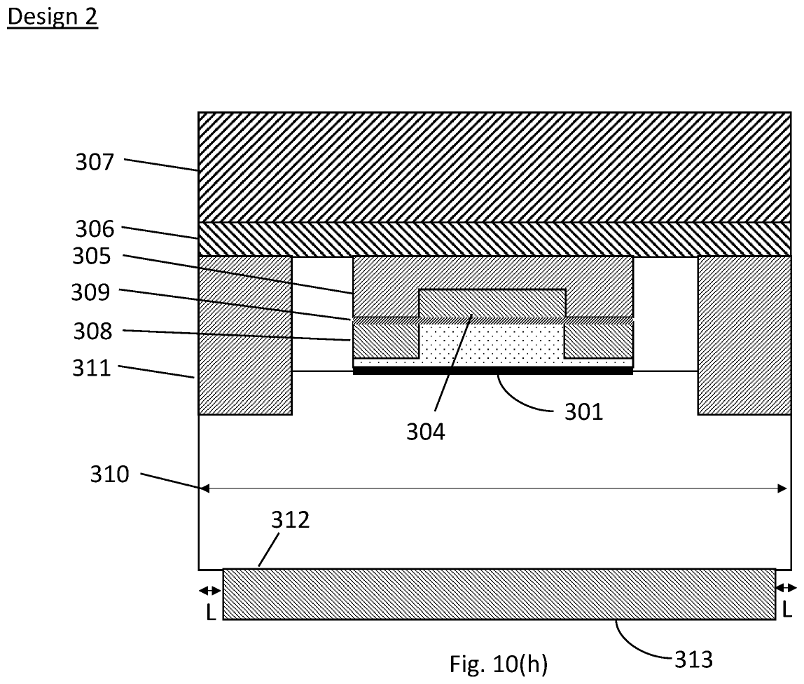

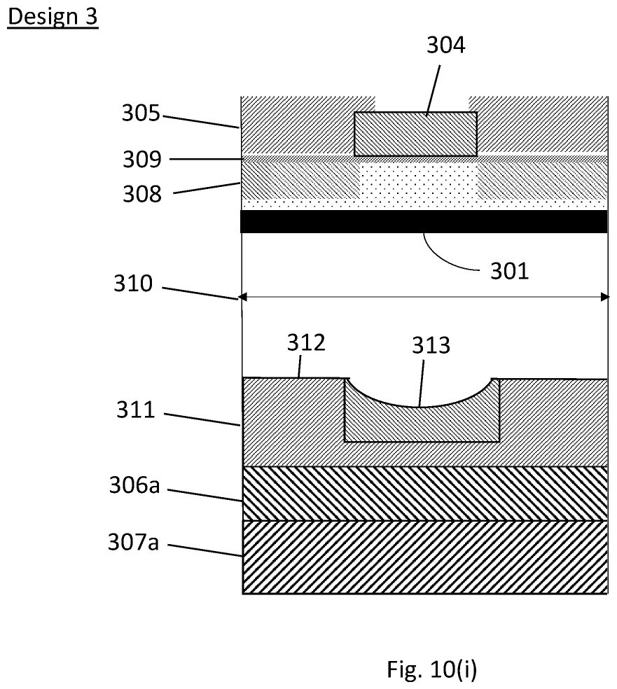

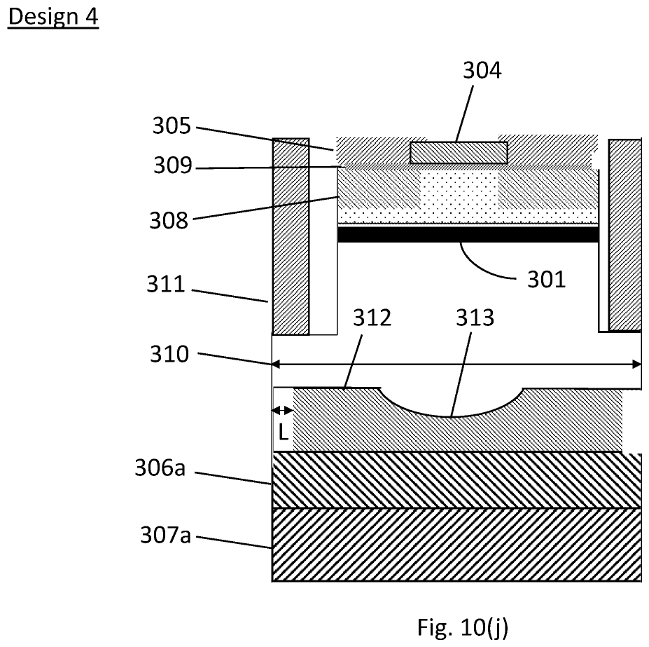

At Step 3, the device 111 is fabricated at the flat surface region 107 by conventional methods, wherein various device 111 designs are possible, as shown in FIGS. 10(a)-10(l), wherein FIGS. 10(a), 10(b), 10(c), 10(d), 10(e) and 10(f) are different possible designs of VCSEL devices 111.

FIG. 10(g) is a cross-sectional view of a single aperture VCSEL device 111 with a current limiting region 304, p-pad 305, bonding layer 306, carrier 307, current confinement layer 308, current spreading layer 309, n-GaN layer 310 and n-pads 311 are deposited to contact the n-GaN layer 310 on the opposite side of an interface 312, and second DBR mirror 313.

Similarly, FIG. 10(h) is a cross-sectional view of a single aperture VCSEL device 111 with same side electrodes formed from the island-like III-nitride semiconductor layers 109, FIG. 10(i) is a cross-sectional view of a single aperture VCSEL device 111 with opposite side electrodes and an n-side curved mirror 313 formed from the island-like III-nitride semiconductor layers 109, FIG. 10(j) is a cross-sectional view of a single aperture VCSEL device 111 with same side electrodes and an n-side curved mirror 313 formed from the island-like III-nitride semiconductor layers 109, FIG. 10(k) is a cross-sectional view of a single aperture VCSEL device 111 with opposite side electrodes and a p-side curved mirror 301 formed from the island-like III-nitride semiconductor layers 109, and FIG. 10(l) is a cross-sectional view of a single aperture VCSEL device 111 with same side electrodes and a p-side curved mirror 301 formed from the island-like III-nitride semiconductor layers.

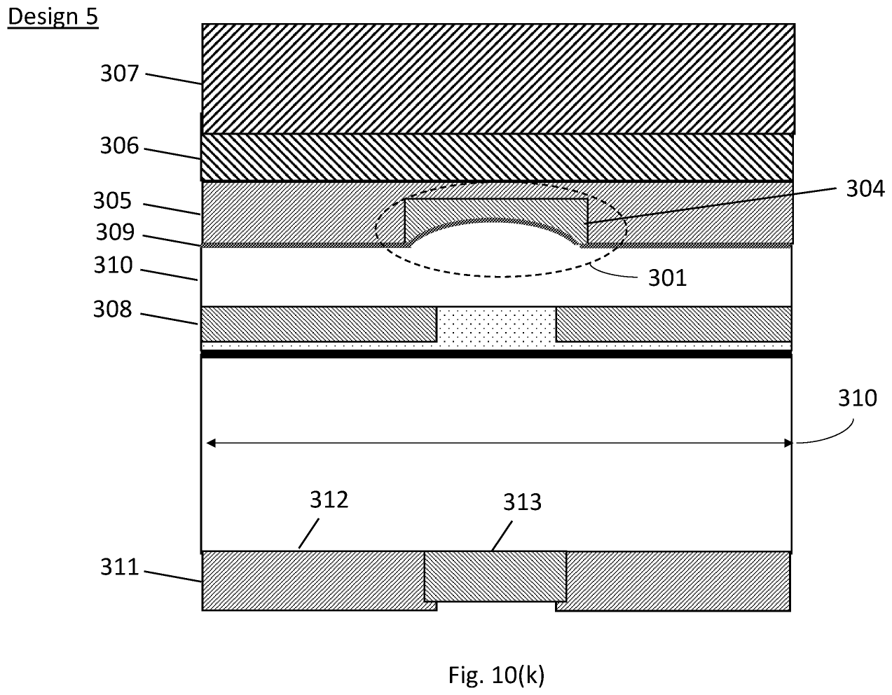

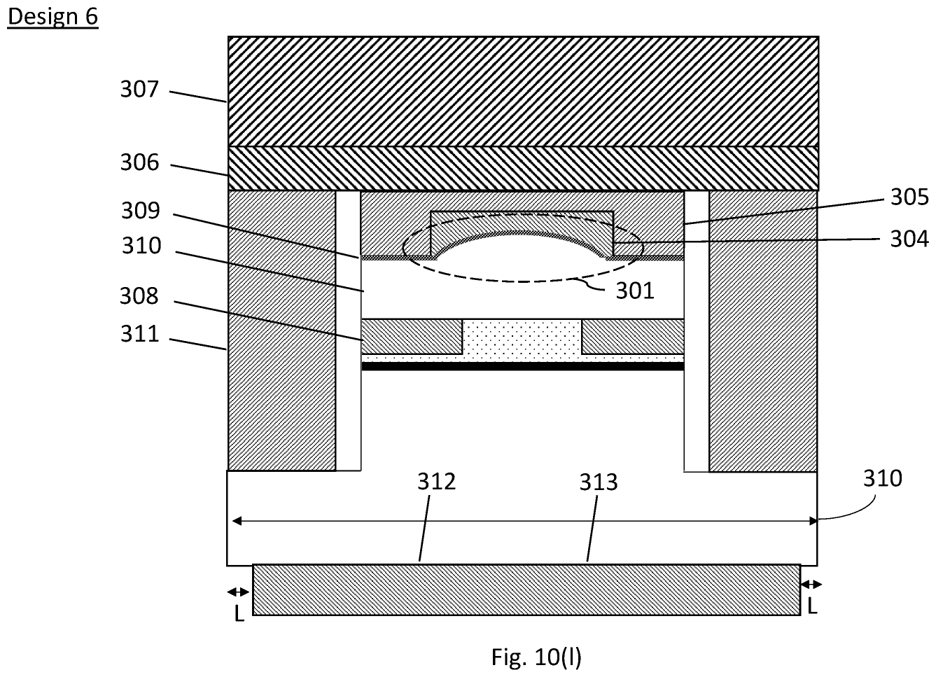

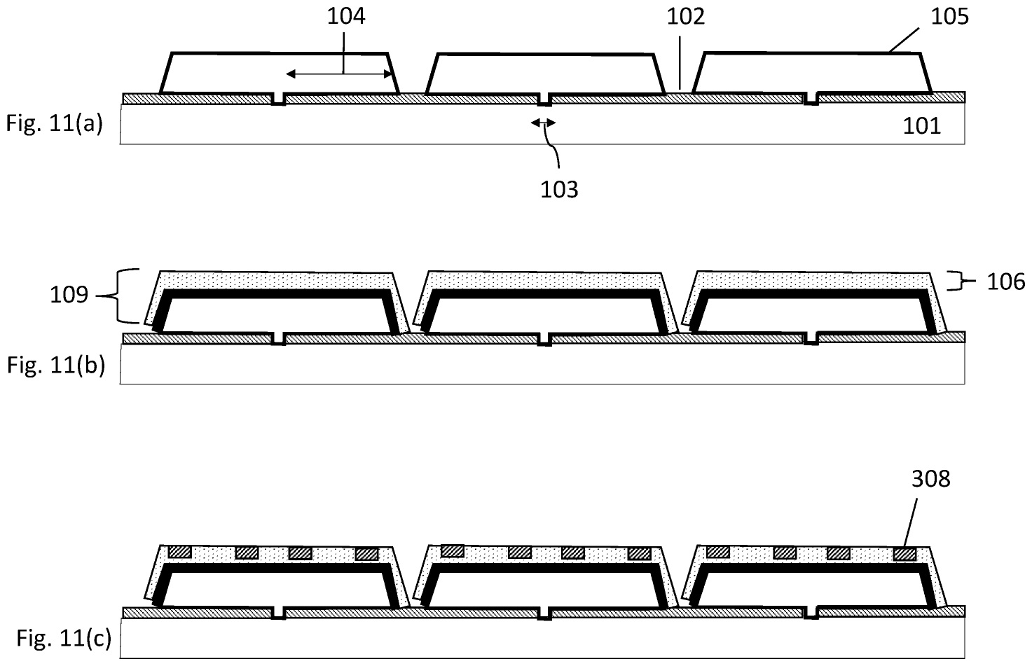

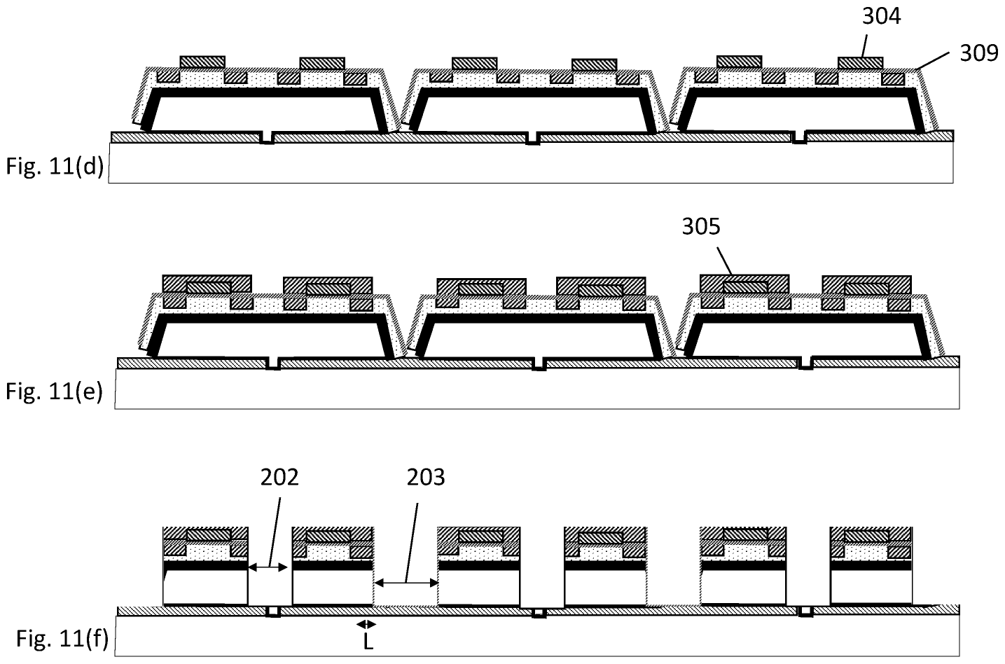

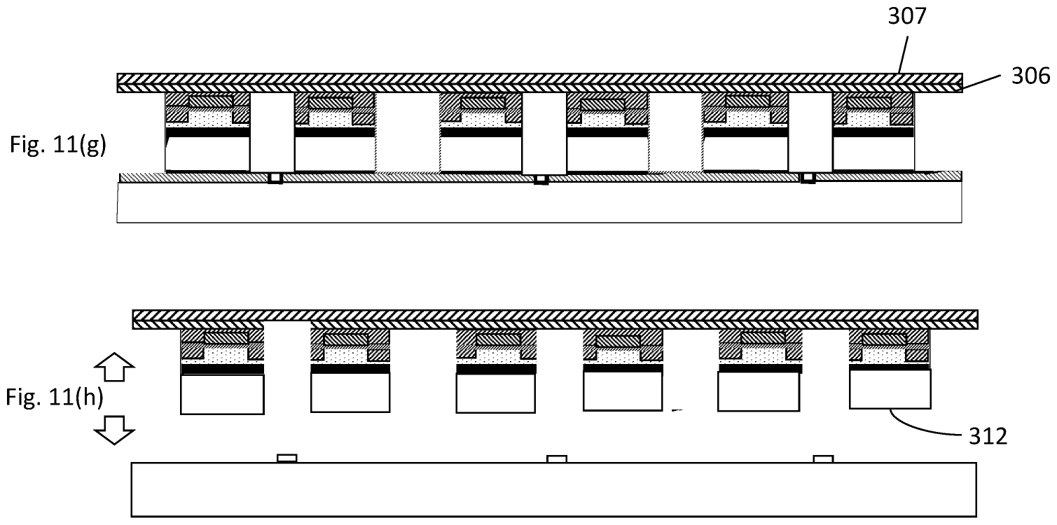

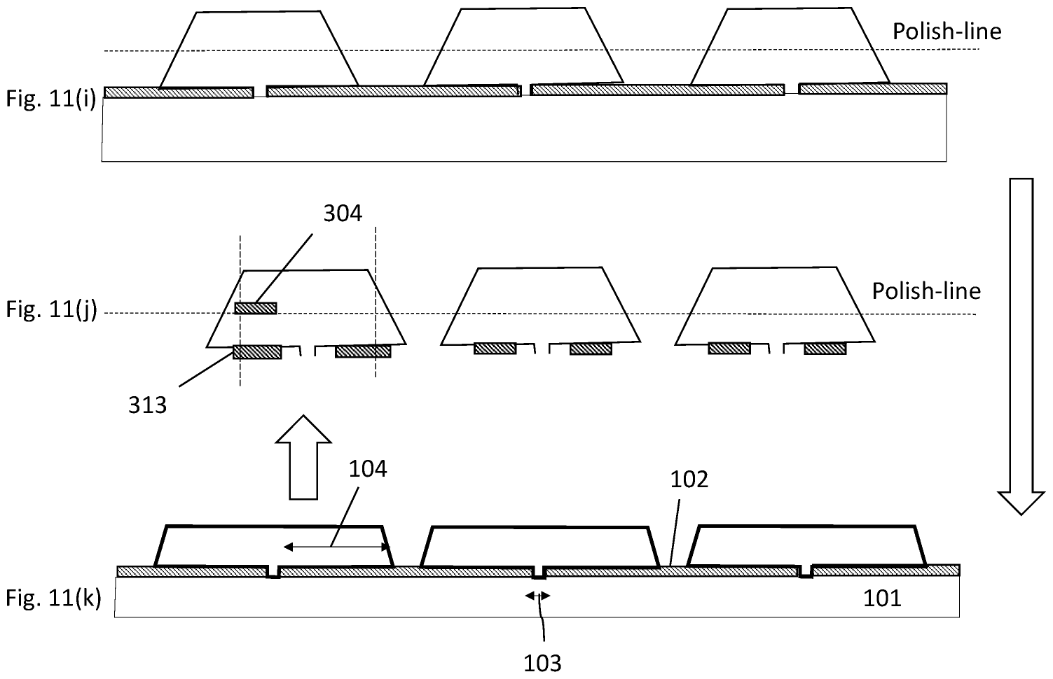

The designs illustrated can also be fabricated on III-nitride layers grown by following various approaches mentioned in FIGS. 2(a)-2(f), 3(a)-3(m), 4(a)-4(g) and 5(a)-5(i) above, as well as FIGS. 11(a)-11(k). FIGS. 11(a), 11(b), 11(c), 11(d), 11(e), 11(f), 11(g) and 11(h) illustrate a VCSEL fabrication process on non-coalesced island-like III-nitride semiconductor layers 109, according to one embodiment of the present invention, and FIGS. 11(i), 11(j) and 11(k) illustrate a possible solution when the aspect ratio of the non-coalesced ELO structures do not have enough space to fabricate VCSEL device devices 111.

In these designs, a first light reflecting mirror was designed at a designated portion of the wing regions of the ELO III-nitride layer 105 by defining a current confinement region 308 on the p-GaN side. Later, a current spreading layer 309, a contact layer, for example, ITO, is deposited on the region comprising current confinement aperture. A light reflecting DBR mirror 301 is a combination of dielectric layers with different refractive indices placed over the current confinement aperture such that contact layer lies between p-GaN and DBR. A p-pad 305 is lithographically defined.

Step 4: Forming a Structure for Separating Devices

The aim of this step is to prepare ELO III-nitride layers 105 comprising current confinement, current spreading, DBRs, p-electrode and n-electrode into the form of bars 110 or individual units of devices 111. i.e., VCSELs. By etching regions 202, 203, a bar 110 of the device 111 can be realized as shown in FIGS. 6(a)-6(e).

As shown in FIGS. 6(a)-6(e), a dividing support region 202 is a region to horizontally separate ELO III-nitride layers 105 into individual VCSEL devices 111 or a group of VCSEL devices 111 formed at periodic lengths, wherein each period is determined by the device 111 length. For example, in the case of a VCSEL device 111, one period is set to be 25-200 μm and vertically along the bar 110. When process #1 for removal of the ELO III-nitride layer 105 is implemented etching regions 202, 203 are necessary. However, when process #2 for removal is implemented, open region 202 may not necessarily etched.

The dividing support regions 202, 203 are lines scribed by a diamond tipped scriber or laser scriber, as shown in FIGS. 6(a)-6(e); or a trench formed by dry-etching such as RIE (Reactive Ion Etching) or ICP (Inductively Coupled Plasma); but is not limited to those methods. The dividing support regions 202, 203 may be formed on only sides of the bar 110 or on one side of the bar 110. The depth of the dividing support regions 202, 203 is preferably 1 μm or more.

Both cases can divide the bar 110 into separate devices 111 at the dividing support regions 202, 203, because the dividing support regions 202, 203 are weaker than any other part. The dividing support region 202 avoids breaking the bar 110 at unintentional positions, so that it can precisely determine the device 111 length.

The vertical dividing support region 202 is created at the open area 103 surface in a manner that avoids a current injection region, which is in the light emitting structure, and the p-electrode, and the layer bending region, although it may encompass at least a portion of the current confinement layer.

As shown in FIGS. 6(a)-6(e), the dividing support regions 202, 203 are formed according to the number of devices 111 to be withdrawn. For example, individual VCSEL devices 111 or VCSEL devices 111 lying side-by-side to open area can be lifted together when process #2 for removal is followed.

In addition, a whole bar 110 containing an array of VCSEL devices 111, or VCSEL devices 111 laying side-by-side to the open area, can be lifted as indicated in FIGS. 6(a)-6(c). Alternatively, the supporting plates 601 can have finger-like structures 602, wherein the plate 601 is thin enough to provide space and flexibility for the finger-like structures 602. The finger-lie structures 602 can attach to the removing bar 110 of devices 111.

Whole bar 110 lifting is helpful when integrating monochromatic lighting or scaling up power from individual devices 111. Alternatively, bar 110 type lifting can also be performed when polychromatic integration needed for display or any such demanding applications.

Step 5: ELO III-Nitride Layers are Removed from the Substrate.

After process #1 for removal of the ELO III-nitride layers 105, the semiconductor layers comprising the current confinement layer, currents spreading layer, DBR mirror, and electrodes are divided into individual devices 111 or a group of devices 111 together. Anchors or hookings may be placed on the individual devices 111 or a group of devices 111.

The divided semiconductor layers are then attached to a receptor or supporting plates via a bonding layer. The devices 111 are then removed from the III-nitride native substrate 101 by gently peeling. Here, the anchor material can be as same as the growth restrict mask 102 or any material that can be strong enough to hold divided devices 11 and weak enough to break when peeling is performed. Alternatively, attached devices 111 can be self-separated from the substrate 101 when the growth restrict layer 102 and anchors are dissolved, for example, using hydrofluoric acid (HF) or buffered HF (BHF) to dissolve growth restrict mask 102 and anchor layer.

A second light reflecting DBR mirror, is placed on the backside of the removed ELO III-nitride layers 105 in the wing region, on the n-GaN side, at an interface between the growth restrict mask 102 and ELO III-nitride layers 105. Then, n-pads are deposited to contact the n-GaN layer. On a few designs, the n-pads are placed on the opposite side of the interface.

During process #2 for removal of the ELO III-nitride layers 105, in Step 4, etching Region 1 202 can be avoided when process #2 is performed, and then skip to Step 5.

Step 6: Dissolving the Growth Restrict Mask by Wet Etching

The method may further comprise a step of removing, by dissolving using a wet etchant, at least a portion of, or preferably almost all of, or most preferably all of, the growth restrict mask 102.

The growth restrict mask 102 is removed using a chemical solution, such as HF or BHF. This allows the devices 111 to be easily removed from the substrate 101. This process would better be conducted before removing the III-nitride layers 105, 106, 109 from substrate 101. This step can also be conducted before processing the device 111 in Step 3 or during Step 3.

Step 7: Removing the Devices from the Substrate

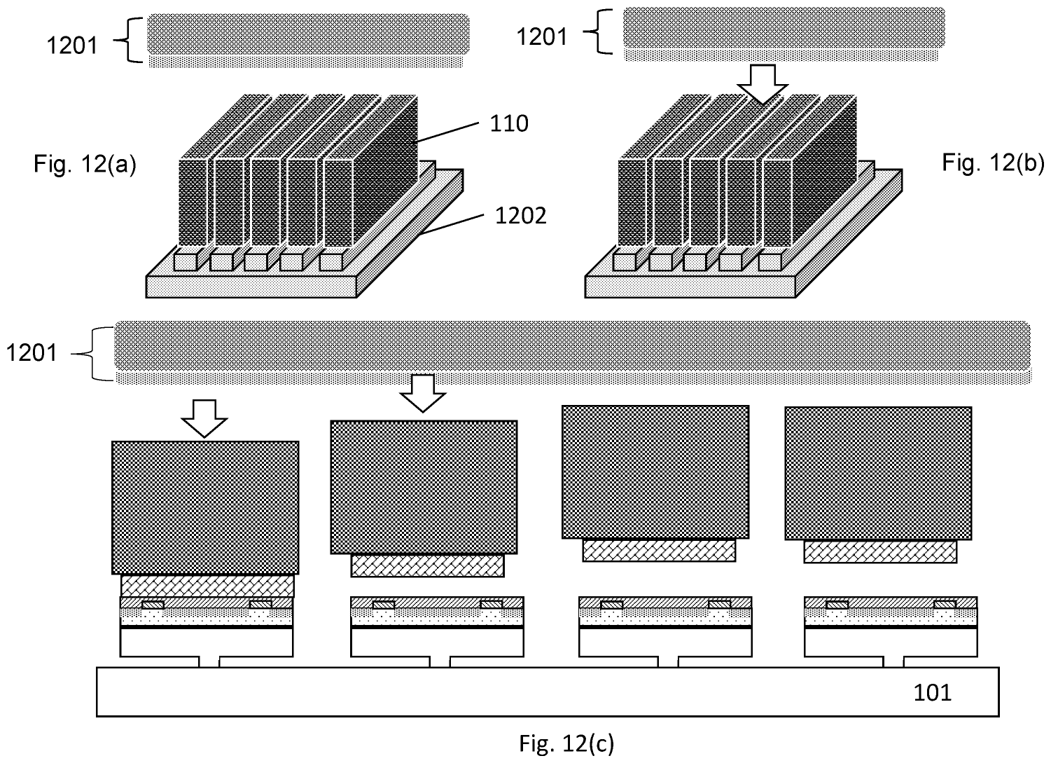

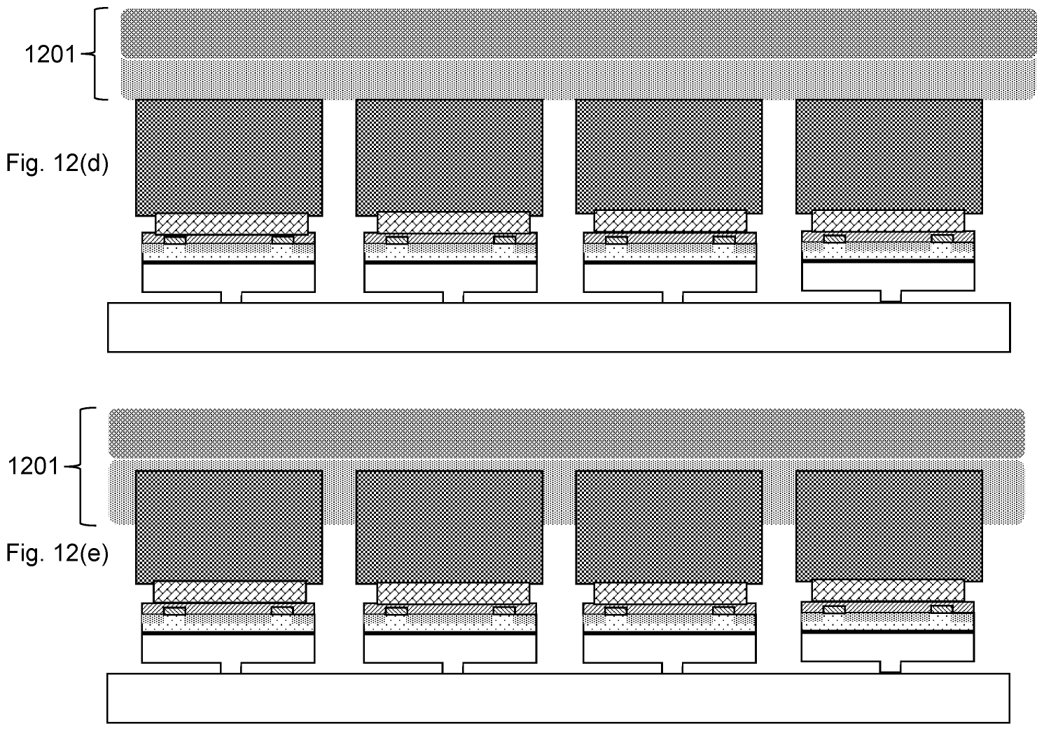

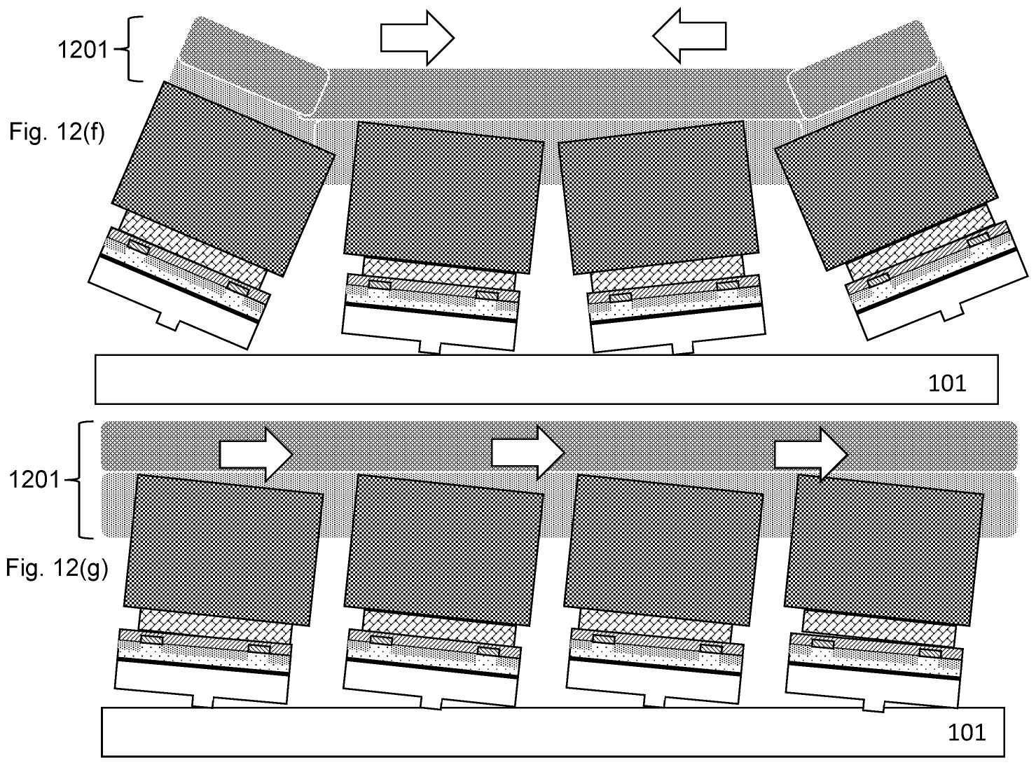

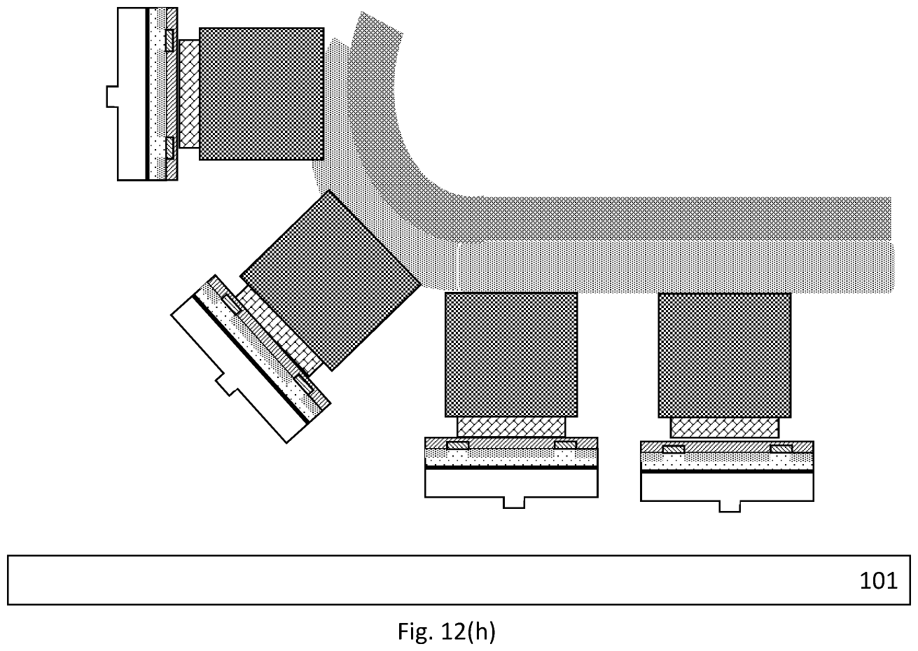

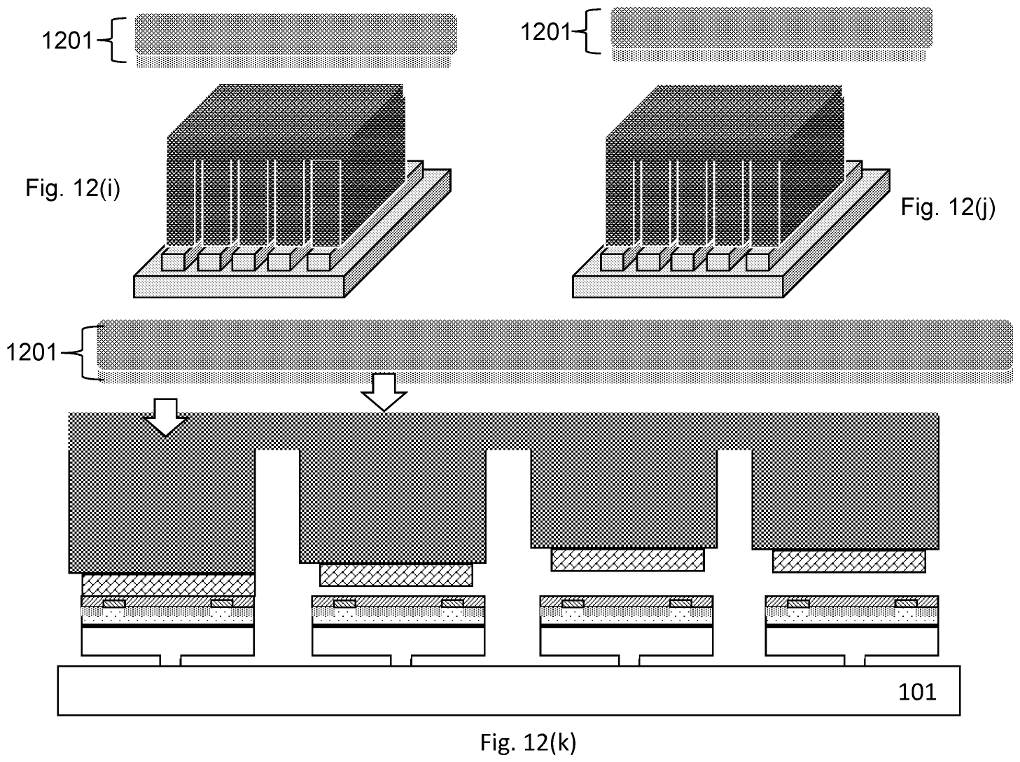

From here, the procedure for removing the bar 110 of devices 111 is explained. Specifically. FIGS. 12(a), 12(b), 12(c), 12(d), 12(e), 12(f), 12(g), 12(h), 12(i), 12(j) and 12(k) illustrate a procedure for removing a bar 110 of a device 111, according to one embodiment of the present invention.

Step 7.1 comprises attaching a polymer film 1201 to the bar 110 of the device 111. In this embodiment, the polymer film 1201 is comprised of a base film, an adhesive and a backing film. Preferably, the polymer film 1201 with the adhesive attachment is sensitive to UV energy, so that later detachment of the devices 111 from the film 1201 can be realized in a UV controlled environment.

Step 7.2 comprises applying pressure to the polymer film 1201 and the substrate 101. The aim of applying pressure is to put the polymer film 1201 in-between the bars 110 of the devices 111 or in between carrier (supporting) plates, 1202. The polymer film 1201 is softer than the bars 110 of the devices 111, so the polymer layer 1201 can easily surround the bars 110 and/or carrier plates 1202 of the devices 111. Preferably, the polymer film 1201 is heated in order to soften it, which makes it easy for the polymer film 1201 to cover the bars 110 of the devices 111 and/or carrier plates 1202.

Step 7.3 comprises reducing the temperature of the polymer film 1201 and the substrate 101, while maintaining the applied pressure. It is not necessary to apply pressure during the changing of the temperature.

Step 7.4 comprises utilizing the differences in thermal coefficients between the polymer film 1201 and the substrate 101 for removing the bars 110 of the devices 111. The polymer film 1201 shrinks as the temperature decreases. As a result, the bottom of the polymer film 1201 is lower than the top of the carrier plates 1202 or bars 110 of the devices 111.

The polymer film 1201 can apply the pressure in the horizontal direction at side facets of the bars 110 of the devices 111, exposing cleaving points 1203 and tilting the bars 110 of the devices 111 downward obliquely. This pressure applied from the side facets allows the bars 110 of the devices 111 to be effectively removed from the substrate 101. During low temperature, the polymer film 1201 maintains the applied pressure from the top of the polymer film 1201 to the bars 110 of the devices 111.

Various methods may be used to reduce the temperature. For example, the substrate 101 and the polymer film 1201 can be placed into liquid N₂ (for example, at 77° K) at the same time while applying pressure. The temperature of the substrate 101 and the polymer film 1201 can also be controlled with a piezoelectric transducer.

When reducing the temperature, the substrate 101 and the polymer film 1201 may be wetted by atmospheric moisture. In this case, the temperature reduction can be conducted in a dry air atmosphere or a dry N₂ atmosphere, which avoids the substrate 101 and the polymer film 1201 getting wet.

Thereafter, the temperature increases, for example, to room temperature, and the pressure is no longer applied to the polymer film 1201. At that time, the bars 110 of the devices 111 have already been removed from the substrate 101, and the polymer film 1201 is then separated from the substrate 101. When using a polymer film 1201, especially a polymer film 1201 having adhesive, the bars 110 of the devices 111 can be removed using the polymer film 1201 in an easy and quick manner.

There may be an occasion having a different height among the bars 110 of the devices 111, depending on a growth condition. In this case, the removal method with the polymer film 1201 is good at removing the different height bars 110 of the devices 111, because these films 1201 are flexible and soft.

Alternatively, above procedure can be realized when the carrier or supporting, plates 1202 have a finger-like structure.

Step 8: Fabricating a Second Light Reflecting DBR Mirror

Removed bars 110 of the devices 111 have a back surface that is an interface between the ELO III-nitride layer 105 and the growth restrict mask 102. The interface is formed by allowing epitaxial layers to grow laterally from open region 103 of the substrate 101. Surface morphology at the ELO interface, between the ELO III-nitride layer 105 and growth restrict mask 102, can be controlled by parameters of the growth restrict mask 102 and growth parameters of the ELO III-nitride layer 105.

The dependency of surface morphology on the growth restrict mask 102 dependency is illustrated in FIGS. 9(a)-9(e).

Case 1: A thinner growth restrict mask 102, for example, a thickness of 10 nm-50 nm, may deteriorate at higher MOCVD growth temperatures while performing epitaxial lateral overgrowth. Thus, producing non-controllable open areas 901 in the growth restrict mask 102. These non-controllable open areas 901 can be refilled along with the pre-determined open area 103 during the epitaxial lateral overgrowth resulting in connecting paths between the substrate 101 and the ELO III-nitride layers 105. The diffused epitaxial layers at these non-controllable open areas 901 may comprise a rough region interface 902 at the backside of the device 111 when bars 110 of the devices 111 are removed. In this case, the yield having a smooth interface surface at the removed ELO III-nitride layer 105 wing may be reduced.

Case 2: A thicker growth restrict mask 102, for example, a thickness of 100 nm-1000 nm, or more typically 1000 nm, can restrict a deteriorated region to within the growth restrict mask 102, such as damage region 903, at higher MOCVD growth temperatures while performing epitaxial lateral overgrowth. Thus, non-controllable open areas 901 can be eliminated by increasing the growth restrict mask 102 height, which translates to a better interface 904 between the ELO III-nitride layer 105 and the growth restrict mask 102. An increased aspect ratio (thickness/width) at the breaking point due to thicker growth restrict mask 102 will ease the removal of bars 110 of the devices 111 as an added advantage.

Case 3: Alternatively, instead of a thicker growth restrict mask 102, a combination of growth restrict masks 905 will also function as Case 2. One growth restrict mask 102 for easy liftoff, for example, SiO₂ and another growth restrict mask 102 for stability at higher temperature, for example, SiN, can be deposited as a combined growth restrict mask 102. A combined thickness of 100 nm-1000 nm or more is preferred, and typically 1000 nm. By choosing a thermally stable growth restrict mask 102 at the interface of the ELO III-nitride layers 105, a better surface 906 for removing the bars 110 of devices 111 can be obtained.

To obtain a smooth interface at the removed ELO III-nitride layer 105 back surface and a higher yield, a thicker growth restrict mask 102 or multiple layers for the growth restrict mask 102 are more preferable than a thinner growth restrict mask 102.

A proof of concept study for the results of the above cases are presented in FIGS. 9(f), 9(g), 9(h) and 9(i). Two categories of growth restrict masks 102 are reported in particular: (a) single-layered masks 102 and (b) multi-layered masks 102. In each category, PECVD or a sputter deposition was chosen for the deposition of the SiO₂ and/or SiN films. Also, a single-layered SiN growth restrict mask 102 is also added to study. Semi-polar 20-2-1 plane and non-polar 10-10 substrates 101 were chosen for the study; however, the results are the same with substrates having a c-plane or other crystal orientation.

As can be seen in FIG. 9(f), ELO III-nitride layers 105 were grown by MOCVD on the mask 102 patterned substrate 101, where the mask 102 was deposited by either PECVD and/or sputter, and the thickness varies from 100 nm to 300 nm for the single-layered mask 102 and a 60 nm SiN layer is added on the single-layered mask 102 to make a multi-layered mask 102. FIG. 9(g) shows the removed ELO III-nitride layers 105 of the various masks 102, wherein dashed lines represent the open areas 103 and the regions on either side of the dashed lines are ELO wings, and the surface shown is the interface of the interest for the DBR mirrors. The interfaces on the ELO wing were scanned using AFM and the results are presented in FIG. 9(h). As can be seen in the AFM scan results, when the thinner single-layered masks 102 (100 nm and 200 nm) are used for growth of the ELO III-nitride layers 105, the interface became rough, reaching above 2 nm for both PECVD and sputter deposited films; however, the interface of the ELO III-nitride layers 105 grown on a sputter deposited single-layered mask 102 that is 300 nm thick has a smoother interface, ˜0.4 nm compared to its PECVD counterpart. Scans on as PECVD and sputter deposited masks 102 before they are introduced into the MOCVD environment revealed rather larger grainsize and increased surface morphology roughness for PECVD films than sputter deposited films. A 60 nm thin SiN film was placed over single-layered masks 102 to make them multi-layered as in case 3 above, and the interface of the removed ELO III-nitride layers from these masks 102 showed a tremendous improvement in the interface smoothness, as can be seen in AFM scans. A minimum surface roughness of as low as 0.25 nm is achieved, even with the thinner single-layered mask 102 with the addition of a 60 nm thick SiN layer, indicating that nitride termination must be stable at a higher temperature and the epitaxial layers' growth environment. A single-layered SiN film also lead to a smoother surface to support this conclusion. It is believed that having either a quality single-layered film, deposited using sputter, IBD or ECR deposition, will produce quality films, or by using a nitride termination mask 102, smooth interfaces can be obtained.

FIG. 9(i) is a graph of surface roughness for the interface vs. various mask 102 types and thicknesses. The plot also added measured AFM scans from non-polar 10-10 plane.

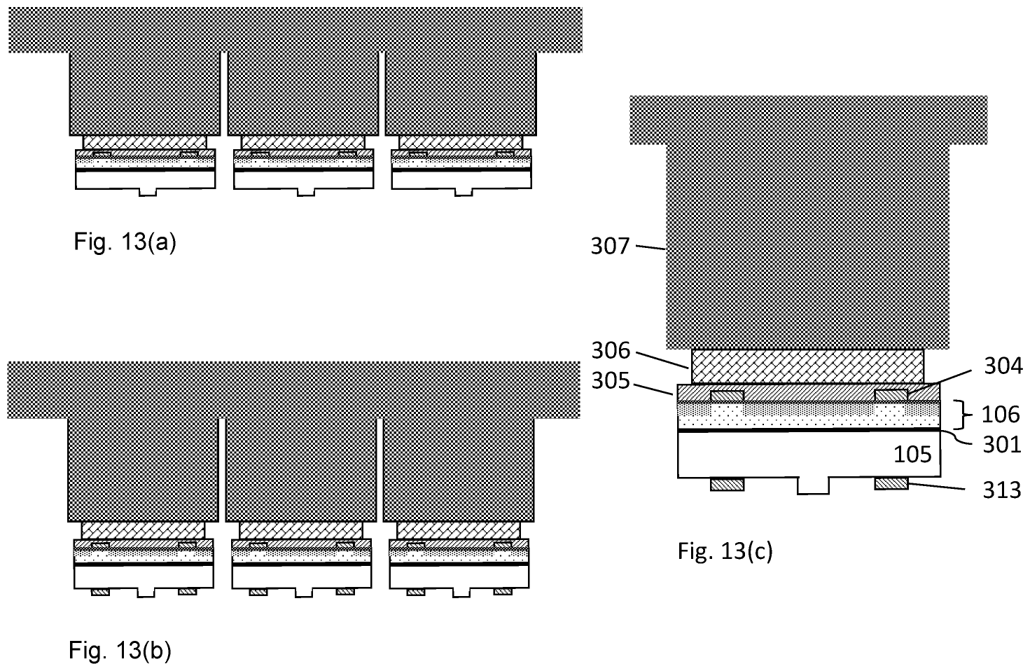

After removing bars 110 of devices 111, mesas are etched and a second light reflecting mirror 313 is defined by aligning with the first light reflecting layer, as shown in FIGS. 13(a), 13(b) and 13(c), which are schematic views of the effect of the growth restrict mask 102 on the interface. The second reflecting layer is a combination of one or more dielectric layers, for example, pairs of SiO₂/Nb₂O₅ layers may be deposited, typically 10 pairs.

Preferably, DBR mirror layers for the resonant cavity of the VCSEL device 111 are displaced away from the open region, for example, more than 1-2 μm away, in order to reduce effects on performance of the VCSEL of unwanted crystal quality near the ELO III-nitride layer 105 bending shape from the open region.

Alternatively, a pre-fabricated DBR mirror can be attached onto the removed ELO bars 110 of devices 111 by surface activation bonding or some other diffusion bonding mechanisms. The external DBR mirrors that are being attached can be of epitaxial in nature to improve thermal performance of the devices 111.

FIGS. 8(a)-8(d) are images of sample interface surfaces between the ELO III-nitride layer 105 and growth restrict mask 102. Specifically, FIGS. 8(a)-8(d) represent experimental results of 3 different crystal orientations, namely polar c-plane (1000), semipolar (20-21) and nonpolar (10-10), as well as a thinner growth restrict mask 102, a thicker growth restrict mask 102 and a multilayered growth restrict mask 102.

FIG. 8(a) shows the results obtained by implementing a process #1 removal method to remove grown ELO III-nitride layers 105 from polar c-plane substrate 101. The ELO III-nitride layers 105 of c-plane III-nitrides are transferred onto a polymer film using process #1. The growth restrict mask 102 in this case was 1 μm thick SiO₂. The images are a back surface of the ELO III-nitride layers 105 on the polymer film.

The surface shown in the image is an N-polar surface, which, in principle, when exposed to chemicals, such as potassium hydroxide (KOH), will become rough. For example, when photoelectric chemical etching method is used to remove Ga-polar semiconductor layers, the surface which is exposed to the chemicals cannot be used to make DBR mirrors. In this method, the as-grown ELO III-nitride layers 105 on the growth restrict mask 102 are used to make the DBR mirrors.

The images shown included magnified images of the back (interface) surface viewed through a laser microscope, scanning electron microscope (SEM) images, and images from atomic force microscopy (AFM) conducted on one of the back surfaces. The surface roughness was found to be from sub-nanometer to 1 or 2 nanometers, which are best for placing a second DBR mirror to complete a resonant cavity of a VCSEL device 111.

FIG. 8(b) shows the results obtained by implementing a process #2 removal method to remove as-grown ELO III-nitride layers 105 from semipolar 20-21 and nonpolar 10-10 substrates 101. These are images of the ELO III-nitride layers 105 of semipolar 20-21 plane III-nitrides transferred onto a polymer film using process #2. The growth restrict mask 102 in this case was 0.2 μm thick SiO₂.

The images shown include a back surface of the ELO III-nitride layers 105 on the polymer film. The surface shown in the image is a back surface of the 20-21 surface, which, in principle, when exposed to chemicals like KOH will become rough. For example, when photoelectric chemical etching method is used to remove Ga-polar semiconductor layers, the surface which is exposed to the chemicals used in this method will back the worse interface. The degree of roughness increases with increasing nitrogen polarity of the exposed surface to the chemicals. The interfaces are useful for making DBR mirrors. In this method, the as-grown ELO III-nitride layers 105 on the growth restrict mask 102 are used to make the DBR mirrors.

The images include magnified images of the back (interface) surface viewed through a laser microscope, SEM images and AFM images conducted on one of the back surfaces, particularly on a wing region. The surface roughness was found to be from sub-nanometer to a few nanometers, which are best for placing a second DBR mirror to complete a resonant cavity of a VCSEL device 111.

Similarly, FIG. 8(c) represents ELO III-nitride layers 105 of a nonpolar 10-10 plane III-nitrides transferred onto a polymer film using process #2. The growth restrict mask 102 in this case was 1 μm thick SiO₂. The images include a back surface of the ELO III-nitride layers 105 on the polymer film. The surface shown in the image is a back surface of the 10-10 surface. In this method, the as-grown ELO III-nitride layers 105 on the growth restrict mask 102 will be used to make DBR mirrors.

The images include magnified images of the back (interface) surface viewed through a laser microscope, SEM images, and AFM images conducted on one of the back surfaces, particularly on a wing region. The surface roughness was found to be from sub-nanometer to a few nanometers, which are best for placing a second DBR mirror to complete a resonant cavity of a VCSEL device 111.

FIG. 8(d) represents ELO III-nitride layers 105 of nonpolar 10-10 plane III-nitrides transferred onto a polymer film using process #2. The growth restrict mask 102 in this case was a multi-layer of 50 nm SiN and 1 μm thick SiO₂, where the SiN faces the interface of the ELO surface. These images are a back surface of the ELO III-nitride layers 105 on the polymer film. The surface shown in the image is a back surface of the 10-10 surface. In this method, as-grown ELO III-nitride layers 105 on the growth restrict mask 102 are used to make the DBR mirrors.

These images include magnified images of the back (interface) surface viewed through a laser microscope and AFM images conducted on one of the back surfaces, particularly on a wing region. The AFM results indicate the surface roughness of the ELO wings when they lie on SiO₂ and SiN, respectively. On the SiN surface, the ELO III-nitride layers 105 have finer grain structure as compared to ELO III-nitride layers 105 on the SiO₂ surface. The surface roughness was found to be from sub-nanometer to a few nanometers, which are best for placing a second DBR mirror to complete a resonant cavity of a VCSEL device 111.

As explained above, the growth restrict mask 102 may have an influence on the back surface. However, controlling the interface when chemicals are not involved is a much simpler way of doing things than chemically or mechanically polishing, or photo-electro-chemical etching. Preferably, using thicker growth restrict masks 102 and/or multiple growth restrict masks 102, yields at the interfaces can be improved.

Alternatively, placing metal-layers on top of growth restrict mask 102, which can withstand the temperatures used for forming ELO III-nitride layers 105, may give a mirror-like finish at the interface of the removed ELO III-nitride layers 105. The backside interface of the removed ELO III-nitride layers 105 at the wing regions can later be used to place a second DBR mirror for the resonant cavity of the VCSEL.

This invention helps in obtaining better crystal quality and smoother surfaces for DBR mirrors of the resonant cavity of VCSEL devices 111. Also, this approach is independent of crystal orientation, whereas other techniques are either tedious, chemically sensitive to crystal orientations, or less tolerances for mass production.

The essence of this invention lies not only in using ELO technology to obtain better quality crystal device layers 106, and smooth interfaces for DBR mirrors of the resonant cavity, but also to control cavity thickness and recycle expensive host substrates 101, for example, III-nitride substrates 101.

Step 9: Fabricating an n-Electrode at the Separate Area of the Device

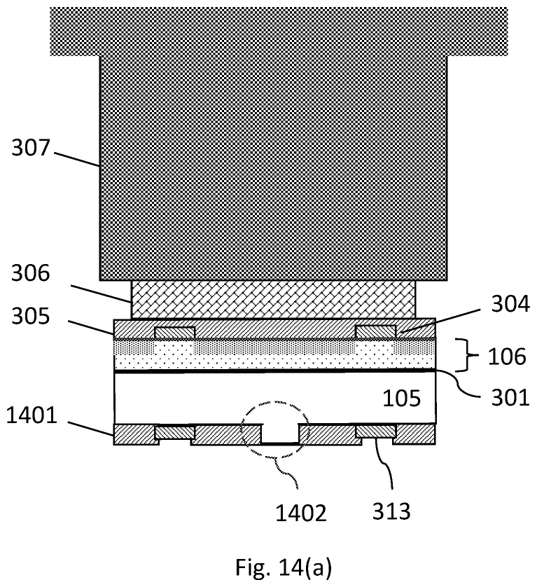

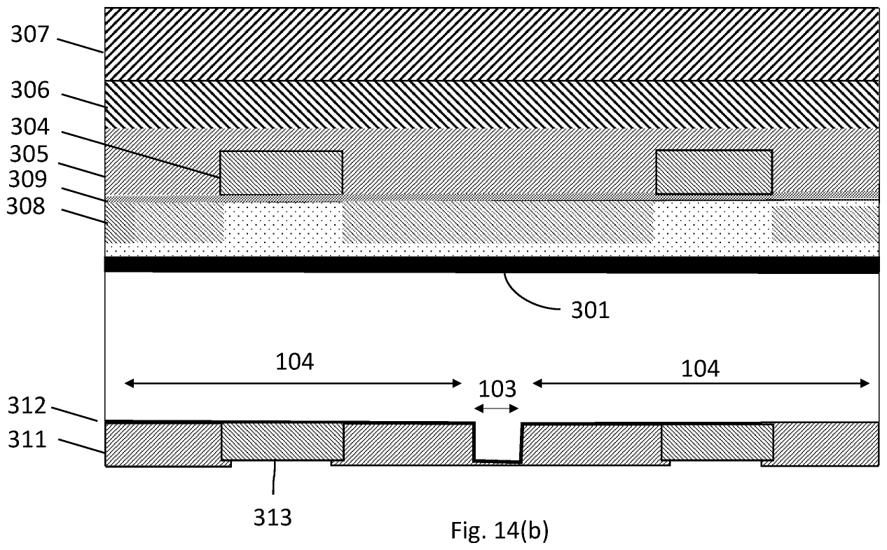

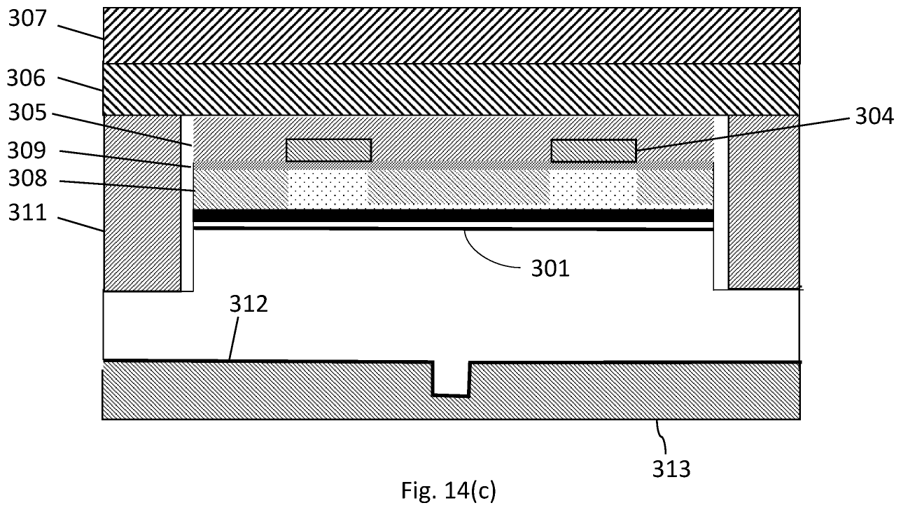

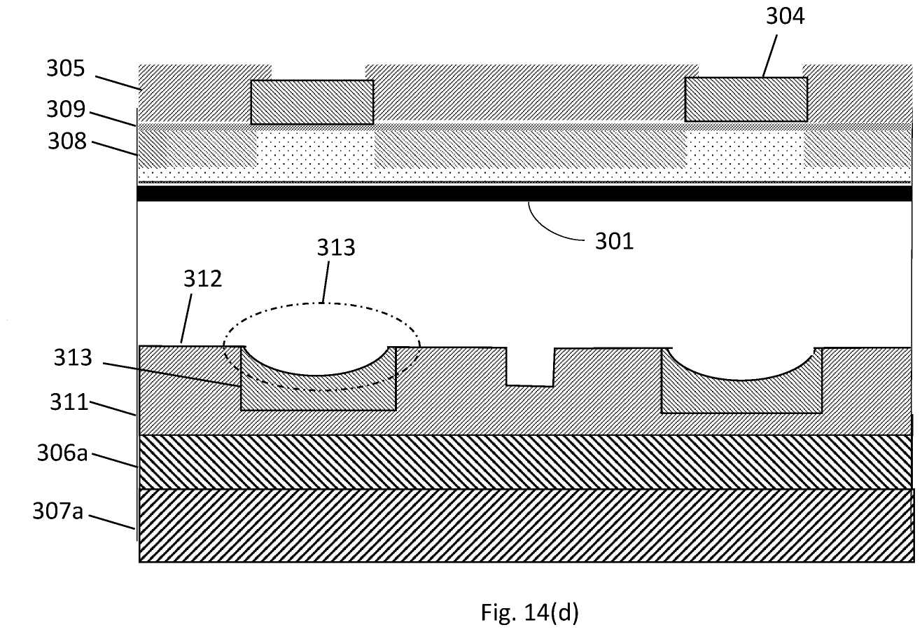

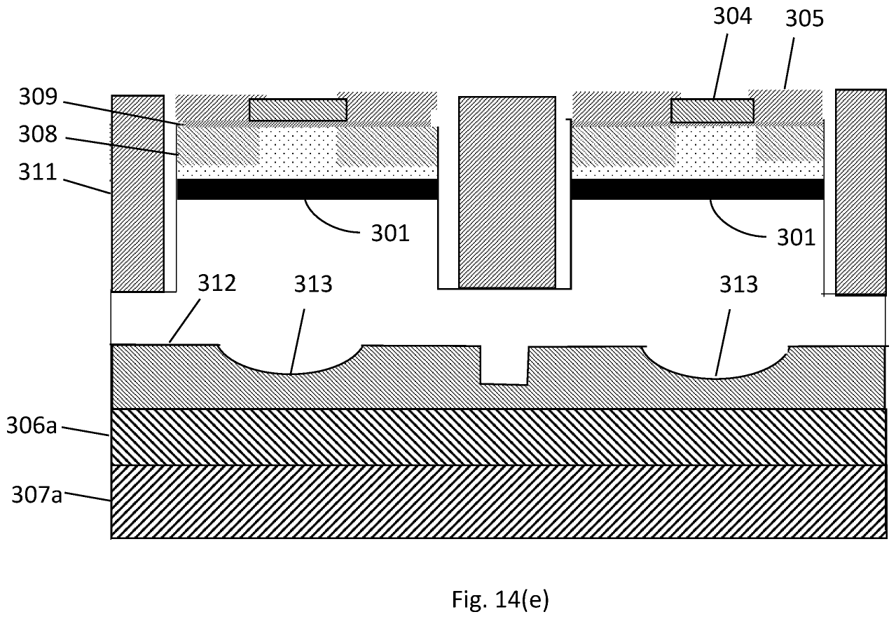

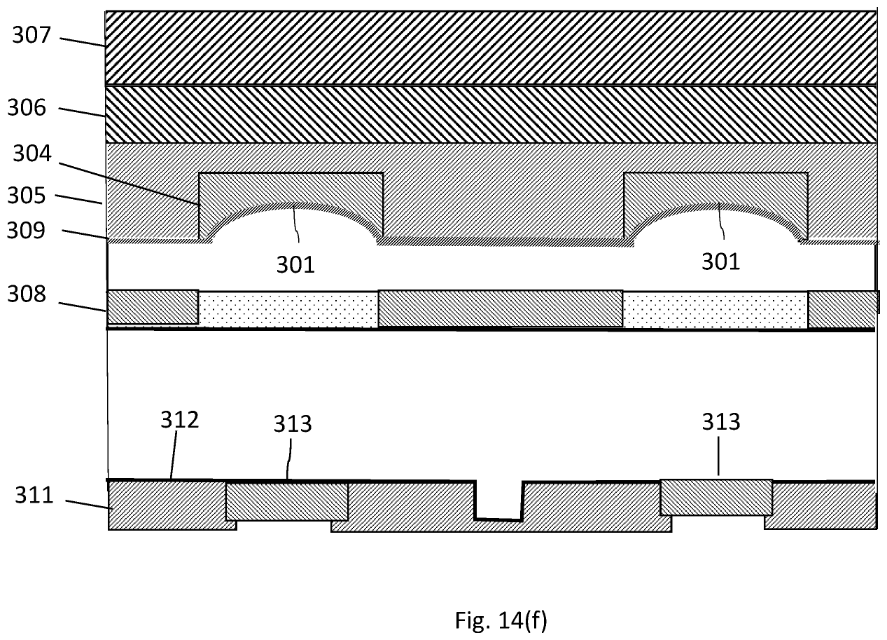

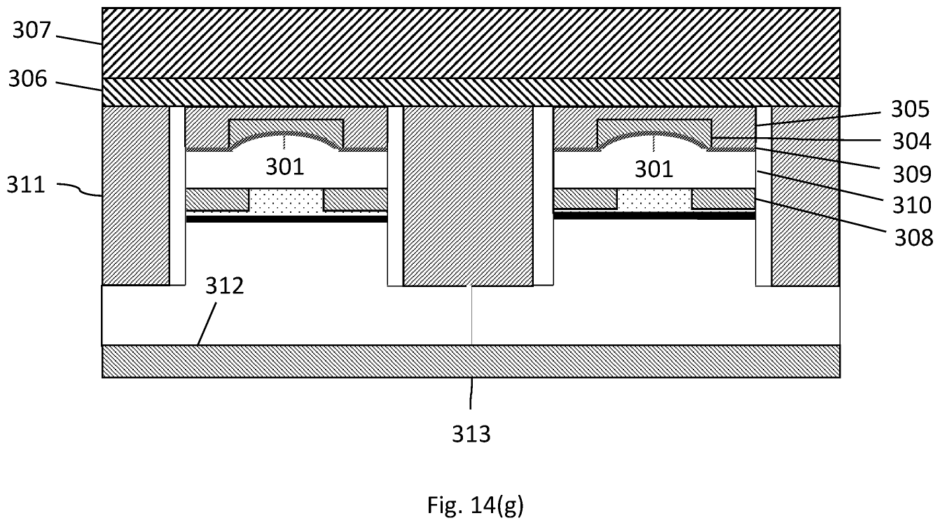

After removing the bar 110 or devices 111 from the substrate 101, the bar 110 remains attached to a carrier, which is shown with the bar 110 positioned in an upside-down manner, as shown in FIGS. 14(a)-14(g). Specifically, FIGS. 14(a), 14(b), 14(c), 14(d), 14(e), 14(f) and 14(g) illustrates a process flow for defining an n-side light reflecting layer after removing a bar 110 of devices 111 using supporting plates, and also illustrate possible device designs when VCSEL devices 111 fabricated on the two wings of the ELO III-nitride layer 105 and open region 103 are included in the device 111 design.

FIG. 14(a) shows the back side of the bar 110 or device 111, which has an n-electrode 1401 on its backside and a step-like feature 1402 at the open area 103 between the two side-by-side light reflecting mirrors 1403. The step-like feature 1402 contacts the substrate 101, or the underlying layer directly, but is not on the growth restrict mask 102. The step-like feature 1402 is the only connection to the substrate 101 that hosted ELO III-nitride layers 105. The step-like feature 1402 is separated from its host substrate 101 in this view and may not substantially contain material from the host substrate 101.

Then, the n-electrode 1401 is deposited on the back side of the device 111 after removing the bar 110 from the substrate 101. The n-electrode 1401 preferably includes the step-like feature 1402. The step-like feature 1402 may not exposed to robust environments during process #2 and is in intact with the host substrate 101 until its separation, which would make a good surface condition for the n-electrode 1401 for obtaining low contact resistivity. The area 1402 is not exposed in process #2 until the bar 110 or devices 111 are removed from its host substrate 101. A second light reflecting DBR mirror 313 is preferably placed away from the step-like feature 1402 edge, for example, at least more than 1-2 μm, to benefit the better crystal quality for the VCSEL devices 111. Therefore, using step-like feature 1402, the yield of VCSEL devices 111 can be increased as the n-electrode 1401 of the device 111 can find a space which may not be useful for the resonant cavity structure.

Alternatively, the n-electrode 1401 also can be disposed on the top surface of the bar 110 or devices 111, which is a surface made for a p-electrode 305.

Typically, the n-electrode 1401 is comprised of the following materials: Ti, Hf, Cr, Al, Mo. W, Au. For example, the n-electrode may be comprised of Ti—Al—Pt—Au (with a thickness of 30-100-30-500 nm) but is not limited to those materials. The deposition of these materials may be performed by electron beam evaporation, sputter, thermal heat evaporation, etc.

When process #2 is used to remove ELO III-nitride layers 105 from the host substrate 101, a bar 110 of devices 111 with ELO wings having a step-like feature 1402 lying in-between can be lifted onto a carrier or a polymer film. The possible device 111 configurations in this case span the same range as depicted in FIGS. 10(a)-10(f) for the single wing removal case. The possible device 111 designs with two ELO wings including the open area are shown in FIGS. 14(a)-14(g).

Step 10: Breaking the Bar into Separate Devices

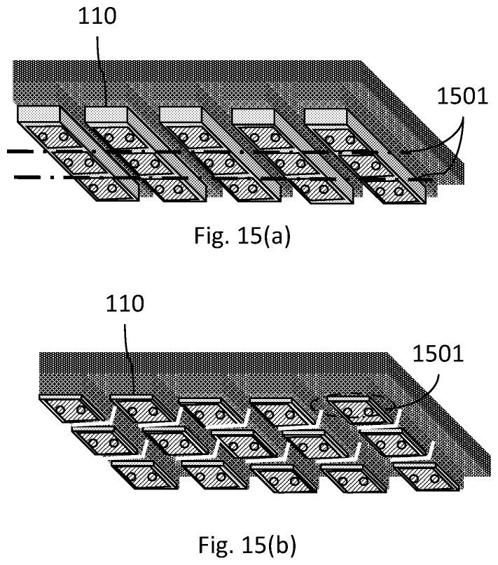

After disposing the n-electrode, each bar 110 is divided into a plurality of devices 111, as shown in FIGS. 15(a) and 15(b). Specifically, FIGS. 15(a) and 15(b) illustrate a process to divide devices 111 after n-electrode formation.

The dividing support region 1501 helps divide the bar 110 into the individual devices 111, as shown in FIG. 15(b). A breaking method can be used, as well as other conventional methods, but it is not limited to these methods.

Step 11: Mounting Each Device on a Heat Sink Plate

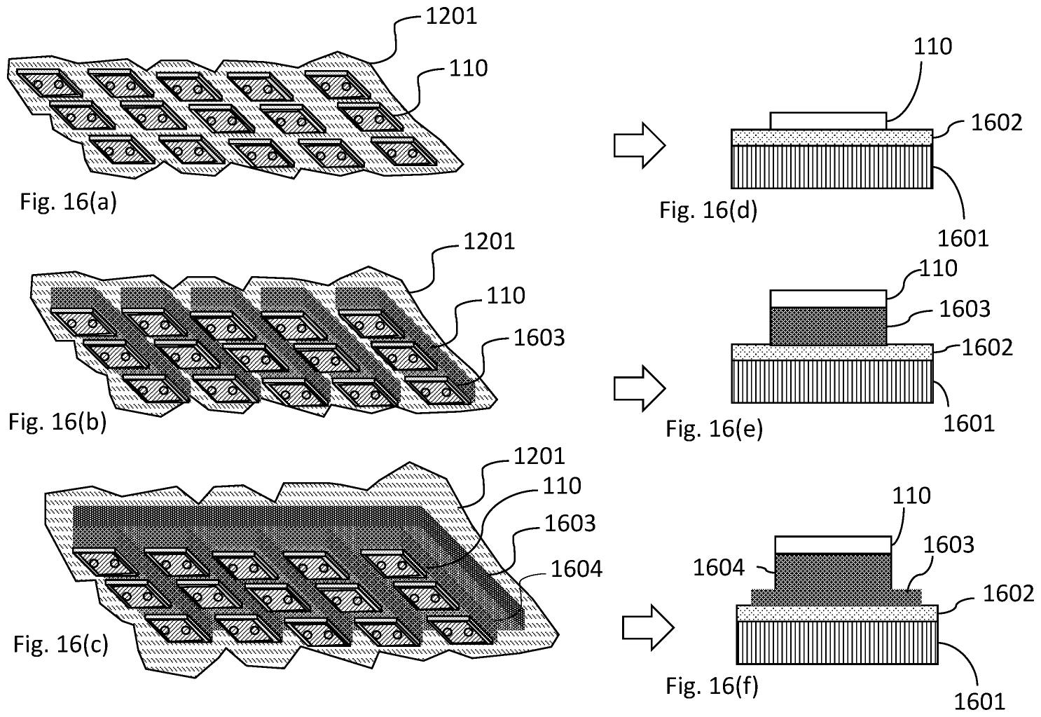

FIGS. 16(a), 16(b), 16(c), 16(d), 16(e) and 16(f) illustrate placing the removed bars 110 of devices 111 on heatsink plates 1601.

After Step 8, the divided bar 110 is lifted using one of three approaches: (1) attaching a polymer film 1201 to the bars 110 of devices 111 as shown in FIG. 16(a) and then bonding the bars 110 of devices 111 to a carrier plate 1601 using a solder 1602 as shown in FIG. 16(d); (2) attaching a polymer film 1201 to a joining plate 1603 as shown in FIG. 16(b), wherein the joining plate 1603 is directly joined to the bar 110 of devices 111, and then bonding the joining plate 1603 to the carrier plate 1601 using a solder 1602 as shown in FIG. 16(e); and (3) attaching a polymer film 1201 to the joining plate 1603 as shown in FIG. 16(c), wherein the joining plate 1603 has a finger-like structure 1604 that is directly joined to the bar 110 of devices 111, and then bonding the joining plate 1603 to the carrier plate 1601 using a solder 1602 as shown in FIG. 16(f).

In one embodiment, the polymer film 1201 is a UV light-sensitive dicing tape that is exposed to UV light, which can reduce the adhesive strength of the film 1201. This makes it easy to remove the devices 111 from the film 1201.

In this step, a heat sink plate 1601 comprised of AlN is prepared. An Au—Sn solder 1602 is disposed on the heat sink plate 1601, the heat sink plate 1601 is heated over the melting temperature of the solder 1602, and the devices 111 on the polymer film 1201 are bonded to the heat sink plate 1601 using the Au—Sn solder 1602. The devices 111 can be mounted on the heat sink plate 1601 in two ways: (1) n-electrode 1401 side down or (2) p-electrode 305 side down, depending on which is exposed as the light emitting side. FIGS. 16(d)-16(f) show the devices 111 mounted to the heat sink plate 1601 using the solder 1602. Alternatively, the carrier plates are heatsink structures.

Step 12: Dividing the Heat Sink Plate

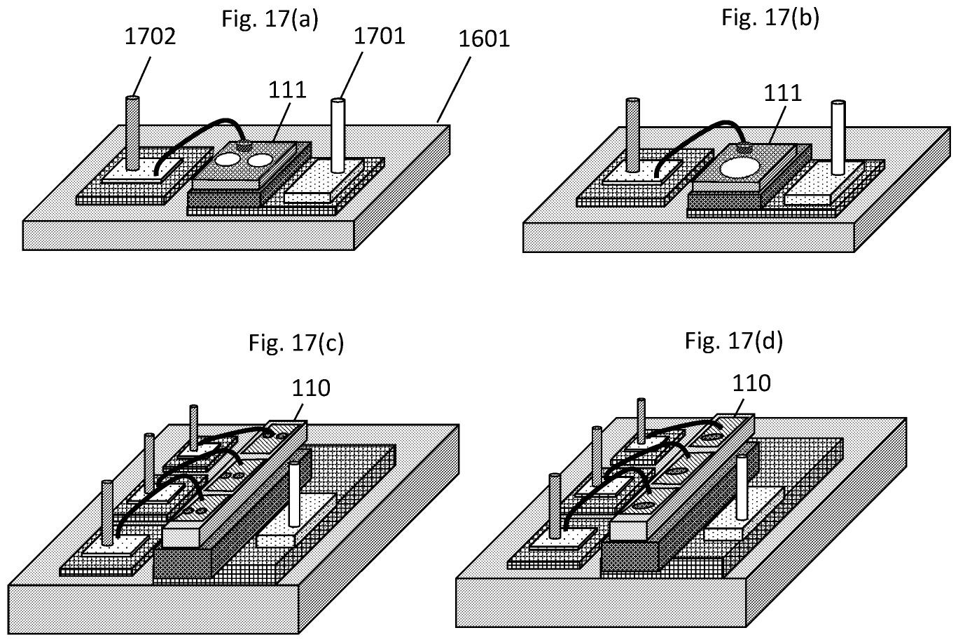

FIGS. 17(a), 17(b), 17(c) and 17(d) illustrate how wire bonds are attached to devices 111, according to one embodiment of the present invention.

As shown in FIGS. 17(a)-17(d), wire bonds 1701 and 1702 are attached to the devices 111, and then the heat sink plate 1601 is divided, for example, between one or more of the devices 111. FIG. 17(a) is an example device 111 having two VCSEL apertures separated by a step-like feature, and FIG. 17(b) is an example device having a single VCSEL aperture. FIGS. 17(c) and 17(d) illustrate how bonds 1701, 1702 are prepared for a whole bar 110 of devices 111 of their respective designs.

FIGS. 17(a)-17(d) illustrate how VCSEL devices 111 in the form of a bar 110 can be integrated for the applications that require greater power or light emission. However, even in applications that require a large amount of light flux, either monochromatic or multi-color, can integrate several bars 110 together.

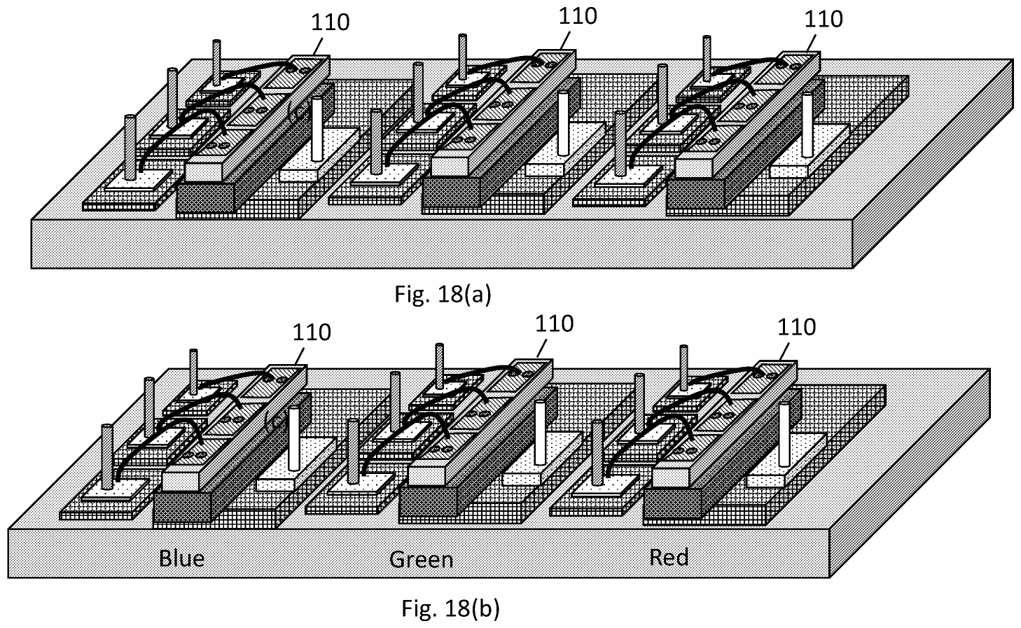

FIG. 18(a) illustrates a monochromatic integration and FIG. 18(b) illustrates a multi-colored integration, with multiple devices 111 on the heat sink plates 1601, according to embodiments of the present invention.

Mass Transfer for Display Applications

Method 1

This invention provides a solution to the problem of mass transferring of smaller light emitting apertures, alternatively called as emissive inorganic pixels, when targeted sizes are below 50 μm.

VCSELs devices 111, fabricated on the ELO III-nitride layers 105, can be removed as mentioned above. In particular, these devices 111 preferably have larger ELO wing regions and smaller open areas 103, that is a ratio between the wing region and open area 103 should be more than 1, more preferably 5-10, and in particular, open areas 103 should be around 1-5 μm. Therefore, devices 111 can be removed from the III-nitride substrate 101 more easily and can be transferred to external carriers or processed in further steps in an easy manner.

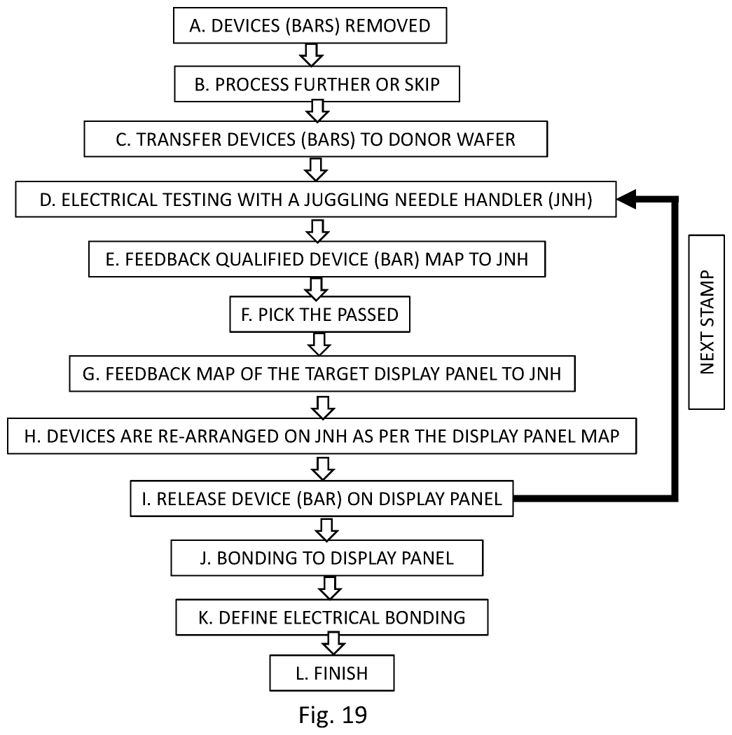

FIG. 19 is a flow chart for integrating VCSEL devices 111 onto a back panel of a display or a maximizing flux. The steps are described below:
Step A: Devices 111 (bars 110) are removed from the substrate 101.
Step B: Devices 111 are processed further to complete fabrication or if no further fabrication required skip to Step C.
Step C: Transfer devices 111 to a donor wafer.
Step D: Electrical characterization with a Juggling Needle Handler (JNH) stamp.
Step E: Feedback qualified map to JNH.
Step F: Pick the qualified devices 111 with vacuum controlled needles of JNH.
Step G: Feedback display panel map to JNH.
Step H: Re-arrange qualified devices 111 on JNH as per the display panel map.
Step I: Release device 111 (bar 110) at the desired place.
Step J: Bond the qualified devices 111 to the display panel.
Step K: Define wire bonding or ribbon bonding.
Step L: Finish.

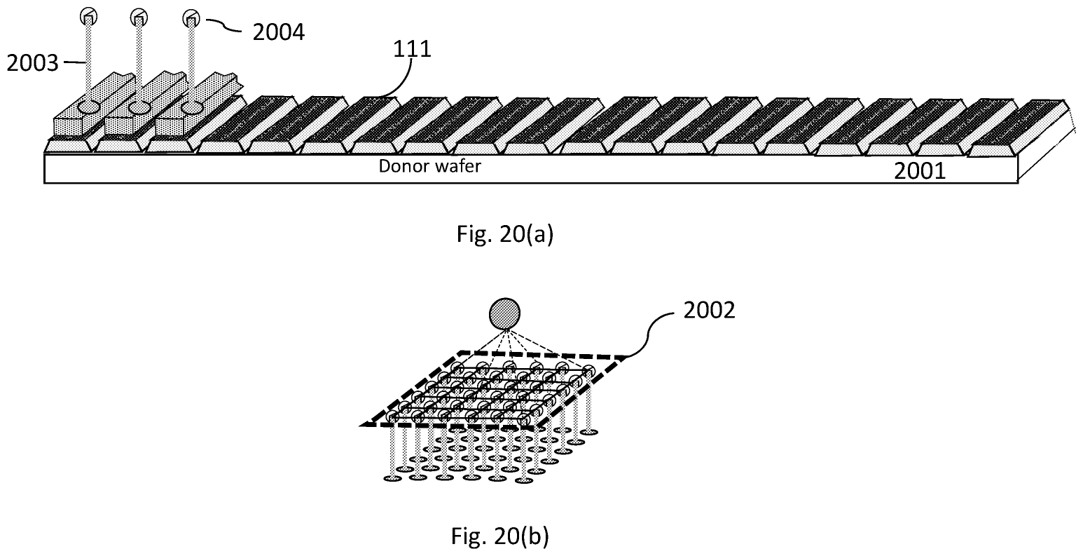

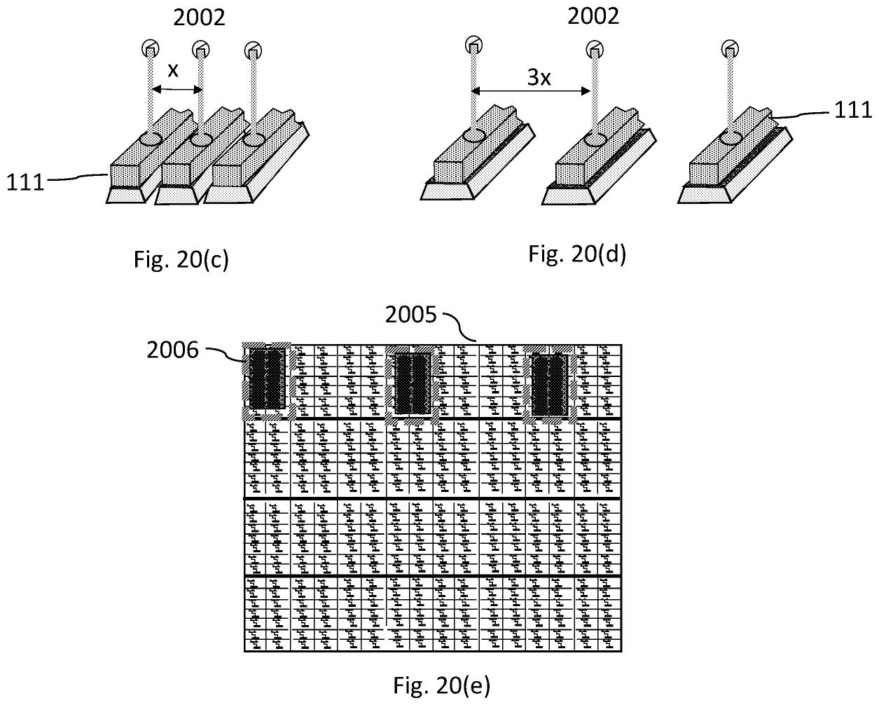

The devices 111 are shown in FIGS. 10(a)-10(l) and 16(a)-16(f), either bare devices 111 or devices 111 in a combination with a heatsink plate 1601 are transferred to a donor wafer 2001, as shown in FIG. 20(a), which illustrates a process dedicated to integrating a bar 110 of devices 111 as whole.

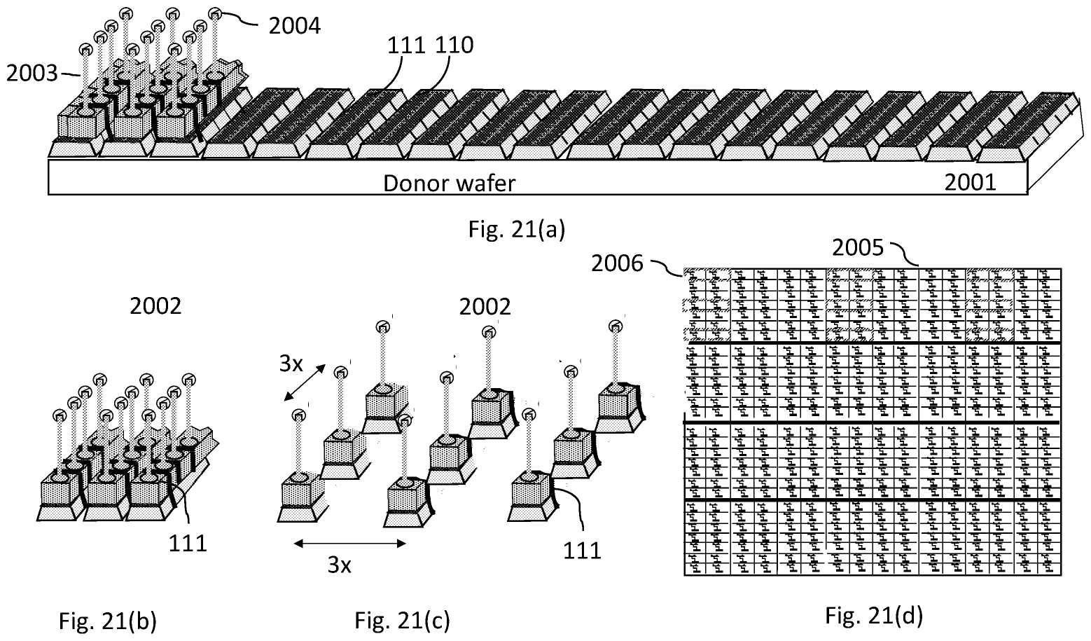

The devices 111 of interest can be a bar 110 of devices 111 having VCSEL devices 111 on either side of the open area 103 or single VCSEL devices 111 on one of the ELO wings. For example, FIGS. 20(a)-20(e) illustrate a transferring flow for VCSEL devices 111 on either side of the open area 103 and FIGS. 21(a)-21(d) illustrate a transferring flow when individual devices 111 are addressed.

Individual devices 111 as shown in FIG. 20(a) or bars 110 of devices 111 as shown in FIG. 21(a) can be transferred to a donor wafer 2001 after Step G or can decide after Step H. As shown in FIG. 20(b), a juggling needle handler (JNH) stamp 2002 may be used, wherein the JNH stamp 2002 is comprised of an array of one or more JNH needles 2003 and functions 2004 such as electrical, vacuum, heating, logic controls, etc., as shown in FIG. 20(a). For example, the JNH stamp 2002 may be 20 mm×20 mm in size to characterize electrically and to pick devices 111 from the donor wafer 2001.

The JNH stamp 2002 may transfer adjacent devices 111, e.g., every x device 111, as shown in FIGS. 20(c) and 21(b), or may transfer devices 111 spaced apart at some interval, e.g., every 3× device 111, as shown in FIGS. 20(d) and 21(c).

In a simple rough estimation, for example, when typical device 111 dimensions of 40 μm×40 μm with a pitch 20 μm are considered, a stamp 2002 may accommodate 333 devices 111 lengthwise and 333 breadthwise. Therefore, at least 100000 devices 111 may be transferred in a minute (which can be made faster with advanced instrumentation).

Also, a micro-LED display transfer process can be easily adopted to this transfer process, as shown in FIGS. 20(e) and 21(d). The display 2005 may be comprised of a plurality of devices 111, wherein the JNH stamp 2002 can pick and place arrays 2006 of the devices 111.

Process #1 and process #2 both have the potential to meet industrial standards when the removing process and fabrication techniques are adopted for both VCSEL devices 111 and micro LED devices 111.

Advantages of this method include the following:
Devices 111 or bars 110 of the devices 111 can be made in a homogeneous epitaxy.
Devices 111 are fabricated on ELO wing regions having low defects as compared to homogeneous epitaxial devices 111.
When device 111 sizes become <50 μm, defects will play an important role in determining brightness; however this approach will tolerate this.
If each individual devices 111 separated by a step-like feature are addressed separately, the problem of dead pixels in display applications can be solved by backing each pixel with another pixel during display panel integration.
Can overcome conventional size integration limits and adds a backup pixel in the given space.
The bar 110 with devices 111 transfer method has more throughput as compared to picking each individual device 111.
Full color integration or monolithic integration is possible with a programmable JNH.

Method 2

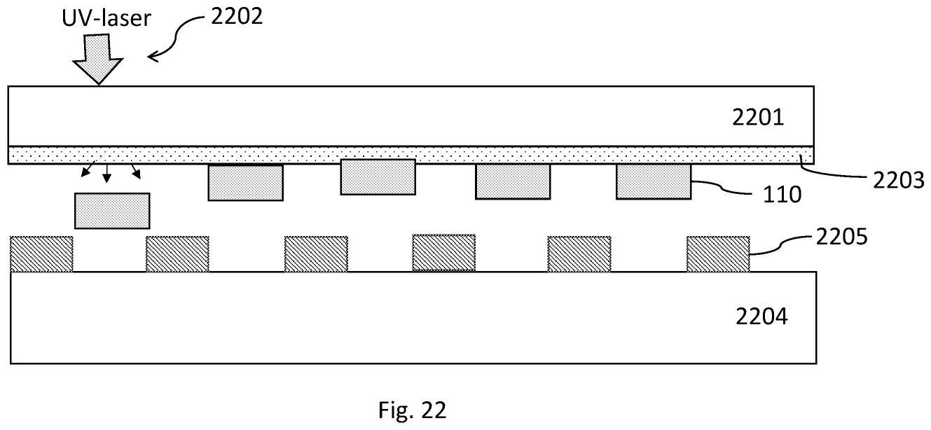

FIG. 22 illustrates a second method that can be used to remove devices 111, such as VCSELs, micro-LEDs or edge emitting lasers, fabricated using the methods described herein. Specifically, FIG. 22 shows one of the possible mass transfer techniques using an ultra-violet (UV) sensitive carrier (e.g., a polymer film) 2201 and UV laser 2201, wherein bars 110 of devices 111 are glued 2203 to the carrier 2201.

The bars 110 of devices 111 are removed onto the UV sensitive polymer film 2201 and then are integrated onto a functional back panel 2204, for example, thin film transistor, integrated back panel, or CMOS circuits back panel, having electrical pads 2205 or other components. The bars 110 of devices 111 on the UV sensitive polymer film 2201 are bombarded by the pulsed UV laser 2202 from the back side of the polymer film 2201 while bringing the functional back panel 2204 to their proximity.

### Definitions of Terms

III-Nitride-Based Substrate

The III-nitride-based substrate 101 may comprise any type of III-nitride-based substrate, as long as a III-nitride-based substrate enables growth of III-nitride-based semiconductor layers 105, 106, 109 through a growth restrict mask 102, any GaN substrate 101 that is sliced on a {0001}, {11-22}. {1-100}, {20-21}, {20-2-1}, {10-11}, {10-1-1} plane, etc., or other plane, from a bulk GaN, and AlN crystal substrate.

Hetero-Substrate

Moreover, the present invention can also use a hetero-substrate 101. For example, a GaN template or other III-nitride-based semiconductor layer may be grown on a hetero-substrate 101, such as sapphire, Si, GaAs, SiC, etc., prior to the growth restrict mask 102. The GaN template or other III-nitride-based semiconductor layer is typically grown on the hetero-substrate 101 to a thickness of about 2-6 μm, and then the growth restrict mask 102 is disposed on the GaN template or other III-nitride-based semiconductor layer.

Growth Restrict Mask

The growth restrict mask 102 comprises a dielectric layer, such as SiO₂, SiN, SiON, Al₂O₃, AlN, AlON, MgF, ZrO₂, etc., or a refractory metal or precious metal, such as W, Mo, Ta, Nb, Rh, Ir, Ru, Os, Pt, etc. The growth restrict mask 102 may be a laminate structure selected from the above materials. It may also be a multiple-stacking layer structure chosen from the above materials.

In one embodiment, the thickness of the growth restrict mask 102 is about 0.05-3 μm. The width of the mask is preferably larger than 20 μm, and more preferably, the width is larger than 40 μm. The growth restrict mask 102 is deposited by sputter, electron beam evaporation, plasma-enhanced chemical vaper deposition (PECVD), ion beam deposition (IBD), etc., but is not limited to those methods.

On an m-plane free standing GaN substrate 101, the growth restrict mask 102 comprises a plurality of opening areas 103, which are arranged in a first direction parallel to the 11-20 direction of the substrate 101 and a second direction parallel to the 0001 direction of the substrate 101, periodically at intervals extending in the second direction. The length of the opening area 103 is, for example, 200 to 35000 μm; the width is, for example, 2 to 180 μm; and the interval of the opening area 102 is, for example, 20 to 180 μm. The width of the opening area 103 is typically constant in the second direction but may be changed in the second direction as necessary.

On a c-plane free standing GaN substrate 101, the opening areas 103 are arranged in a first direction parallel to the 11-20 direction of the substrate 101 and a second direction parallel to the 1-100 direction of the substrate 101.

On a semipolar (20-21) or (20-2-1) GaN substrate 101, the opening areas 103 are arranged in a direction parallel to [−1014] and [10-14], respectively.

Alternatively, a hetero-substrate 101 can be used. When a c-plane GaN template is grown on a c-plane sapphire substrate 101, the opening area 103 is in the same direction as the c-plane free-standing GaN substrate 101; when an m-plane GaN template is grown on an m-plane sapphire substrate 101, the opening area 103 is same direction as the m-plane free-standing GaN substrate 101. By doing this, an m-plane cleaving plane can be used for dividing the bar 110 of the device 111 with the c-plane GaN template, and a c-plane cleaving plane can be used for dividing the bar 110 of the device 111 with the m-plane GaN template; which is much preferable.

III-Nitride-Based Semiconductor Layers

The ELO III-nitride layers 105, the III-nitride semiconductor device layers 106 and the island-like III-nitride semiconductor layers 109 can include In, Al and/or B, as well as other impurities, such as Mg, Si, Zn, O, C, H, etc.

The III-nitride-based semiconductor device layers 106 generally comprise more than two layers, including at least one layer among an n-type layer, an undoped layer and a p-type layer. The III-nitride-based semiconductor device layers 106 specifically comprise a GaN layer, an AlGaN layer, an AlGaInN layer, an InGaN layer, etc. In the case where the device 111 has a plurality of III-nitride-based semiconductor layers, the distance between the island-like III-nitride semiconductor layers 109 adjacent to each other is generally 30 μm or less, and preferably 10 μm or less, but is not limited to these figures. In the semiconductor device 111, a number of electrodes according to the types of the semiconductor device 111 are disposed at predetermined positions.

Epitaxial Lateral Overgrowth

The crystallinity of the island-like III-nitride semiconductor layers 109 grown using ELO upon the growth restrict mask 102 from a striped opening are 103 of the growth restrict mask 102 is very high.

Furthermore, two advantages may be obtained using a III-nitride-based substrate 101. One advantage is that a high-quality island-like III-nitride semiconductor layer 109 can be obtained, such as with a very low defects density, as compared to using a sapphire substrate 101.

Another advantage in using a similar or the same material for both the epilayer 109 and the substrate 101, is that it can reduce strain in the epilayer 109. Also, thanks to a similar or the same thermal expansion, the method can reduce the amount of bending of the substrate 101 during epitaxial growth. The effect, as above, is that the production yield can be high, in order to improve the uniformity of temperature.

The use of a hetero-substrate 101, such as sapphire (m-plane, c-plane), LiAlO₂, SiC, Si, etc., for the growth of the epilayers 105, 106, 109 is that these substrates are low-cost substrates. This is an important advantage for mass production.

When it comes to the quality of the device 111, the use of a free standing III-nitride-based substrate 101 is more preferable, due to the above reasons. On the other hand, the use of a hetero-substrate 101 makes it easy to remove the III-nitride-based semiconductor layers 105, 106, 109, due to a weaker bonding strength at the cleaving points.

Also, when a plurality of island-like III-nitride semiconductor layers 109 are grown, these layers 109 are separated from each other, that is, are formed in isolation, so tensile stress or compressive stress generated in each of the island-like III-nitride semiconductor layers 109 is limited within the layers 109, and the effect of the tensile stress or compressive stress does not fall upon other III-nitride-based semiconductor layers.

Also, as the growth restrict mask 102 and the ELO III-nitride layers 105 are not bonded chemically, the stress in the ELO III-nitride layers 105 can be relaxed by a slide caused at the interface between the growth restrict mask 102 and the ELO III-nitride layers 105.

Also, the existence of gaps between each the island-like III-nitride semiconductor layers 109, as shown by no-growth region 104 in FIG. 1(a), results in the substrate 101 having rows of a plurality of island-like III-nitride semiconductor layers 109, which provides flexibility, and the substrate 101 is easily deformed when external force is applied and can be bent.

Therefore, even if a slight warpage, curvature, or deformation occurs in the substrate 101, this can be easily corrected by a small external force, which avoids the occurrence of cracks. As a result, the handling of substrates 101 by vacuum chucking is possible, which makes the manufacturing process of the semiconductor devices 111 more easily carried out.

As explained, island-like III-nitride semiconductor layers 109 made of high quality semiconductor crystal can be grown by suppressing the curvature of the substrate 101, and further, even when the III-nitride-based semiconductor layers 105, 106, 109 are very thick, occurrences of cracks, etc., can be suppressed, and thereby a large area semiconductor device 111 can be easily realized.

Flat Surface Region

The flat surface region 107 is between layer bending regions 108. Furthermore, the flat surface region 107 is in the region of the growth restrict mask 102.

Fabrication of the semiconductor device 111 is mainly performed on the flat surface region 107. The width of the flat surface region 107 is preferably at least 5 μm, and more preferably is 10 μm or more. The flat surface region 107 has a high uniformity of thickness for each of the semiconductor layers 105, 106, 109 in the flat surface region 107.

Layer Bending Region

FIG. 1(b) illustrate the layer bending regions 108. If the layer bending region 108 that includes the active layer 106a remains in the device 111, a portion of the emitted light from the active layer 106a is reabsorbed. As a result, it is preferable to remove at least a part of the active layer 106a in the layer bending region 108 by etching.

If the layer bending region 108 that includes an active layer 106a remains in the VCSEL device 111, the laser mode may be affected by the layer bending region 108 due to a low refractive index (e.g., an InGaN layer). As a result, it is preferable to remove at least a part of the active layer 106a in the layer bending region 108 by etching.

The emitting region formed by the active layer 106a is a current injection region. In the case of a VCSEL 111, the emitting region is a resonant cavity aperture structure vertically above p-side or below n-side or vice versa.

For the VCSEL, the edge of the emitting region should be at least 1 μm or more from the edge of the layer bending region 108, and more preferably 5 μm.

From another point of view, an epitaxial layer of the flat surface region 107 except for the opening area 103 has a lesser defect density than an epitaxial layer of the opening area 103. Therefore, it is more preferable that the aperture structures should be formed in the flat surface region 107 including on a wing region.

Semiconductor Device

The semiconductor device 111 is, for example, a Schottky diode, a light-emitting diode, a semiconductor laser, a photodiode, a transistor, etc., but is not limited to these devices 111. This invention is particularly useful for VCSELs. This invention is especially useful for a semiconductor laser which require smooth regions for cavity formation.

Polymer Film

The polymer film 1201 is used in order to remove the island-like III-nitride semiconductor layers 109 from the III-nitride-based substrate 101 or the GaN template used with the hetero-substrate 101. In the present invention, dicing tape, including UV-sensitive dicing tape, which are commercially sold, can be used as the polymer film 1201. For example, the structure of the polymer film 1201 may comprise triple layers or double layers, but is not limited to those examples. The base film material, for example, having a thickness of about 80 μm, may be made of polyvinyl chloride (PVC). The backing film material, for example, having a thickness of about 30 μm, may be made of polyethylene terephthalate (P.E.T.). The adhesive layer, for example, having a thickness of about 15 μm, may be made of acrylic UV-sensitive adhesive.

When the polymer film 1201 is a UV-sensitive dicing tape and is exposed to UV light, the stickiness of the film 1201 is drastically reduced. After removing the island-like III-nitride semiconductor layers 109 from the substrate 101, the polymer film 1201 is exposed by the UV light, which makes it is easy to remove.

Heat Sink Plate

As noted above, the removed bar 110 may be transferred to a heat sink plate 1701, which may be AlN, SiC, Si, Cu, CuW, and the like. As shown in FIGS. 17(a)-17(d), the solder 1702 for bonding, which may be Au—Sn. Su-Ag—Cu, Ag paste, and the like, is disposed on the heat sink plate 1701. Then, an n-electrode 311 or p-electrode 305 is bonded to the solder 1702. The devices 111 can also be flip-chip bonded to the heat sink plate 1701.

In the case of bonding devices 111 to the heat sink plate 1701, the size of the heat sink plate 1701 does not matter, and it can be designed as desired.

Light-Reflecting DBR Mirror

The light reflecting layer mentioned in this invention is also referred to as a dielectric DBR mirror. The DBR mirror is comprised of, for example, a semiconductor multilayer film or a dielectric multilayer film. Examples of a dielectric materials include but not limited to Si, Mg, Al, Hf, Nb, Zr, Sc, Ta, Ga, Zn, Y, B, Ti, etc., or nitrides of these elements, like SiN, AlN, AlGaN, GaN, BN, etc., or oxides of these elements, like SiOx, TiOx, NbOx, ZrOx, TaOx, ZnOx, AlOx, HfOx, SiNx, AlNx, etc. The light reflecting layer can be obtained by alternatively laminating one or more dielectric materials having different refractive indices. The materials of different refractive indices, different thickness and various number of material layers chosen to obtain desired light reflectance. The thickness of each film of dielectric layer can be adjusted depending on the material and the oscillation wavelength of the emitted light from the resonant cavity.

Preferably, the thickness of these layers as odd multiples of a quarter of oscillation wavelengths. The reflectance of the two light reflective elements, one on the top and one on the bottom are different. These two lights reflecting elements including active layer, n-GaN layer and part of p-GaN layer collectively called as a resonant cavity. In general light emitting side of the device's light reflecting layer reflectance is smaller than the other side.

Current Confinement Region

The resonant cavity can be created by shaping current flowing through the VCSEL device 111 narrow enough to confine within the diameter of the resonant cavity of the aperture. This can be achieved by making the layers around the aperture where the current injection takes place more conductive than its neighborhood. For example, either using reactive ion etching or plasma etching, or dielectric masks, the neighboring region of the aperture can be made resistive.

### ALTERNATIVE EMBODIMENTS

### First Embodiment

A III-nitride-based semiconductor device 111 and a method for manufacturing thereof, according to a first embodiment are explained.

In the first embodiment, as shown in FIGS. 1(a)-1(c), a base substrate 101 or a host substrate 101 is first provided, and a growth restrict mask 102 that has a plurality of striped opening areas 103 is formed on the substrate 101.

In this embodiment, the island-like III-nitride semiconductor layers 109 are largely uniform with a very smooth surface. Thereafter, as shown in FIGS. 4(a)-4(g), 5(a)-5(i) and 10(a)-10(l), a light emitting aperture was defined on the ELO wing region through designing a current confinement region. One of the DBR mirrors of VCSEL is placed on the current confining region. VCSELs require light reflecting mirrors, such as DBRs, on top of current apertures to filter a selected wavelength.

The bar 110 of devices 111 containing the island-like III-nitride semiconductor layers 109 are removed using process #1 or process #2. The second light reflecting mirror is placed on the back region at the interface between the growth restrict mask 102 and the ELO III-nitride layer 105 interface, and then an n-electrode is defined, depending on the device 111 design as explained in FIGS. 10(a)-10(l). The island-like III-nitride semiconductor layers 109 are divided into devices 111 using a breaking method. This method can be applied before removing ELO III-nitride layers 105 from the host substrate 101. It is believed that there are a number of reasons why these methods obtain better results.

First, the island-like III-nitride semiconductor layers 109 are removed from the free standing GaN substrate 101. The freestanding GaN substrate 101 has a lot of defects, such as dislocations and stacking faults. However, only exposing a small region for epitaxial growth and allowing the epitaxial layers to relax on wing regions which have no direct contact with III-nitride substrate 101 vertically, one can realize a less defect regions for light emitting apertures. Moreover, the island-like III-nitride semiconductor layers 109 are made by MOCVD, so they have an extremely high crystal quality.

Second, the width of the open region and the height of the breaking area are very narrow and short, which causes epitaxial layers to be easily removed. The width is about 1-5 μm, and the height is about 5-180 μm. The island-like semiconductor layers 109 is processed by Steps 1-13 of the method set forth above, in order to obtain VCSELs.

When a non-coalesced stripe-like pattern approach is chosen to fabricate VCSEL devices 111 as discussed for semipolar and nonpolar ELO III-nitride layers 105, unlike the polar ELO III-nitride layers 105, the ELO III-nitride layers 105 of nonpolar and semipolar tend to form an aspect ratio with not much space to fabricate an entire VCSEL cavity and its electrode pads, for example, as illustrated in FIGS. 11(i), 11(j) and 11(k). In such a scenario, complex aspect ratio non-coalesced ELO III-nitride layers 105 formed on host substrate 101, as shown in FIGS. 11(i) and 11(j), are etched or polished back to an aspect ratio such as that shown in FIG. 11(k), which accommodates a complete device 111 structure as shown in FIGS. 10(a)-10(f).

This method is advantageous for obtaining smooth interfaces for fabricating DBR mirrors of a VCSEL device 111. General approaches like thinning substrate 101 or removing semiconductor layers by photo electrical etching for fabricating DBR mirrors is tedious and crystal orientation dependent. However, this approach is robust and crystal plane independent. Substrates 101 that are used to produce device layers 106 can be recycled several times for similar fabrication. The approach of this invention not only provides a smooth crystal interface for DBR mirrors, but also a good crystal quality device 111, as this invention proposes fabricating a resonant cavity completely on the ELO III-nitride layers 105 wing. Preferably, this does not include the open region of the substrate 101 from where the device layers 106 are grown.

### Second Embodiment

In a second embodiment, ELO III-nitride layers 105 on the III-nitride substrate 101 are made to coalesce as shown in FIGS. 2(a)-2(f). The remaining device 111 fabrication is similar to the first embodiment except an additional etching must be performed at the coalescence region 203 in order to remove ELO III-nitride layers 105 out of host substrate 101. After removing ELO III-nitride layers 105 from host substrate 101, a second DBR mirror of the resonant cavity is implemented following similar fabrication steps as mentioned in the first embodiment.

### Third Embodiment

The third embodiment is similar to the first and second embodiments for designing VCSEL devices 111, except for shaping a III-nitride substrate 101 surface which in previous embodiments was covered by a planar growth restrict mask 102. The growth restrict mask 102, the shape of which later serves as an interface for placing a second DBR, can be shaped either as a finite radius curve having a center of curvature away from the surface of the host substrate 101 or as a rectangular/tapered vessel surface as shown in FIGS. 4(a)-4(g) and 5(a)-5(i). Later, the shaped surface is covered with a growth restrict mask 102 leaving an open area exposed for the ELO III-nitride layers 105 growth. A slightly rectangular or tapered vessel shape can also be formed using a dry etching, like RIE, and two period mask patterns are shown in FIGS. 4(a)-4(g) and 5(a)-5(i).

FIG. 5(g) illustrates a patterned host substrate 101. To remove ELO III-nitride layers 105 where the interface was modified to a finite radius curvy surfaces, the host substrate 101 needs to be patterned with a two-period growth restrict mask 102. For example, dry etching as described in FIG. 5(a), or a electrochemical etching process as described in FIG. 4(a), or alternatively nano-imprinting the desired structure of growth restrict mask 102 on the host substrate 101, are a few of the possible techniques.

Throughout this invention, device 111 designs are displayed using a cross-sectional view even though their actual representation should be best presented with a top view stripe structure illustrated. One of such glimpses was given in FIG. 5(g) along with the cross-sectional view of FIG. 4(g) and 5(d). Alternatively, a patch structure of the growth restrict mask 102 displayed in FIG. 5(h) may also be followed in order to realize individual devices 111 as described in FIG. 4(g) and FIG. 5(f). In such a case, dividing a bar 110 of devices 11 into individual devices 111 can be avoided as compared to a stripe-like pattern used to fabricate devices 111.

Alternatively, this embodiment can also be practiced on a III-nitride substrate 101 having a highly doped III-nitride semiconductor layer 301.

Once the host substrate 101 is patterned as desired, ELO III-nitride layers 105 formed from the open region adopt the shape of the growth restrict mask 102 by leaving a smooth interface between the growth restrict mask 102 and ELO III-nitride layers 105. In particular, the patterned shape on the host substrate 101 serves as a wing of ELO III-nitride layer 105.

Once the desired ELO III-nitride layers 105 and semiconducting device layers 106 are formed, VCSEL device 111 processes are performed similar to those mentioned above. The ELO III-nitride layers 105 are removed from the host substrate 101 either by process #1 or process #2. A second DBR mirror of the resonant cavity of VCSEL is placed at the interface.

### Fourth Embodiment

The fourth embodiment uses process #2 and lifting devices 111 in pairs. For example, devices 111 are divided such that each unit contains two devices 111, one on each wing of the ELO III-nitride layers 105 separated by the open region. FIGS. 14(a)-14(g) are magnified views of the possible device 111 designs.

### Fifth Embodiment

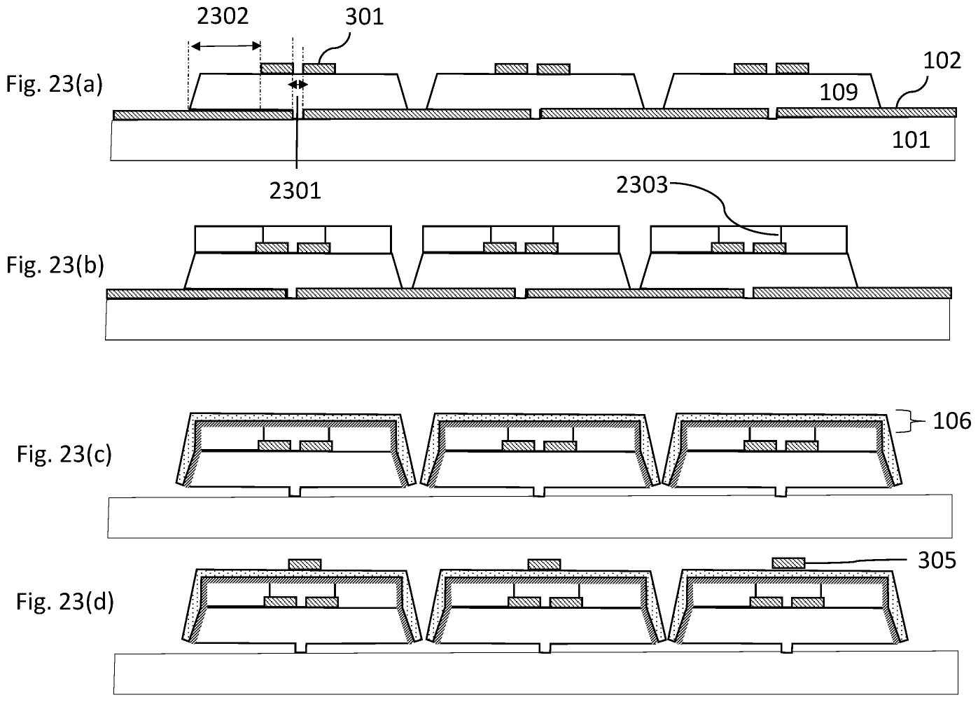

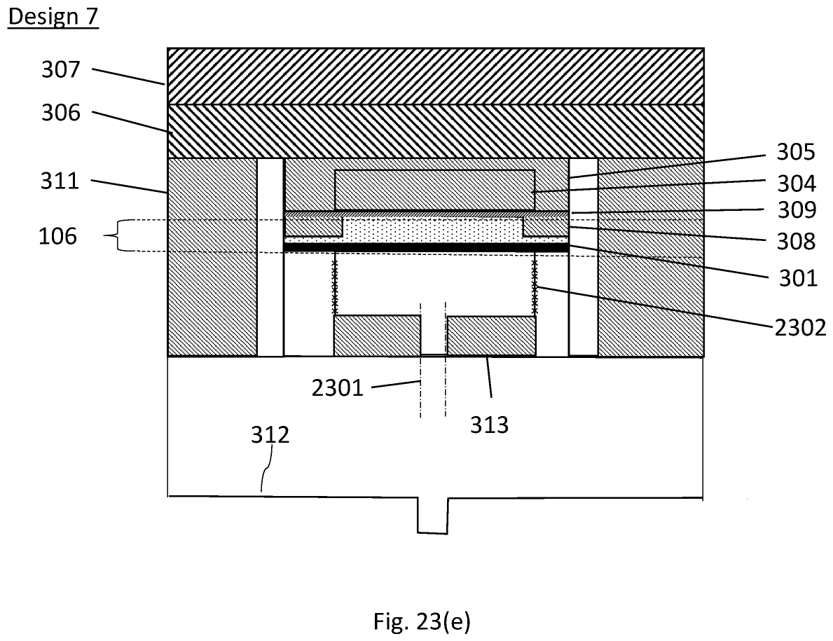

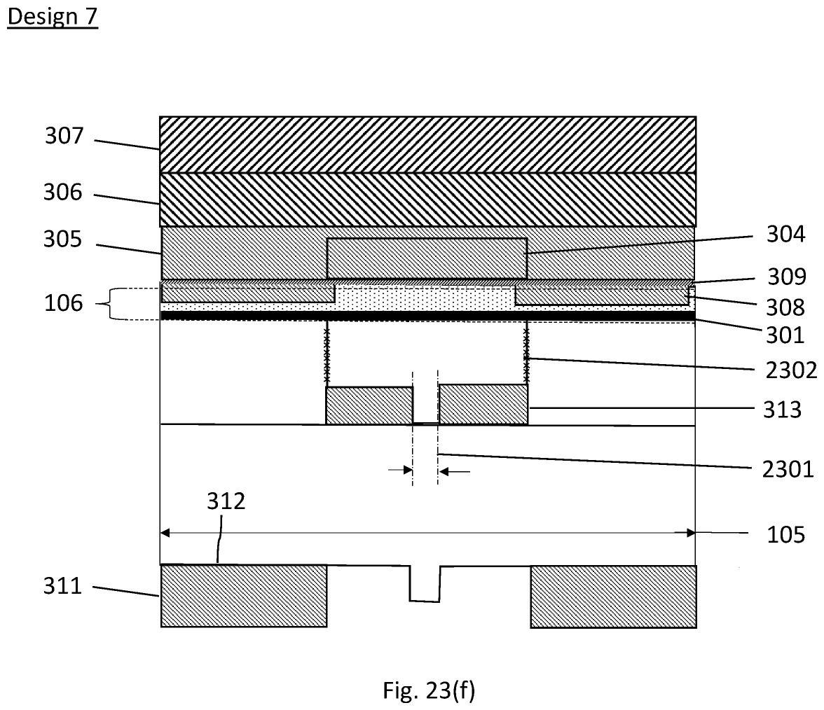

In a fifth embodiment, ELO can be performed at least two times, as shown in FIGS. 3(a)-3(m), as well as 23(a)-23(f). For the second ELO growth, the growth restrict mask 102 can be chosen as one of the light reflecting DBR mirrors, preferably, an n-GaN side light reflecting mirror. Specifically, FIGS. 23(a), 23(b), 23(c), 23(d), 231 and 23(f) represent a process for fabricating an embedded DBR resonant cavity VCSEL and magnified versions of possible designs.

For example, in the design shown in FIGS. 23(a)-23(f), the unwanted crystal quality obtained during the embed process of the light reflecting layer was separated from the resonant cavity path. The primary ELO III-nitride semiconductor layer 105 of the process can be used to extract heat generated from device 111 operation using an open region path 2301 at the host substrate 101 region.

This design can have several alterations, like using III-nitride semiconductor layers 105 for heat extraction or can thin them to avoid light emitting cone interference, or can open the p-side electrode pattern to allow light to emit by closing the n-side electrode structure, etc.

When process #2 is followed, a device 111 that was removed from the host substrate 101 can be carefully engineered to have two resonant cavities, one on each side wing of the open region, as shown in FIGS. 23(a)-23(f).

### Sixth Embodiment

In a sixth embodiment, AlGaN layers are used as the island-like III-nitride semiconductor layers 109. The AlGaN layers may be grown as an ELO III-nitride layer 105 on various off angle substrates 101, with an Al composition set to be 0.03-0.05. The AlGaN layers 109 can have a very smooth surface using the present invention. Using the present invention, the AlGaN layers 109 can be removed, as the island-like III-nitride semiconductor layers 109, from various off angle substrates 101.

### Seventh Embodiment

In a seventh embodiment, an ELO III-nitride layer 105 is grown on various off angle substrates 101. The off-angle orientations range from 0 to +15 degrees and 0 to −28 degrees from the m-plane towards the c-plane. The present invention can remove the bar 110 from the various off-angle substrates 101 without breaking the bars 110. When various crystal plane substrates 101 are used, the removed region of the bar 110 at the open area may process the cleaved surfaces like the staircase when bar 110 is removed mechanically, making the open area unsuitable for fabricating DBR mirrors for VCSEL devices 111; however, independent of crystal orientation, the surface on the bar's removed wing regions are smooth enough to fabricate such delicate DBR mirrors for VCSEL devices 111. For example, when a semi-polar bar 110 is removed from its host semi-polar plane, 20-2-1 or 20-21, the open region of the removed portion of the bar 110 may contain a cleaved non-polar plane, 10-10 or the like, which is at an angle of 75 or 15 degrees from the host semi-polar plane, and which looks like a staircase pattern at the open region, as shown in FIG. 8(k), however, wing region of the bar 110 shown in FIG. 8(i) contains a smoother surface than the open region. Thus, the proposal for fabricating DBR mirrors for VCSEL devices 111 on the wing region of the ELO region is a best solution independent of crystal planes. This is an advantage for this technique, as various off-angle orientations for semiconductor plane devices 111 can be realized without changing the fabrication process.

### Eighth Embodiment

In an eighth embodiment, an ELO III-nitride layer 105 is grown on c-plane substrates 101 with two different mis-cut orientation. The island-like III-nitride semiconductor layers 109 are removed after processing a desired device 111.

### Ninth Embodiment

In a ninth embodiment, a sapphire substrate 101 is used as the hetero-substrate. This structure is almost the same as the first embodiment's structure, except for using the sapphire substrate 101 and a buffer layer. In this embodiment, the buffer layer may also include an additional n-GaN layer or undoped GaN layer. The buffer layer is grown at a low temperature of about 500-700° C. degrees. The n-GaN layer or undoped GaN layer is grown at a higher temperature of about 900-1200° C. degrees. The total thickness is about 1-3 μm. Then, the growth restrict mask 102 is disposed on the buffer layer and the n-GaN layer or undoped GaN layer. The rest of process to complete the device 111 is the same as the first to fourth embodiments.

On the other hand, it is not necessary to use the buffer layer. For example, the growth restrict mask 102 can be disposed on the hetero-substrate 101 directly. After that, the ELO III-nitride layer 105 and/or III-nitride-based semiconductor device layers 106 can be grown. In this case, the interface between the hetero-substrate 101 surface and the bottom surface of the ELO III-nitride layer 105 divides easily due to the hetero-interface, which includes a lot of defects.

Employing the present invention, smooth interfaces of the ELO III-nitride layer 105 can be obtained for a resonant cavity, even using the hetero-substrate 101, because a wing region of the ELO III-nitride layer's 105, and an interface between the growth restrict mask 102 and the ELO III-nitride layer 105, are used as resonant cavity mirrors in the device 111.

The use of the hetero-substrate 101 also has a large impact for mass production. For example, the hetero substrate 101 used can be a low cost and large size substrate 101, such as sapphire, GaAs and Si, as compared to a free standing GaN substrate 101. This results in low cost devices 111. Moreover, sapphire and GaAs substrates are well known as low thermal conductivity materials, so devices 111 using these substrates have thermal problems. However, using the present invention, since the device 111 is removed from the hetero-substrate 101, it can avoid these thermal problems.

Furthermore, in the case using the ELO growth method for removing the bar 110 of the device 111, this method can reduce drastically dislocation density and stacking faults density, which has become a critical issue in the case of using hetero-substrates 101.

Therefore, this invention can solve many of the problems resulting from the use of hetero-substrates 101.

### Tenth Embodiment

A tenth embodiment removes the ELO III-nitride layers 105 using a secured delicate hook, which temporarily holds the ELO III-nitride layers 105 and releases them onto a either temporary carrier substrate or permanently bonding to a substrate. CMOS panel, or TFT back panel. Using ELO technique larger wings can be obtained, on these wings several devices 111 like, VCSELs, LEDs, power electronic devices can be fabricated. By doing so these devices 111 own a unique feature of reduced defects compared to devices 111 fabricated from conventional substrates.

This is described in FIGS. 7(a)-7(j). In the first part of hooking process, either coalesced III-nitride layers or discrete, as shown in FIG. 7(b); in both cases, the desired optical device 111 can be placed on top of the ELO III-nitride layers 105. The ELO III-nitride layers 105 are masked 701, for example, with SiO₂ layer deposited via chemical vapor deposition (CVD), atomic layer deposition (ALD), or sputtering. The mask 701 can be patterned such a way to extract a useful chip out of the ELO III-nitride layers 105 from the ELO wing by placing two different types of hooks 702. For example, in a Type-1 etching, an open ELO window is included in the mask 701 pattern, as shown in FIG. 7(c); therefore open ELO window acts as a hook 702 to hold the devices 111. Similarly, in a Type-2 etching, as shown in FIG. 7(g), which does not include an open ELO window, leads to several other types of hooks 702.

This process may be performed after finishing all the front-end processes on coalesced or discrete ELO III-nitride layers 105. For example, in the case of small size LEDs, the operating device 111 designed on the ELO wing includes p-electrode and n-electrodes on the III-nitride semiconducting layers 109 top side. The 701 mask used for etching the III-nitride layers 109 on the host substrate 101 can also be served as a passivation layer to protect from electrical leaks or improve efficiencies for small sized LEDs.

Using a mask 701, typically SiO₂, the desired chip dimensions are etched down at least to expose the growth restrict mask 102. Then, in Type-2 etching, a hook layer 702 is placed to contact the exposed growth restrict mask 102. Alternatively, the hook layer 702 may contact the host substrate 101 at the open ELO window. Also, the process of etching III-nitride semiconducting layers 109 down to expose the underlying growth restrict mask 102 can be done in two steps, for example, in the case of thicker III-nitride semiconducting layers 109, >10 μm, a hard mask 701 is used first to etch to slightly above the growth restrict mask 102, so that the underlying growth restrict mask 102 is not exposed at this time; then, in the second step, a soft mask 701, like the photoresist, is used to at least expose the underlying growth restrict mask 102. This configuration leads to one of the hooking 702 designs, Pattern 1 named in Type-2 etching. It may also be possible using only either a hard mask 701 and/or soft mask 701 that the underlying growth restrict mask 102 can be exposed without a two-step etching process.

In Type-2 etching, after exposing the underlaying growth restrict mask 102, the etched layers possess no support from the host substrate 101, as shown in FIG. 7(f), except that they are sandwiched between the growth restrict mask 102 and the etch mask 701. At this stage, III-nitride layered devices 111 not flown away from the host substrate 101. The inventors experimentally observed 100% remaining of the III-nitride layered devices 111 on the growth restrict mask 102 after exposing the growth restrict mask 102, see, for example, the optical microscope image in FIG. 7(h). The III-nitride layered devices 111 at this time are sandwiched between the growth restrict mask 102 and the mask 701 used for exposing the growth restrict mask 102. This is a unique configuration that only achievable using the approach of this invention. Even though the growth restrict layer for the ELO process was initially prepared at a low temperature, −300° C., during the formation of the III-nitride layers 109 in the MOCVD reactor chamber, the growth restrict mask 102 was exposed to higher temperatures, 1200° C., which would facilitated a weaker bond, for example, Van der Waals forces, between the growth restrict mask 102 and the backside of the III-nitride layers 109.

Alternatively, a further securing process may be possible by placing a thin layer, a chip securing layer 702, preferably a dielectric SiO₂ of thickness 10 nm to 300 nm, on top of the etch mask 701, as shown in FIG. 7(f). Several hook designs are shown in FIGS. 7(g) and 7(h), including Pattern 1, Pattern 2 and Pattern 3, which are made possible by selectively opening the etch mask 701 and chip secure layer 702. In FIG. 7(h), the inventors present an experimentally demonstrated Pattern 3 hook design, where the chip securing layer 702 protects the device 111 with a stripe running across the width of the device 111.

Now, a carrier wafer can be temporary or permanent, and may be attached to the III-nitride layered devices 111. Imposing ultrasonic or mechanical or thermal treatments, the only support hook layer 702 can be broken, and the devices 111 can be transferred onto the carrier wafer.

This unique process is helpful not only in solving the present micro-LEDs mass transfer problem, but also helps to realize unique patterns of VCSELs and dual clad edge emitting Fabry Perot lasers, as described below.

VCSEL: n-Side Curved Mirror on an Epitaxial Layer with No Substrate Involved

After placing a secured chip layer 702, the devices 111 may be transferred onto a temporary carrier 703 either using a crystal bond, electron wax or a temporary attachment layer, as indicated in FIG. 7(i). After transferring onto a temporary carrier 703, the back side of the devices 111 is patterned as concave by reflowing a resist and a curved mirror is fabricated on the back side of the devices 111 and the devices 111 are transferred back onto a permanent bonded wafer 706 for packaging, with light extracted from a p-side of the device 111. Using this process, and removing the substrate 101, light emission from the p-side is possible for VCSEL devices 111, whereas in other processes, such as photo-electro-chemical etching or electro-chemical etching, an n-side curved mirror on removed epitaxial layers may not be possible.

Dual clad Fabry Perot (FP) Laser

FIG. 7(j) illustrates a dual-clad Fabry Perot (FP) laser fabricated according to one embodiment of the present invention, wherein the FP laser is comprised of carrier plates 703, clad layer 707, n-GaN and waveguide layers 708, single or multiple quantum wells 709, p-GaN and waveguide layers 710, and ITO clad layer 711. Unlike dividing III-nitride layer devices 111 into small-sized LEDs or VCSELs, an FP laser can be designed on the ELO wing by placing a ridge structure 712 and confinement layers 707, 708, 710, 711 on the ELO wing region. For example, placing an ITO layer 711 externally as one clad layer before removing a laser bar 110 by any of the above discussed hooking techniques and, after removal, another clad layer 707, such as Aluminum Nitride (AlN), is placed externally. This process is more controllable to achieve dual clad FP lasers, as the ELO wings' thickness in the n-GaN and waveguide layers 708 can be controlled epitaxially for the very critical design of long-wavelength lasers and exactly designed laser epitaxial layers are removed from the growth restrict mask 102 surface. Two clad layers 707, 711 are externally placed using, for example, sputter, Electron Beam, ECR, CVD, etc. Alternatively, in the case where the FP laser's back surface of the ELO wing in the n-GaN and waveguide layers 708 is not necessarily flat, even if thickness on the n-GaN base layer exceeds the desired dimension, one can etch back to the desired value after transferring the FP laser bars 110 onto a carrier 703 before placing a second clad layer 711. In this configuration, junction down or sandwiched cooling techniques can be imposed on the final device 111 for better thermal management.

Mass Production

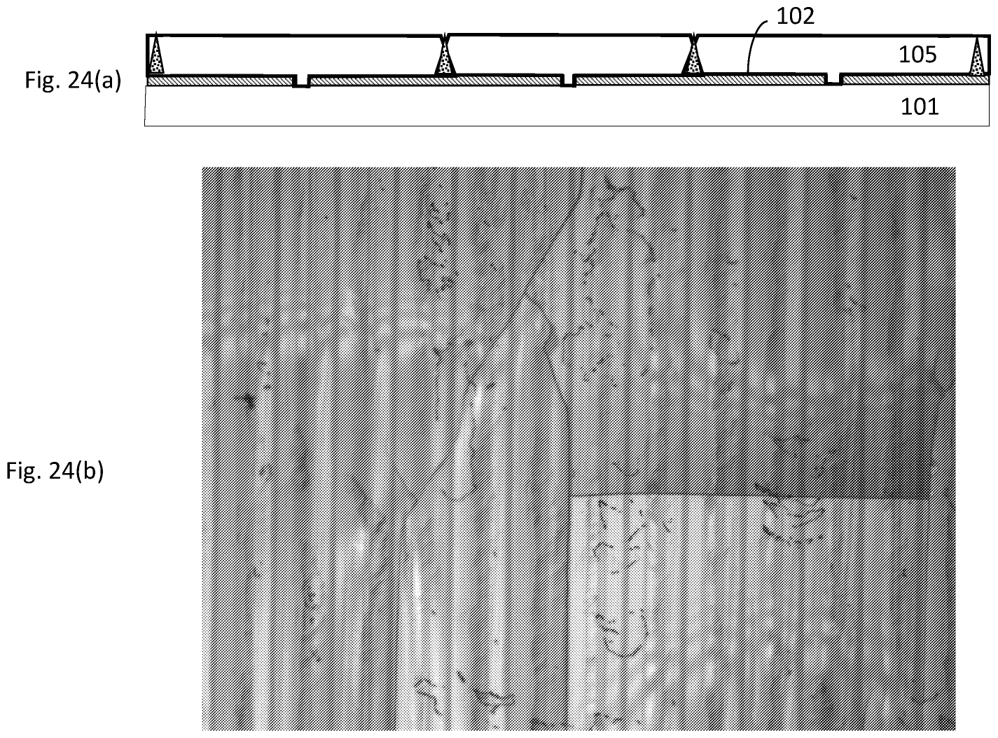

One of the designs experimented with embedding a DBR-like mirror structure, for example, a growth restrict mask 102 with ELO III-nitride layers 105 as shown in FIG. 24(a). However, cracks were generated on the surface of ELO III-nitride layers 105 as shown in FIG. 24(b). Specifically, FIG. 24(a) illustrates a growth restrict mask 102 embedded by ELO III-nitride layers 105, and FIG. 24(b) shows visible cracks in the surface of the ELO III-nitride layers 105.

Thermal expansion coefficients of embedded DBR mirror material, mostly dielectric layers from the growth restrict mask 102, and semiconducting ELO III-nitride layers 105 differ significantly. As a result, significant stress will be developed between these layers 102, 105 when temperatures of the environment change. In general, ELO III-nitride layers 105 are fabricated in an MOCVD environment around 700° C.-1200° C. and they must be cooled down to room temperatures for fabrication of devices 111. This is the most frequent scenario when embedded DBR mirror patterns are implemented.

The built-up internal stress between the ELO III-nitride layers 105 and DBR mirror material 102 may gradually lead to cracks being generated in the layers of the device 111. This also makes for unreliable contact between the embedded DBR mirror 102 and the ELO III-nitride layers 105 laid on top of it. The cracks in the layers of the device 111 attract moisture and make the DBRs vulnerable to the environment and, in a worst case scenario, device layers 106 can be self-lifted. This will affect the reflectivity of the DBR mirrors and the longevity of the device 111. Experimentally, cracks in the ELO III-nitride layers 105 were observed when a growth restrict mask 102, comprising a dielectric layer of SiO₂, was embedded by forming ELO III-nitride layers 105 on top of growth restrict mask 102, as shown in FIGS. 24(a)-24(b). These cracks not only reduce the yield, but also diminish the characteristics of the device 111.

In summary, when a DBR mirror is placed without first removing the ELO III-nitride layers 105, several reliability problems follow:
Built-in internal stress and ELO III-nitride layers 105 weakly-bonded to the DBR mirrors may cause peel-off and cracks in the device layers 106, thus resulting in reliability and yield problems.
Differences in thermal expansion coefficients of dielectric materials 102 and the semiconducting host substrate 101 induces internal stress between the device layers 106 and the DBR mirrors, resulting in cracks in the device layers 106.
Unreliable contact is established at the interface between the DBR mirrors and the device layers 106 which will affect yield, reliability, and efficiency of the device 111.
The DBR mirror degrades from its original designed characteristics by attracting moisture from the cracks.
To form ELO III-nitride layers 105 on surface of the DBR mirror, the top surface of the DBR mirror must be chosen to accommodate a good crystal ELO layer. If a proper DBR material is not chosen, then debris from the ELO material will randomly sit on the surface of the DBR mirror, and thus effect the yield and reliability.
If a device 111 includes the host substrate 101, the device 111 will be expensive.
Light emitting from the device 111 can be absorbed in the included host substrate 101, so thinning must be introduced, with its additional cost and where the byproduct of thinning is useless.
Uniform and planar distribution of thinning is difficult by polishing and etching methods.
Non-planar shaped DBR mirrors are not possible in such a case.
Careful designs must be followed to avoid unwanted crystal quality that arises at the coalescence regions.

The weak bond between the ELO III-nitride layers 105 and the DBR mirror, which may have adverse effects, may also be advantageous in certain aspects:
1. ELO III-nitride layers 105 weakly-bonded to the DBR mirror preserves a smooth interface at the back surface of the ELO III-nitride layers 105.
2. ELO III-nitride layers 105 weakly-bonded to the DBR mirror can assist in the removal processes mentioned above with improved yields.
3. There is a flexibility in choosing a single or double layered growth restrict mask 102, instead of a complex dielectric layer pair of general DBR designs.
4. There is a reduced about whether the DBR mirror material was exposed to extreme temperature conditions.

This invention mitigates these problems by taking advantage of the weakly-bonded interface between the DBR mirror and the ELO III-nitride layers 105:
1. On the preserved smooth interface at the ELO III-nitride layers 105 back surface due to weak bond we place a desired DBR mirror design externally after removing ELO III-nitride layers 105. For example, one could use surface activation bonding with an external pre-pared DBR mirror, or sputter or deposit DBR layers for a better bond higher reliability.
2. Weak bond assist removal of ELO III-nitride layered devices 111 attain better yields.

Additionally, the DBR mirror may be deposited externally after removing the ELO III-nitride layers 105 or device layers 106 from the host substrate 101. By doing so, the device layers 106 become stress-free due to their free-standing nature. Next, a DBR mirror may be deposited or placed at the interface of the ELO wing region, which makes a reliable bonding with the wing interface, thus making the desired function of the DBR realizable.

Preferably, the DBR should be placed at least 1 μm distance away L from the edge of the etched portions to avoid etch damage. It was experimentally observed that the interface of the removed ELO wing has a roughness less than 2 nm and, at most, can reach to a sub-nanometer level. Further, improvements in the reduction of the interface's roughness was proposed using a multi-layer approach or a thermally stable growth restrict mask 102 or material parameter development.

In the end, the approach of this invention is cost effective, since the device 111 is removed from the host substrate 101 and the host substrate 101 can be recycled several times.

Alternative Designs

Design 1

The above portion of this application describes one type of design, known as Design 1, as shown in FIG. 10(g). Alternative designs are also available, as described below.

Design 2

Another type of design, known as Design 2, is shown in FIGS. 10(h) and 14(c).

In this design, the first light reflecting mirror 301 was designed at a designated portion of the wing regions of the ELO III-nitride layer 105 by defining a current confinement region 308 on the p-GaN side.

Later, a current spreading layer 309 and a contact layer, for example ITO, are deposited on the region comprising the current confinement aperture. Light reflecting DBR mirror 301 is a combination of dielectric layers with different refractive indices placed over the current confinement aperture such that the contact layer lies between the p-GaN and DBR.

At this stage, a single aperture device 111 as shown in FIG. 10(h) or a double aperture device 111 as shown in FIG. 14(c) can be fabricated by patterning the p-pad 305 accordingly. In the case of single aperture design, the p-pad 305 is lithographically defined to assist aperture dividing. These designs define the p-pad 305 and n-pad 311 on same side. For defining the n-pad 311, the III-nitride semiconductor 105, 106, 109 layers are top down etched to reach the n-GaN layer and then the n-pad 305 is deposited.

Later, single or double aperture bars 110 are then attached to the carrier plate 307 via a bonding layer 306. The devices 111 are then removed from the substrate 101 using an adhesive film.

A second light reflecting mirror 313 is blanket deposited at the backside of the device 111, which is n-GaN, at the side at the interface 312 between the growth restrict mask 102 and the ELO III-nitride layers 105.

Design 3

Another type of design, known as Design 3, is shown in FIGS. 10(i) and 14(d).

In this design, the first light reflecting mirror is designed at a designated portion of the wing regions of the bar 110 by defining a current confinement region 308 on the p-GaN side.

Later, a current spreading layer 309 and a contact layer, for example ITO, are deposited on the region comprising the current confinement aperture. Light reflecting DBR mirror 301, which is a combination of dielectric layers with different refractive indices, is placed over the current confinement aperture such that the contact layer lies between the p-GaN and DBR.

At this stage, a single aperture device 111 as shown in FIG. 10(i) or a double aperture device 111 as shown in FIG. 14(d) can be fabricated by patterning the p-pad 305 accordingly. In the case of a single aperture design, the p-pad is lithographically defined to assist aperture dividing.

The device 111 is attached to a carrier 307 via bonding layer 306. The devices 111 are then removed from the substrate 101 using an adhesive film. Then, a convex shape 1010 is transferred onto the n-GaN side at the interface between the growth restrict mask 102 and the ELO region, lithographically.

The second light reflecting DBR mirror 313 is deposited on the convex shape. The n-pad is blanket deposited for electrical connection.

Finally, the device 111 is transferred onto a carrier plate 307a via bonding layer 306a. Or, by selecting a carrier 307 and bonding layer 306 transparent to emitting light of the device 111, one can avoid the transfer process to a second carrier plate 307a.

Design 4

Another type of design, known as Design 4, is shown in FIGS. 10(j) and 14(e).

In this design, the first light reflecting mirror is designed at a designated portion of the wing regions of the bar 110 by defining a current confinement region 308 on the p-GaN side.

Later, a current spreading layer 309 and a contact layer, for example ITO, are deposited on the region comprising the current confinement aperture. Light reflecting DBR mirror 301, which is a combination of dielectric layers with different refractive indices, is placed over the current confinement aperture such that the contact layer lies between the p-GaN and DBR.

At this stage, a single aperture device 111 as shown in FIG. 10(j) or a double aperture device 111 as shown in FIG. 14(e) can be fabricated by patterning the p-pad 305 accordingly. In the case of single aperture design, the p-pad 305 is lithographically defined to assist aperture dividing. This design defines the n-pad 305 and p-pad 311 on the same side.

To define the n-pad 311, the III-nitride semiconductor layers 105, 106, 109 are etched from the top down to expose the n-GaN layer. The n-pad 311 is deposited at the designated portion.

The device 111 is attached to a carrier 307 via bonding layer 307. The devices 111 are then removed from the substrate 101 using an adhesive film. Then, a convex shape is transferred onto the n-GaN side at the interface between the growth restrict mask 102 and the ELO III-nitride layer 105, lithographically.

The second light reflecting DBR mirror 313 is deposited on the convex shape.

Finally, the device 111 is transferred onto a carrier plate 307a via bonding layer 306a.

Or, by selecting a carrier 307 and bonding layer 306 transparent to emitting light of the device 111, one can avoid the transfer process to a second carrier plate 307a.

Design 5

Another type of design, known as Design 5, is shown in FIGS. 10(k) and 14(f).

This design can be fabricated on III-nitride layers grown by the methods mentioned in FIG. 1(c) and FIG. 11(b).

In this design, a convex shape was patterned on the p-side of the device 111. Specifically, the III-nitride base epitaxial layers 106 of the device 111 terminated with a p-type layer. To fabricate a curved surface, a thick n-GaN layer 310 was re-deposited on the p-GaN layer, after defining a current confinement region 308 in the p-layer.

A convex shape is then patterned on the thicker n-GaN layer on either side of the open region conforming to the wing region of the ELO. A current spreading layer 309, for example ITO, was deposited over the convex region, and a light reflective element 313 was then deposited on the convex shape followed by a p-pad 305.

At this stage, a single aperture device 111 as shown in FIG. 10(k) or a double aperture device 111 as shown in FIG. 14(f) can be distinguished by patterning a p-pad 305 accordingly. In the case of single aperture design, the p-pads 305 are lithographically defined to assist aperture dividing.

The device 111 is then attached to a carrier 307 via bonding layer 306. The devices 111 are then removed from the substrate 101 using an adhesive film.

On the backside of the device 111, which is n-GaN, at the interface 312 between the growth restrict mask 102 and the ELO III-nitride layers 105, a second light reflecting mirror 313 is defined lithographically and n-pads 311 are deposited to contact the n-GaN layer.

Design 6

Another type of design, known as Design 6, is shown in FIGS. 10(l) and 14(g).

In this design, a convex shape was patterned on the p-side of the device 111. Specifically, the III-nitride base epitaxial layers 106 of the device 111 terminated with a p-type layer. To fabricate a curved surface, a thick n-GaN layer 310 was re-deposited on the p-GaN layer, after defining a current confinement region 308 in the p-layer.

A convex shape was patterned on the thicker n-GaN layer 310 on either side of the open region conforming to the wing region of the ELO III-nitride layer 105. A current spreading layer 309, for example, ITO, is deposited over the convex region, and a light reflective element 301 was then deposited on the convex shape followed by a p-pad layer 305.

In this design, the n-pad 311 and p-pad 305 are on the same side of the device 111, where the III-nitride semiconductor layers 105, 106, 109 are etched from the top down and the n-pad 311 was deposited at the designated region.

At this stage, a single aperture device 111 as shown in FIG. 10(l) or a double aperture device 111 as shown in FIG. 14(g) can be distinguished by patterning p-pad 305 and n-pad 311 accordingly.

The device 111 is attached to a carrier 307 via a bonding layer 306. The devices 111 are then removed from the substrate 101 using an adhesive film.

On the backside of the device 111, which is n-GaN, at the interface 312 between the growth restrict mask 102 and the ELO III-nitride layers 105, a second light reflecting mirror 313 is defined lithographically or blanked deposited to finish the device 111.

Design 7

Another type of design, known as Design 7, is shown in FIGS. 3(l), 3(m), 23(a)-23(f).

In this design, the light reflecting mirror DBR 301 is placed over initially grown coalesced III-nitride semiconductor layers 105. The DBR 301 is embedded in the second stage of MOCVD growth as a result a coalescence line that appears above the newly established growth restrict mask 303. Once the DBR 301 is embedded, the III-nitride semiconductor layers 106 containing active and p-GaN layers are grown, as shown in FIG. 3(c).

The design of FIG. 3(l) contains a p-pad 305 and n-pad 311 on the same side of the device 111. A current confinement layer 308 is designed at the designated place on the p-GaN layer using lithography. Afterwards, a current spreading layer 309 is placed over the p-GaN layer containing a current confinement aperture. A light reflecting DBR mirror 313 is placed over the current confining aperture. Then, a p-pad 305 is defined over the light reflecting DBR mirror and an n-pad 311 is deposited on the n-GaN layers by etching the device 111 from the top down until the n-GaN layers are exposed. The device 111 is attached to a carrier 307 via bonding layer 306. The devices 111 are then removed from the substrate 101 using an adhesive film.

In FIGS. 23(a)-23(d), a light reflecting DBR mirror 301 may be placed over the initially-grown island-like III-nitride semiconductor layers 109. The DBR mirror 301 will be embedded in the second stage of MOCVD growth as a result of a coalescence line, which will appear above the growth restrict mask 102. The position of the line can be adjusted by exposing areas 2301 and 2302. For example, by making open area 2301 width lie in-between the widths of the growth restrict mask 102 and the exposed area including the layer bending region 108 and the width of area 2302 being larger than area 2301, the DBR mirror 310 can be embedded such that a coalescence line 2303 stays at the edge of the DBR mirror 301. Thus, the distance between two coalescence lines 2303 can be manipulated to obtain a quality epitaxial region area for the DBR mirror 301. Once DBR 301 is embedded as shown in FIG. 23(b), the III-nitride semiconductor layers 106 containing the active and p-GaN layers are grown, as shown in FIG. 23(c), and a p-pad 305 is deposited as shown in FIG. 23(d).

The p-pad 305 and n-pad 311 are on opposite sides of the device 111. A current confinement layer 308 is designed at the designated place on the p-GaN layer using lithography. Afterwards, a current spreading layer 309 is placed over the p-GaN layer containing the current confinement aperture. A light reflecting DBR mirror 301 is placed over the current confining aperture. The design is only used with a single aperture. The aperture on the p-side basically overlaps between two wing regions obtained during two ELO growths, and more specifically, between two coalescence lines generated from the secondary ELO growth. The p-pad 305 is defined over the light reflecting mirror 301. The device 111 is attached to a carrier 307 via bonding layer 306. The devices 111 are then removed from the substrate 101 using an adhesive film. The n-pad 311 is then deposited on the back side at the designated area in a manner that does not obstruct emitting light.

In FIGS. 23(e) and 23(f), the p-pad 305 and n-pad 311 are on opposite sides of the device 111. A current confinement layer 308 is designed at the designated place on the p-GaN layer using lithography. Afterwards, a current spreading layer 309 is placed over the p-GaN layer containing the current confinement aperture. A light reflecting DBR mirror 301 is placed over the current confining aperture. The design is only used with a single aperture. The aperture on the p-side basically overlaps between two wing regions obtained during two ELO growths, and more specifically, between two coalescence lines generated from the secondary ELO growth. The p-pad 305 is defined over the light reflecting mirror 301. The device 111 is attached to a carrier 307 via bonding layer 306. The devices 111 are then removed from the substrate 101 using an adhesive film. The n-pad 311 is then deposited on the back side at the designated area in a manner that does not obstruct emitting light.

Pattern 1

Pattern 1 is illustrated in FIGS. 4(a)-4(g), which is a set of designs that require pre-processing before actual ELO is performed. The shapes shown in FIGS. 4(a)-4(g) can be obtained in several methods,

For example, Pattern 1 of FIGS. 4(a)-4(g) can be obtained by the following steps:
i. A highly doped III-nitride layer 401 is deposited on the III-nitride substrate 101.
ii. A mask 402 in the form of stripes, having two different widths x, y separated by a distance z is deposited on the highly doped III-nitride layer 401.
iii. The highly doped III-nitride layer 401 is selectively etched, for example, using electro chemical etching.
iv. The resulting concave shapes 403 can appear at the selectively etched regions.
v. The resulting concave shapes 403 are covered with a growth restrict mark 404, while selectively opening regions 405 of width 1 μm-10 μm between two concave shapes 403. The opening region 405 is preferably less than 5 μm.

Pattern 2

Pattern 2 is illustrated in FIGS. 5(a)-5(g), which is a set of designs that require pre-processing before the actual ELO is performed. The shapes shown in FIGS. 5(a)-5(g) can be obtained in several methods.

For example, Pattern 2 in FIGS. 5(a)-5(g) can be obtained by the following steps:
i. A highly doped III-nitride layer 501 is deposited on the III-nitride substrate 101. Alternatively, this pattern can utilize a III-nitride substrate 101 without a highly doped layer.
ii. A mask 502 in the form of stripes, having two different widths x, y separated by a distance z is deposited on the highly doped III-nitride layer 501.
iii. The highly doped III-nitride layer 501 is then selectively dry etched, for example, using reactive ion etching, resulting in recessed shapes 503 that can appear at the selectively etched regions.
iv. The substrate 101 comprising recessed regions is then covered with a growth restrict mark 504 while selectively opening regions 505 of width 1 μm-10 μm between two consecutive recessed shapes 503. The opening region 505 is preferably less than 5 μm.

Design 8: Devices on Pattern 1

In this design, known as Design 8 with Pattern 1, epitaxial layers are grown laterally on the patterned mask from FIGS. 4(a)-4(g).

The III-nitride epitaxial layers 105 take the concave shape 403 at the window on either side of the open region 405. Later, III-nitride base layers 106 comprising active and p-GaN layers are grown over 405. The device 111 can be singulated with a single aperture device 111 or can be integrated as whole containing two apertures as a single device 111 as desired.

The device 111 configuration is best suited for a long-cavity resonating cavity 412 between two light reflecting mirrors 408, 413. By having long light reflecting cavities, better thermal management and less tolerance to active layer placement in the cavity 412 can be achieved, and therefore more feasible manufacturability can be foreseen.

After growing the active and p-GaN layers on top of the base III-nitride semiconductor layers, a current confinement layer 406 is designed at the designated place on the p-GaN layer using lithography. Afterwards, a current spreading layer 407 is placed over the p-GaN layer containing the current confinement aperture. A light reflecting mirror 408, such as a DBR mirror, is placed over the current confining aperture. Single or double apertures are feasible with these designs. The aperture on the p-side is placed vertically above the concave shaped region. The p-pad 409 is defined over the light reflecting mirror.

The device 111 is then attached to a carrier 410 via bonding layer 411. The devices 111 are then removed from the substrate 101 using an adhesive film. After transferring the devices 111 onto a carrier, a light reflecting mirror is deposited on the convex shape region (when looking at the backside of the device 111) and then n-pads are defined.

If only a device 111 with a single aperture is needed, then separation of the double aperture device 111 along the YY′ line may be made as indicated in FIG. 5(f).

If the carrier and the bonding layers are transparent to the emitted light of the aperture, then no further transfer is required; however, if an opaque carrier and/or bonding layer is chosen, then the devices 111 must be transferred to a carrier 410 using a bonding layer 411 after fabricating the n-side light reflecting mirror and n-pad.

Design 9: Devices on Pattern 2

In this design, known as Design with Pattern 2, epitaxial layers are laterally grown on a patterned mask shown in FIGS. 5(a)-5(g). The devices 111 of this type can also be fabricated on an epi-ready III-nitride substrate 101 without a highly doped layer 501 on top. These designs can be fabricated using a double period dry etching mask. The shape of the second reflecting element is slightly different as compared to FIG. 3(a). A dry etching can result anywhere between sharp edges or tapered edges piercing towards the III-nitride semiconductor ELO III-nitride layers 105.

The III-nitride epitaxial layers 105 take the designed shape (sharp or tapered) 510 at the window on either side of the open region 505. Later, III-nitride base layers 106 comprising active and p-Gan layers are grown over 105. The device 111 can be singulated as a single aperture device 111 or can be integrated as a whole containing two apertures as a single device 111 as per the demand.

The device 111 configuration is best suited for a long-cavity resonating cavity 512 between two light reflecting mirrors. By having long light reflecting cavities, better thermal management and less tolerance to active layer placement in the cavity can be achieved, therefore feasible manufacturability can be foreseen.

After growing the active and p-GaN layers on top of base III-nitride semiconductor layers, a current confinement layer 506 is designed at the designated place on the p-GaN layer using lithography. Afterwards, a current spreading layer 507 is placed over the p-GaN layer containing the current confinement aperture. A light reflecting mirror 508 is placed over the current confining aperture. Single or double apertures are feasible in these designs. The aperture on the p-side is placed vertically above the concave shaped region. The p-pad 509 is defined over the light reflecting mirror.

The device 111 is then attached to a carrier 510 via bonding layer 511. The devices 111 are then removed from the substrate 101 using an adhesive film. After transferring the devices 111 onto carrier 510, a light reflecting mirror is deposited on the designed shape 504 (when looking at the backside of the device 111) and n-pads are defined.

If only a device 111 with a single aperture is needed, then separation of the double aperture device 111 is made along YY′ line as indicated in FIG. 5(f).

If the carrier and the bonding layers are transparent to the emitted light of the aperture, then no further transfer is required; however, if an opaque carrier and/or bonding layer is chosen, then the devices 111 must be transferred to a carrier 510 using a bonding layer 511 after fabricating the n-side light reflecting mirror and n-pad.

The devices 111 described above are comprised of the following III-nitride semiconductor device layers 106 laid one on top of another, in the order mentioned, grown on the ELO III-nitride layers 105 deposited on the growth restrict mask 102; an n-Al_{0.06}GaN clad layer, an n-GaN guiding layer, an InGaN/GaN multiple quantum well (MQW) active layer, an AlGaN EBL layer, a p-GaN waveguide layer, an ITO cladding layer, an SiO₂ current limiting layer (or reactive ion etching can used to limit the current to aperture), and a p-electrode.

An optical resonator is comprised of a cavity structure, wherein a cavity is formed at the top and bottom of the device 111. A dielectric DBR, also referred to as a light reflecting mirror, is comprised of multiple dielectric layers with different refractive indices. The optical resonator provides optical confinement in a vertical direction. The length between two DBRs of the optical resonator structure is on the order of 5 to 50 μm and typically is 10 μm. ITO used as current spreading layer.

Conventional methods, such as photolithography and dry etching or reactive ion etching, can be used to fabricate the aperture structure. The current confinement region depth (from the top surface to the bottom surface) is in the p-GaN waveguide layer. The region of interest for current blocking is pre-determined before etching is performed, based on simulation or previous experimental data.

In one embodiment, the p-electrode 509 may be comprised of one or more of the following materials: Pd, Ni, Ti, Pt, Mo, W. Ag, Au, etc. For example, the p-electrode 509 may comprise Pd—Ni—Au (with thicknesses of 3-30-300 nm). These materials may be deposited by electron beam evaporation, sputter, thermal heat evaporation, etc. In addition, the p-electrode 509 is typically deposited on the ITO current spreading layer 507.

Process Steps

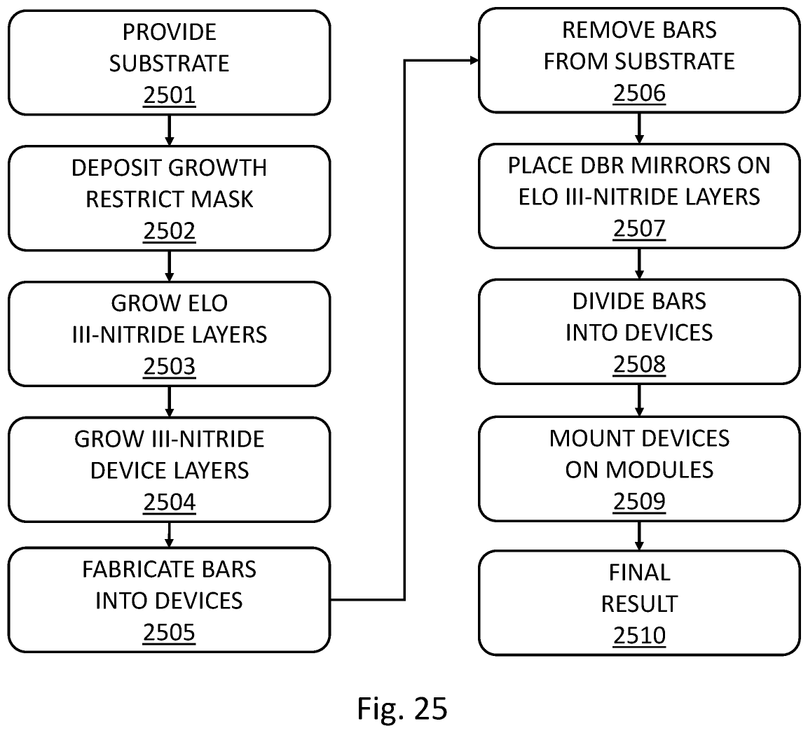

FIG. 25 is a flowchart that illustrates a method for fabricating good quality light emitting apertures for VCSEL devices 111 on ELO wing regions of ELO III-nitride layers 105, wherein: one or more bars 110 of devices 111 comprised of III-nitride semiconductor layers 105, 106, 109 are formed on the substrate 101. The steps of the method are described in more detail below.

Block 2501 represents the step of providing a host substrate 101. In one embodiment, the substrate 101 is a semiconducting substrate, independent of crystal orientations, such as III-nitride based substrate 101, for example, a GaN-based substrate 101, or a hetero-substrate 101, such as a sapphire substrate 101. This step may also include an optional step of depositing a template layer on or above the substrate 101, wherein the template layer may comprise a buffer layer or an intermediate layer, such as a GaN underlayer.

Block 2502 represents the step of depositing a growth restrict mask 102 on or above the substrate 101, i.e., on the substrate 101 itself or on the template layer. The growth restrict mask 102 is patterned to include a plurality of striped opening areas 103. The growth restrict mask 102 may comprises a multi-layer structure.

Block 2503 represents the step of forming one or more III-nitride layers 105 on or above the growth restrict mask 102 using epitaxial lateral overgrowth (ELO). This step may or may not include stopping the growth of the ELO III-nitride layers 105 before adjacent ones of the ELO III-nitride layers 105 coalesce to each other.

Block 2504 represents the step of growing one or more III-nitride device layers 106 on or above the ELO III-nitride layers 105, thereby fabricating a bar 110 forming one or more devices 111 on the substrate 101. Additional device 111 fabrication may take place before and/or after the bar 110 is removed from the substrate 101.

Block 2505 represents the step of fabricating the bars 110 into devices 111.

Block 2506 represents the steps of removing the bar 110 comprised of the ELO III-nitride layers 105 and the III-nitride device layers 106 from the substrate 101. The removed ELO III-nitride layers 105 contain at least a partially processed portion of the VCSEL device 111. A thickness of the removed ELO III-nitride layers 105 are controlled epitaxially to realize a functional version of the VCSEL device 111. At least one of the removed ELO III-nitride layers 105 is used to extract heat from the VCSEL device 111 during device 111 operation.

Block 2507 represents the steps of placing one or more dielectric distributed Bragg reflector (DBR) mirrors for a resonant cavity of the VCSEL device 111 on a backside of the removed ELO III-nitride layers 105, wherein the backside of the removed ELO III-nitride layers 105 has a non-planar shape and the dielectric DBR mirrors are placed on the backside of the removed ELO III-nitride layers 105 at a wing region of the removed ELO III-nitride layers 105. The host substrate is pre-patterned to realize the non-planar shape, and the non-planar shape comprises a curvature, the backside of the removed ELO III-nitride layers 105 has a finite radius of the curvature, and a center of the curvature is on a side of the host substrate's 101 surface. At least one of the dielectric DBR mirrors is sandwiched between the removed ELO III-nitride layers 105. The dielectric DBR mirrors are placed on the backside of the removed ELO III-nitride layers 105 at a distance of at least 1 μm away from a coalesced region and open area 103 edge. The resonant cavity of the VCSEL device 111 formed by the DBR mirrors does not contain a substantial portion of the host substrate 101.

Block 2508 represents the optional step of dividing the bar 110 into one or more devices 111 at dividing support regions formed along the bar 110.

Block 2509 represents the step of mounting the devices 111 in a module, wherein the devices 111 are mounted to a stem and stage of the module.

Block 2510 represents the resulting product of the method, namely, one or more III-nitride based semiconductor devices 111, such as VCSEL devices 111, fabricated according to this method, as well as a substrate 101 that has been removed from the devices 111 and is available for recycling and reuse.

The devices 111 may comprise one or more ELO III-nitride layers 105 grown on or above a growth restrict mask 102 on a substrate 101, wherein the growth of the ELO III-nitride layers 105 is stopped before adjacent ones of the ELO III-nitride layers 105 coalesce to each other. The devices 111 may further comprise one or more additional III-nitride device layers 106 grown on or above the ELO III-nitride layers 105 and the substrate 101.

Advantages and Benefits

The present invention provides a number of advantages and benefits:
Expensive III-nitride based substrates 101 can be reused after the substrates 101 are removed from the device layers 106.
High quality layers 105, 106, 109 may be obtained using a substrate 101 of the same or similar materials, with a very low defect density.
Using the same or similar materials for both the substrate 101 and the layers 105, 106, 109 can reduce the strain in the layers 105, 106, 109.
Using materials with the same or similar thermal expansion for both the substrate 101 and the layers 105, 106, 109 can reduce bending of the substrate 101 during epitaxial growth.
Layers 105 grown by ELO have a good crystal quality.
When the ELO III-nitride layers 105 do not coalesce with each other, internal strain is released, which helps to avoid any occurrences of cracks. For device layers 106 that are AlGaN layers, this is very useful, especially in the case of high Al content layers.
The resonant cavity of the VCSEL device 111 is fabricated on an ELO wing region.
The ELO wing region is a low defect region area, which improves characteristics of the device 111.
There is no need for a tedious substrate thinning process to fabricate a second DBR mirror of the cavity. Thinning is needed for conventional fabrication in order to avoid significant absorption of emitted wavelength of the device 111.
Alternate processes like photo chemical etching processes to remove semiconductor layers are crystal plane dependent and extremely slow. However, the methods described herein have no crystal plane dependency. Any plane of the crystal can obtain a smooth interface at the growth restrict mask 102 by controlling parameters of the growth restrict mask 102 and growth.
On the other hand, the method of removing in this invention is not expensive, is robust, and can be used for mass transfer.
After removing the ELO III-nitride layers 105, they can be simply surface bonded to an external prepared DBR mirror by surface activation or diffusion bonding, because the interface of the removed layers is smooth enough to assist such bonding techniques
Embedded DBR mirror designs works better for managing heat.
Long cavity curved mirror structures can be fabricated without involving complex steps and only using the epitaxially grown layers, which allows for recycling of the substrate.
The island-like III-nitride semiconductor layers 109 are formed in isolation, so that tensile stress or compressive stress are reduced.
Also, the growth restrict mask 102 and the ELO III-nitride layers 105 are not bonded chemically, so the stress in the ELO III-nitride layers 105 and additional device layers 106 can be relaxed by a slide caused at the interface between the growth restrict mask 102 and the ELO III-nitride layers 105.
The existence of the no-growth regions 104 between each of the island-like III-nitride semiconductor layers 109 provides flexibility, and the substrate 101 is easily deformed when external force is applied and can be bent. Therefore, even if there occurs a slight warpage, curvature, or deformation in the substrate 101, this can be easily corrected by a small external force, to avoid the occurrence of cracks. As a result, the handling of the substrates 101 by vacuum chucking is possible, which makes the manufacturing process of the semiconductor devices 111 more easily carried out.
The no-growth region 104 makes it is easy to dissolve a large area of the growth restrict mask 102.
Layers 105, 106, 109 of high-quality semiconductor crystal can be grown by suppressing the curvature of the substrate 101, and further, even when the layers 105, 106, 109 are very thick, the occurrences of cracks, etc., can be suppressed, and thereby a large-area semiconductor device 111 can be easily realized.
The fabrication method can also be easily adopted to large size wafers (>2 inches).
The light emitting apertures fabricated on either side of the open region 103, will improve light output from size.
By conventional means, it is difficult to place similar light out providing devices 111 close enough to solve less light problems.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method, comprising:
forming one or more epitaxial lateral overgrowth (ELO) III-nitride layers on a growth restrict mask using a host substrate;
removing the ELO III-nitride layers from the host substrate; and
placing one or more dielectric distributed Bragg reflector (DBR) mirrors for a resonant cavity of a vertical cavity surface emitting laser (VCSEL) on a backside of the removed ELO III-nitride layers.

2. The method of claim 1, wherein the dielectric DBR mirrors are placed on the backside of the removed ELO Iii-nitride layers at a wing region of the removed ELO III-nitride layers.

3. The method of claim 2, wherein the wing region has a roughness value less than 2 nm.

4. The method of claim 1, wherein at least one of the dielectric DBR mirrors are sandwiched between the removed ELO III-nitride layers.

5. The method of claim 1, wherein the dielectric DBR mirrors are placed on the backside of the removed ELO III-nitride layers at a distance of at least 1 μm away from a coalesced region and open area edge.

6. The method of claim 1, wherein the removed ELO III-nitride layers contain at least a partially processed portion of the VCSEL.

7. The method of claim 1, wherein a thickness of the removed ELO III-nitride layers are controlled epitaxially to realize a functional version of the VCSEL.

8. The method of claim 1, wherein at least one of the removed ELO III-nitride layers is used to extract heat from the VCSEL during device operation.

9. The method of claim 1, wherein the resonant cavity of the VCSEL does not contain a substantial portion of the host substrate.

10. The method of claim 1, wherein the backside of the removed ELO III-nitride layers has a non-planar shape.

11. The method of claim 10, wherein the non-planar shape comprises a curvature, the backside of the removed ELO III-nitride layers has a finite radius of the curvature, and a center of the curvature is on a side of the host substrate's surface.

12. The method of claim 10, wherein the host substrate is pre-patterned to realize the non-planar shape.

13. The method of claim 1, wherein the growth restrict mask comprises a multi-layer structure.

14. The method of claim 1, wherein the growth restrict mask is placed using a sputter-like deposition system.

15. The method of claim 1, wherein the host substrate is a semiconducting substrate.

16. The method of claim 15, wherein the semiconducting substrate is a III-nitride substrate.

17. The method of claim 15, wherein the semiconducting substrate is independent of crystal orientations.

18. A device, comprising:
one or more epitaxial lateral overgrowth (ELO) III-nitride layers formed on a growth restrict mask using a host substrate, wherein the ELO III-nitride layers are removed from the host substrate after being formed for exposing a backside of the ELO III-nitride layers; and
one or more dielectric distributed Bragg reflector (DBR) mirrors for a resonant cavity of a vertical cavity surface emitting laser (VCSEL) placed on the exposed backside of the ELO III-nitride layers.

19. A method for fabricating a quality and manufacturable aperture for light emitting elements, comprising:
forming III-nitride semiconductor layers on a substrate using a growth restrict mask and epitaxial lateral overgrowth (ELO), wherein the III-nitride semiconductor layers are formed as a bar of one or more devices; and
fabricating one or more light emitting resonating cavities on the bar, wherein the light emitting resonating cavities are defined by distributed Bragg reflectors formed on wing regions of the epitaxial lateral overgrowth.
